(19) United States
(12) Patent Application Publication
(10) Pub. No.: US 2012/0164574 A1
(43) Pub. Date: Jun. 28, 2012

(54) ACTINIC-RAY-SENSITIVE OR RADIATION-SENSITIVE RESIN COMPOSITION, AND ACTINIC-RAY-SENSITIVE OR RADIATION-SENSITIVE FILM AND PATTERN FORMING METHOD USING THE SAME

(75) Inventors: Yoko TOKUGAWA, Shizuoka (JP); Mitsuhiro FUJITA, Shizuoka (JP); Tomoki MATSUDA, Shizuoka (JP)

(73) Assignee: FUJIFILM CORPORATION, Tokyo (JP)

(21) Appl. No.: 13/324,538

(22) Filed: Dec. 13, 2011

(30) Foreign Application Priority Data
Dec. 24, 2010 (JP) 2010-288727
Nov. 14, 2011 (JP) 2011-248688

(51) Int. Cl. G03F 7/20; G03F 7/075; G03F 7/027; G03F 7/004

(52) U.S. Cl. 430/281.1; 430/270.1; 430/325

(57) ABSTRACT

Provided is an actinic-ray-sensitive or radiation-sensitive resin composition that is excellent in depth of focus and density distribution dependency, and an actinic-ray-sensitive or radiation-sensitive film and a pattern forming method using the same.

An actinic-ray-sensitive or radiation-sensitive resin composition according to the present invention includes (A) a first resin which decomposes by an action of an acid to increase a solubility of the first resin in an alkaline developer, (B) a second resin which includes at least one of a fluorine atom and a silicon atom and is different from the first resin, and (C) an onium salt which includes a nitrogen atom in a cation portion and generates an acid by being decomposed upon irradiation with actinic-ray or radiation.

### BACKGROUND OF THE INVENTION

1. Field of the Invention

The present invention relates to an actinic-ray-sensitive or radiation-sensitive resin composition, and an actinic-ray-sensitive or radiation-sensitive film and a pattern forming method using the same. More specifically, the present invention relates to a composition applicable to a production process of a semiconductor such as IC, a production process of a circuit board of a liquid crystal, a thermal head, or the like, or other lithography processes of photofabrication, and to a film and a pattern forming method using the same. Particularly, the present invention relates to a composition suitable for being exposed by a liquid immersion projection exposure apparatus that uses far-ultraviolet rays having a wavelength of 300 nm or less as a light source, and to a film and a pattern forming method using the same.

2. Description of the Related Art

In the past, a method of performing exposure through a liquid for liquid immersion, that is, a liquid immersion exposure method has been widely used in the production process or the like of a semiconductor. In a case of employing the liquid immersion exposure method, a technique of adding a hydrophobic resin to a resist composition is known (for example, see JP2007-187887A and WO2007/116664A). In case of such a configuration is employed, a fine pattern can be formed with high accuracy.

However, a resist performance of the resist composition could be further improved. Particularly, depth of focus (DOF) and density distribution dependency need to be further improved.

### SUMMARY OF THE INVENTION

An object of the present invention is to provide an actinic-ray-sensitive or radiation-sensitive resin composition that is excellent in depth of focus and density distribution dependency, and an actinic-ray-sensitive or radiation-sensitive film and a pattern forming method using the same.

An actinic-ray-sensitive or radiation-sensitive resin composition that can achieve the above object contains (A) a first resin which decomposes by an action of an acid to increase a solubility of the first resin in an alkaline developer, (B) a second resin which includes at least one of a fluorine atom and a silicon atom and is different from the first resin, and (C) an onium salt which includes a nitrogen atom in a cation portion and generates an acid by being decomposed upon irradiation with actinic-ray or radiation.

In the present invention, as a preferable embodiment, the content of the second resin is in a range of from 0.1% by mass to 10% by mass based on the total solid contents of the composition, and the second resin includes a repeating unit that has at least one group selected from a group consisting of the following (x), (y), and (z).

(x) an alkali-soluble group,

(y) a group which decomposes by an action of an alkaline developer to increase a solubility of the second resin in the alkaline developer, and

(z) a group which decomposes by an action of an acid to increase a solubility of the second resin in an alkaline developer.

Particularly, the second resin preferably includes a repeating unit having (z) the group which decomposes by an action of an acid to increase a solubility of the second resin in an alkaline developer.

In the present invention, as a preferable embodiment, the onium salt is a sulfonium salt, and the cation portion includes a basic moiety having the nitrogen atom and a partial structure represented by the following general formula (N-I).

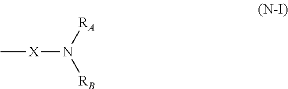

In the formula,

each of R_{A} and R_{B} independently represents a hydrogen atom or an organic group.

X represents a single bond or a linking group.

At least two of R_{A}, R_{B}, and X may form a ring by binding to each other.

Particularly, the onium salt is preferably represented by the following general formula (N-II).

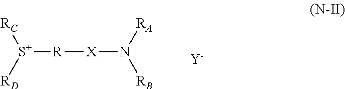

In the formula,

each of R_{A} and R_{B} independently represents a hydrogen atom or an organic group.

X represents a single bond or a linking group.

R represents an organic group.

Each of R_{C} and R_{D} independently represents a hydrogen atom or an organic group.

At least two of R_{A}, R_{B}, X, R, R_{C}, and R_{D} may form a ring by binding to each other.

Y⁻ represents an anion.

The present invention includes an actinic-ray-sensitive or a radiation-sensitive film formed using the composition according to any of the above descriptions.

The present invention also includes a pattern forming method including forming a film by using the composition according to any of the above descriptions, exposing the film through a liquid for liquid immersion, and developing the exposed film.

According to the present invention, an actinic-ray-sensitive or a radiation-sensitive resin composition that is excellent in depth of focus and density distribution dependency, and an actinic-ray-sensitive or a radiation-sensitive film and a pattern forming method using the same can be provided.

### DESCRIPTION OF THE PREFERRED EMBODIMENTS

Hereinafter, the embodiments of the present invention will be described in detail.

Herein, a group and an atomic group for which it is not specified regarding whether the groups are substituted or unsubstituted includes both a group not having a substituent and a group having a substituent. For example, an “alkyl group” for which it is not specified regarding whether the group is substituted or unsubstituted includes not only an alkyl group not having a substituent (unsubstituted alkyl group) but also an alkyl group having a substituent (substituted alkyl group).

In addition, the terms “actinic-ray” or “radiation” herein refers to, for example, a bright line spectrum of a mercury lamp, a far-ultraviolet ray represented by an excimer laser, an extreme ultraviolet (EUV) ray, an X-ray, or an electron beam (EB). The “light” refers to the actinic-ray or the radiation. The term “exposure” refers not only to light irradiation by the mercury lamp, the far-ultraviolet ray, the X-ray, the EUV ray, and the like, but also to drawing by a particle beam such as an electron beam, an ion beam, or the like.

The composition according to the present invention contains (A) a resin (which will be also referred to as an acid-decomposable resin or a resin (A) hereinafter) which decomposes by an action of an acid to increase a solubility of the first resin in an alkaline developer, (B) a resin (which will be also referred to as a hydrophobic resin or a resin (B) hereinafter) which includes at least one of a fluorine atom and a silicon atom, and (C) an onium salt (which will be referred to as a compound (C) hereinafter) which includes a nitrogen atom in a cation portion and generates an acid by being decomposed upon irradiation with actinic-ray or radiation.

The present inventors found that the addition of the compound (C) to the composition containing the resins (A) and (B) greatly improved the depth of focus and the density distribution dependency. The reason is not necessarily clear, but the present inventors assume that the reason is as follows. That is, due to some interactions between the resin (B) and the compound (C), components such as a basic compound and a solvent are inhibited from volatilizing from the composition film during pre-baking. As a result, the components having volatilized from an unexposed portion are inhibited from being reattached onto the surface of an exposed portion, and consequently, density dependency is lowered. For the same reason, the depth of focus increases.

(A) Acid-Decomposable Resin

The acid-decomposable resin (which will be also referred to as the resin (A) hereinafter) includes a group (which will be also referred to as an “acid-decomposable group” hereinafter) that generates an alkali-soluble group by being decomposed by the action of an acid, in a main chain or a side chain, or in both the main chain and the side chain of the resin. The resin (A) is preferably insoluble or hardly soluble in the alkaline developer.

The acid-decomposable group preferably includes a structure in which the alkali-soluble group is protected with a group that is decomposed and eliminated by the action of an acid.

Examples of the alkali-soluble group include a phenolic hydroxyl group, a carboxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Examples of a preferable alkali-soluble group include a carboxyl group, a fluorinated alcohol group (preferably hexafluoroisopropanol), a sulfonic acid group, and the like.

A preferable group as the acid-decomposable group is a group substituted with a group that eliminates hydrogen atoms of these alkali-soluble groups by acid.

Examples of the group that eliminates the hydrogen atoms by acid include —C(R₃₆)(R₃₇)(R₃₈), —C(R₃₆)(R₃₇)(OR₃₉), —C(R₀₁)(R₀₂)(OR₃₉), and the like.

In the formulae, each of R₃₆ to R₃₉ independently represents an alkyl group, a cycloalkyl group, an aryl group, an aralkyl group, or an alkenyl group. R₃₆ and R₃₇ may form a ring by binding to each other.

Each of R₀₁ to R₀₂ independently represents a hydrogen group, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, or the like, and more preferably a tertiary alkyl ester group.

The repeating unit having the acid-decomposable group, which can be contained in the resin (A), is preferably a repeating unit represented by the following general formula (AI).

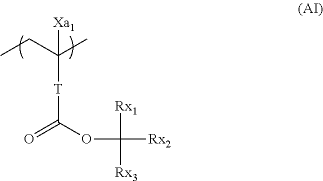

In the general formula (AI),

Xa₁ represents a hydrogen atom, a methyl group that may have a substituent, or a group represented by —CH₂—R₉. R₉ represents a hydroxy group or a monovalent organic group, and examples thereof include an alkyl group having 5 or less carbon atoms and an acyl group, preferably include an alkyl group having 3 or less carbon atoms, and more preferably include a methyl group. Xa₁ preferably represents a hydrogen atom, a methyl group, a trifluoromethyl group, or a hydroxymethyl group.

T represents a single bond or a divalent linking group.

Each of Rx₁ to Rx₃ independently represents a (linear or branched) alkyl group or a (monocyclic or polycyclic) cycloalkyl group.

At least two of Rx₁ to Rx₃ may form a (monocyclic or polycyclic) cycloalkyl group by binding to each other.

Examples of the divalent linking group of T include an alkylene group, a —COO-Rt- group, an —O-Rt- group, and the like. In the formula, Rt represents an alkylene group or a cycloalkylene group.

T is preferably a single bond or a —COO-Rt- group. Rt is preferably an alkylene group having 1 to 5 carbon atoms, and more preferably a —CH₂— group or a —(CH₂)₃— group.

The alkyl group of Rx₁ to Rx₃ is preferably a methyl group, an ethyl group, an n-propyl group, an isopropyl group, an n-butyl group, an isobutyl group, a t-butyl group, or the like, which has 1 to 4 carbon atoms.

The cycloalkyl group of Rx₁ to Rx₃ is preferably a monocyclic cycloalkyl group such as a cyclopentyl group or a cyclohexyl group, and a polycyclic cycloalkyl group such as a norbornyl group, a tetracyclodecanyl group, a tetracyclododecanyl group, or an adamantyl group.

The cycloalkyl group that at least two of Rx₁ to Rx₃ form by binding to each other is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. The cycloalkyl group is particularly preferably a monocyclic cycloalkyl group having 5 to 6 carbon atoms.

As a preferable embodiment, Rx₁ is a methyl group or an ethyl group, and Rx₂ to Rx₃ form the cycloalkyl group described above by binding to each other.

The respective groups may include a substituent. Examples of the substituent include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like, and the number of carbon atoms thereof is preferably 8 or less.

The total content of the repeating unit having the acid-decomposable group is preferably 20 mol % to 70 mol %, and more preferably 30 mol % to 50 mol %, based on all repeating units in the resin (A).

Specific examples of a preferable repeating unit having the acid-decomposable group will be shown below, but the present invention is not limited thereto.

In the specific examples, Rx and Xa₁ represent a hydrogen atom, CH₃, CF₃, or CH₂OH. Rxa and Rxb represent an alkyl group having 1 to 4 carbon atoms respectively. Z represents a substituent including a polar group, and if there is a plurality of substituents, they are independent respectively. p represents 0 or a positive integer.

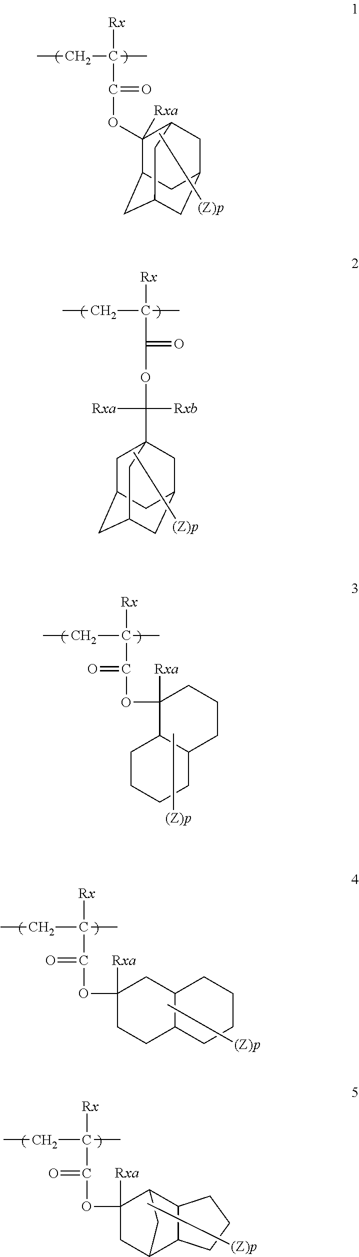

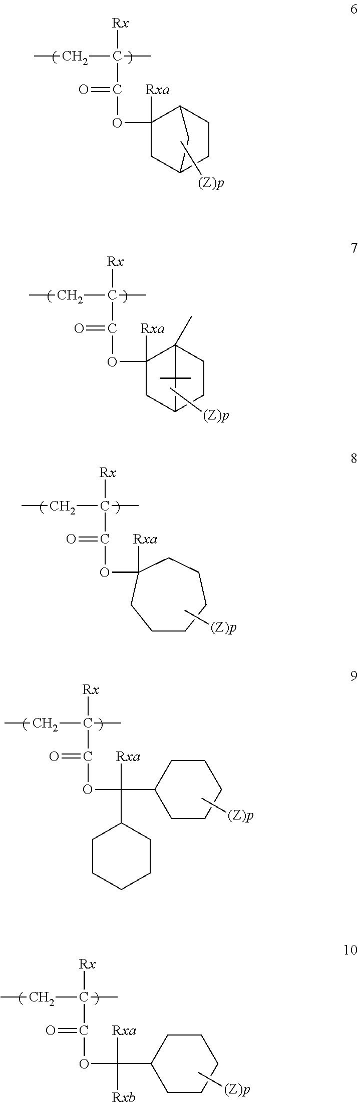

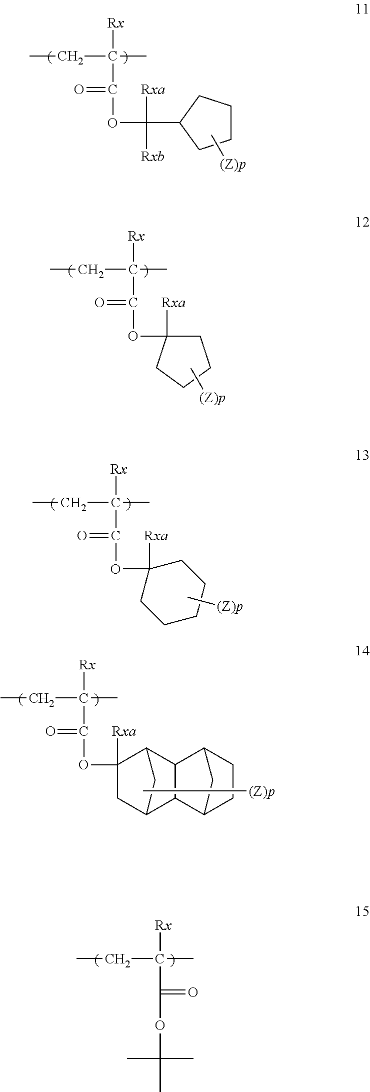

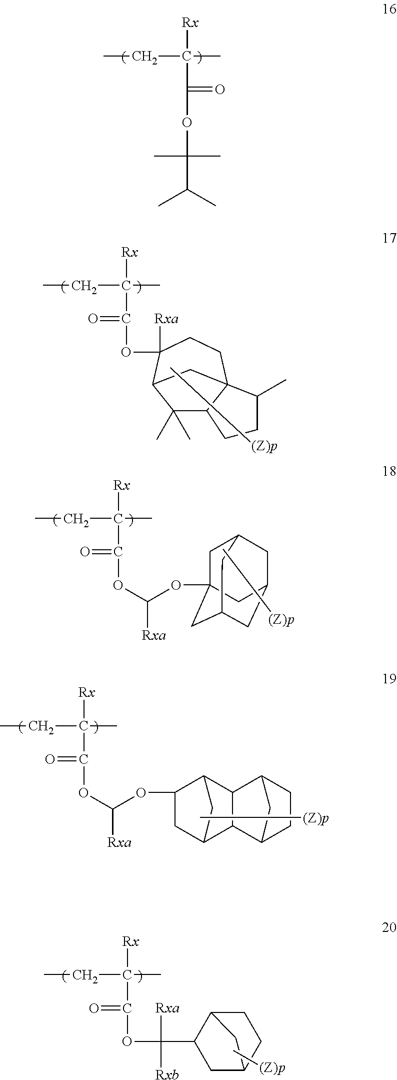

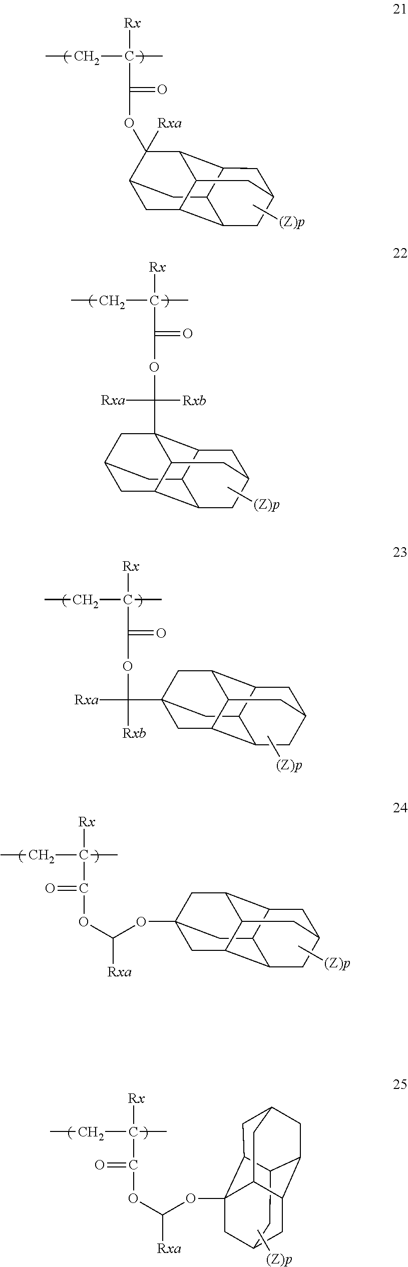

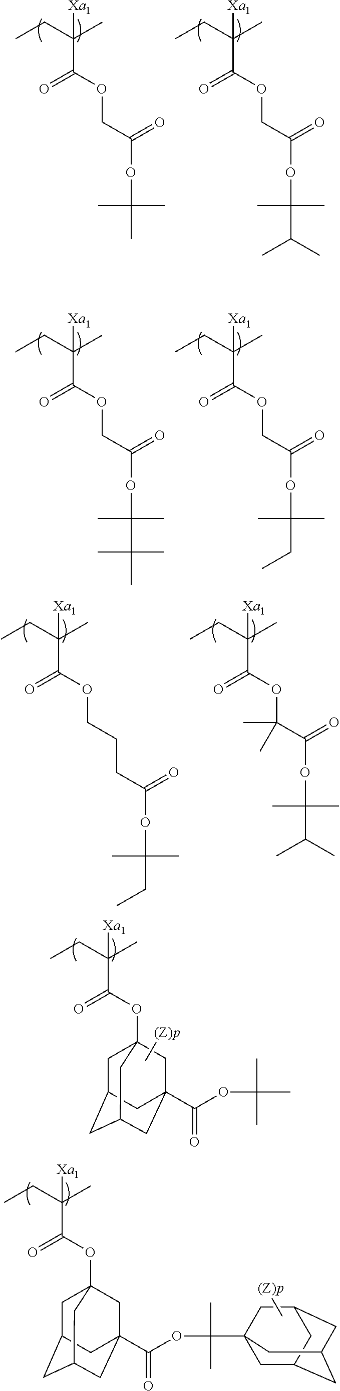

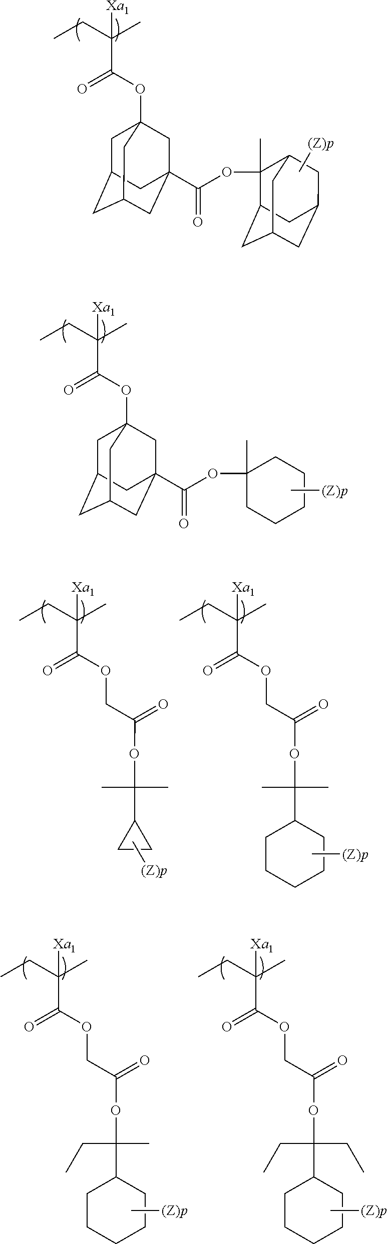

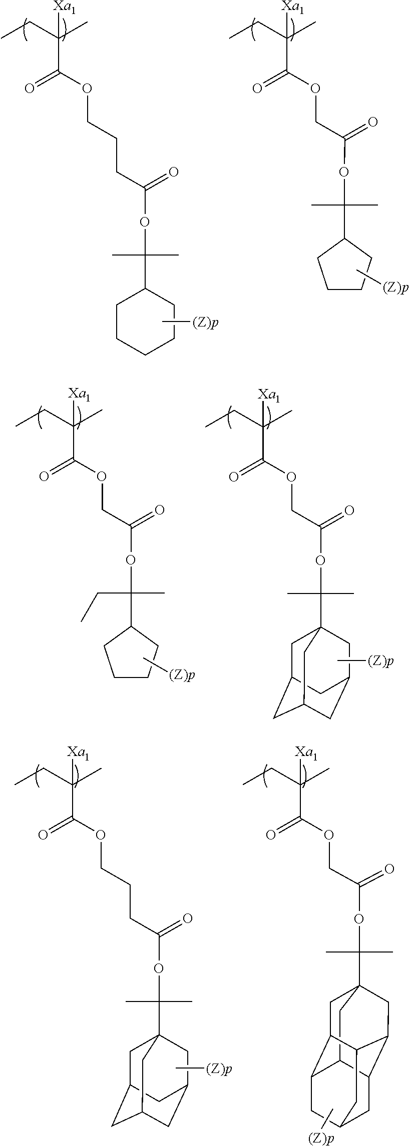

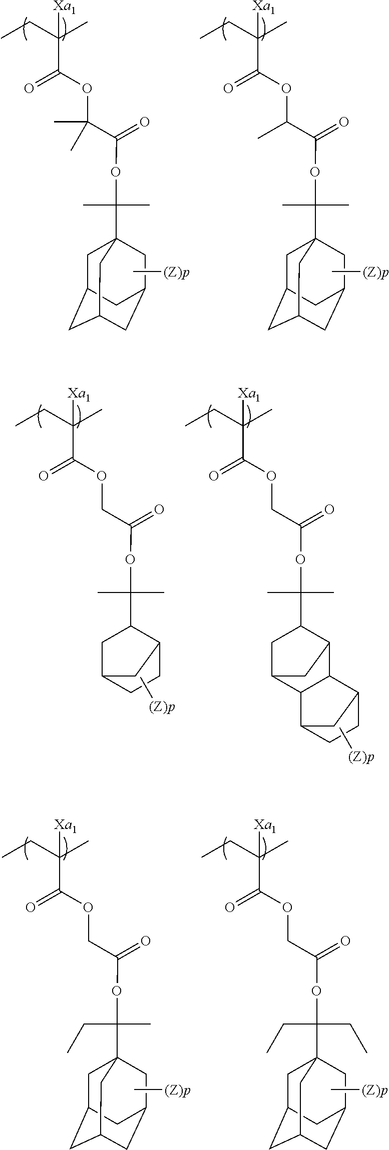

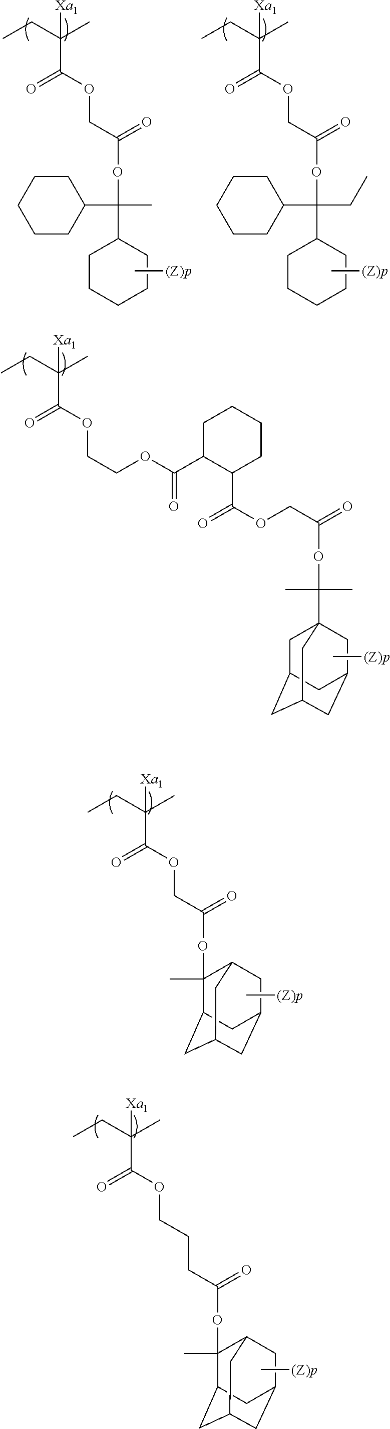

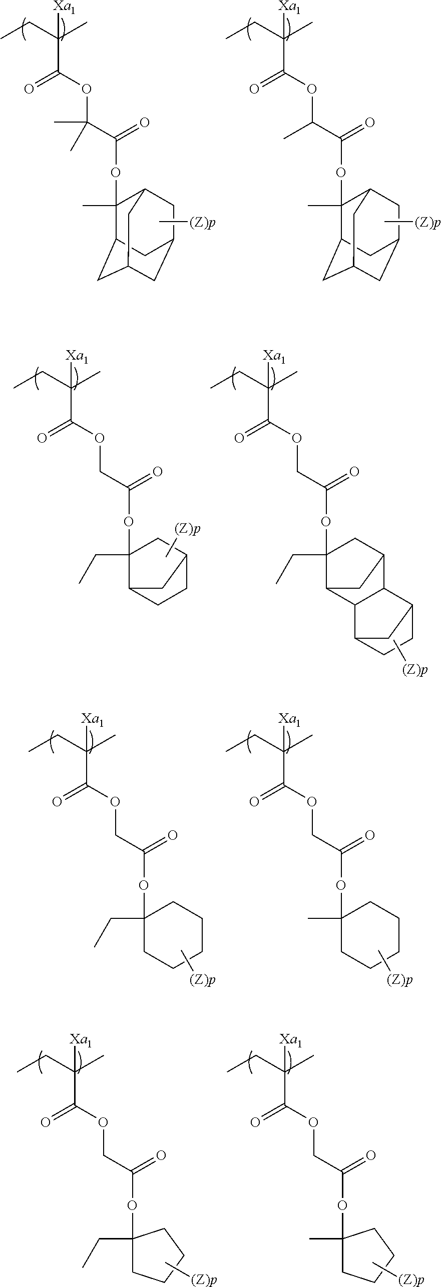

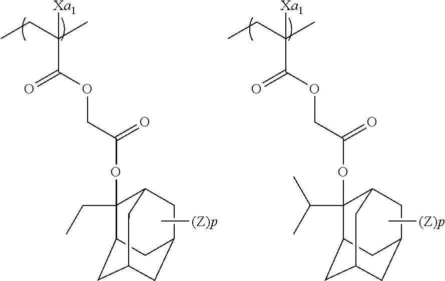

The resin (A) is preferably a resin that includes at least any of the repeating units represented by general formula (I) and the repeating units represented by general formula (II) as the repeating unit represented by general formula (AI).

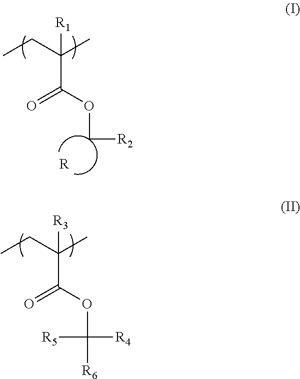

In general formulae (I) and (II),

each of R₁ and R₃ independently represents a hydrogen atom, a methyl group that may have a substituent, or a group represented by —CH₂—R₉. R₉ represents a monovalent organic group.

Each of R₂, R₄, R₅, and R₆ independently represents an alkyl group or a cycloalkyl group.

R represents an atomic group necessary for forming an alicyclic structure with carbon atoms.

R₁ preferably represents a hydrogen atom, a methyl group, a trifluoromethyl group, or a hydroxymethyl group.

The alkyl group in R₂ may be linear or branched, and may have a substituent.

The cycloalkyl group in R₂ may be monocyclic or polycyclic, and may have a substituent.

R₂ is preferably an alkyl group, more preferably a group having 1 to 10 carbon atoms, and still more preferably a group having 1 to 5 carbon atoms, and examples of the group include a methyl group and an ethyl group.

R represents an atomic group necessary for forming an alicyclic structure with carbon atoms. The alicyclic structure that R forms is preferably a monocyclic alicyclic structure, and the number of carbon atoms thereof is preferably 3 to 7, and more preferably 5 or 6.

R₃ is preferably a hydrogen atom or a methyl group, and more preferably a methyl group.

The alkyl group in R₄, R₅, and R₆ may be linear or branched, and may have a substituent. The alkyl group is preferably a methyl group, an ethyl group, an n-propyl group, an isopropyl group, an n-butyl group, an isobutyl group, a t-butyl group, or the like, which has 1 to 4 carbon atoms.

The cycloalkyl group in R₄, R₅, and R₆ may be monocyclic or polycyclic, and may have a substituent. The cycloalkyl group is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

The repeating unit represented by general formula (II) is preferably a repeating unit represented by the following general formula (II-I).

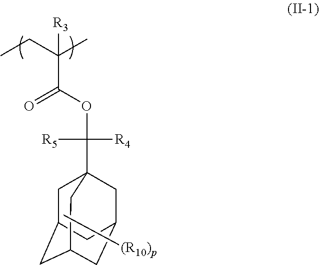

In general formula

R₃ to R₅ have the same definition as those in general formula (II).

R₁₀ represents a substituent having a polar group. When there is a plurality of R₁₀s, they may be the same as or different from each other. Examples of the substituent having a polar group include a linear or branched alkyl group and a cycloalkyl group having a hydroxyl group, a cyano group, an amino group, an alkylamino group, or a sulfonamide group. The substituent is preferably an alkyl group having a hydroxyl group, and an isopropyl group is particularly preferable as a branched alkyl group.

p represents an integer of 0 to 15, and is preferably an integer of 0 to 2, and more preferably 0 or 1.

As preferable combinations in a case where the resin (A) uses the acid-decomposable repeating units in combination, the following combinations are exemplified. In the following formulae, each R independently represents a hydrogen atom or a methyl group.

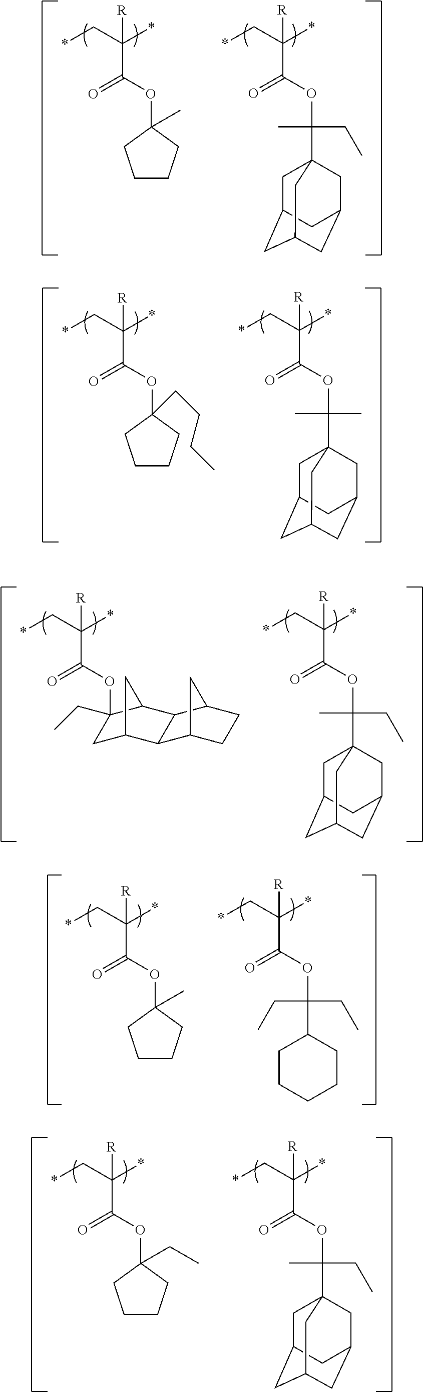

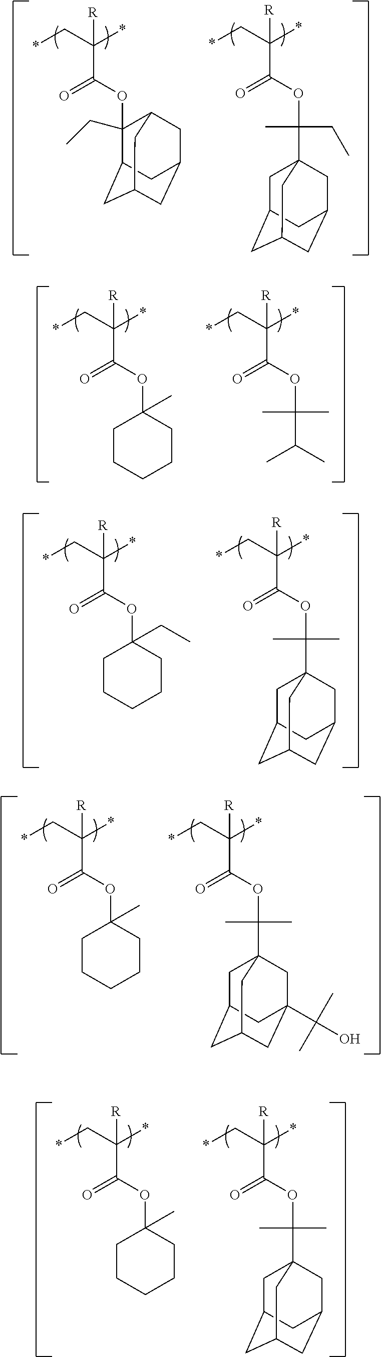

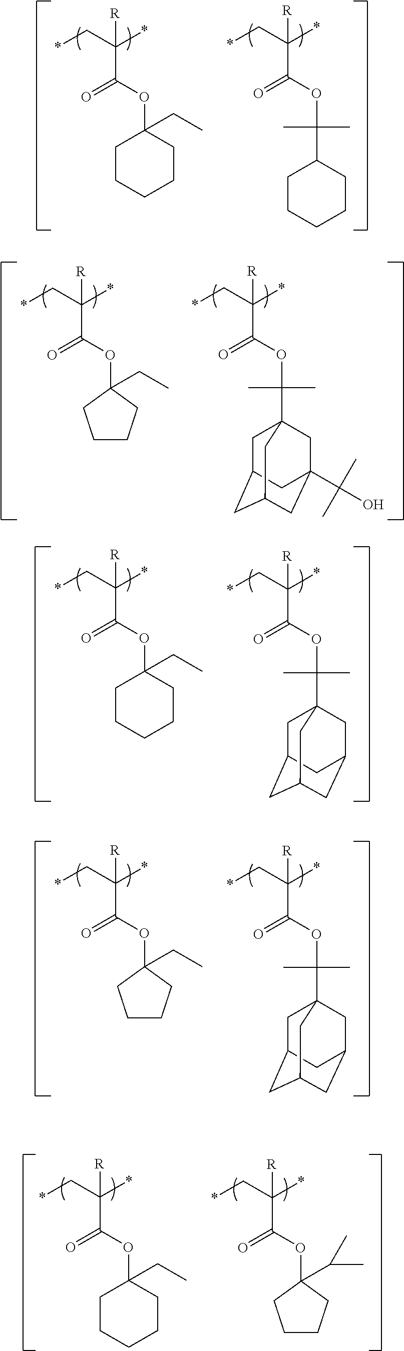

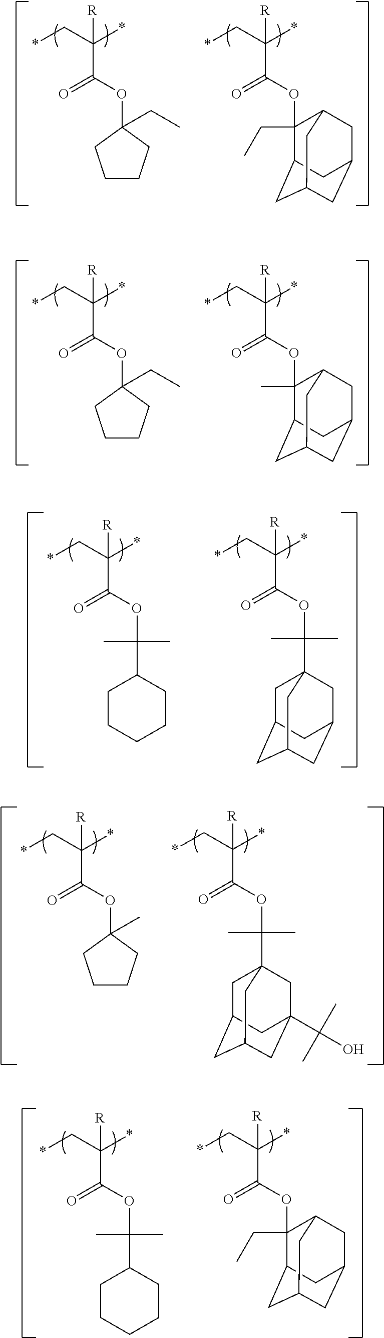

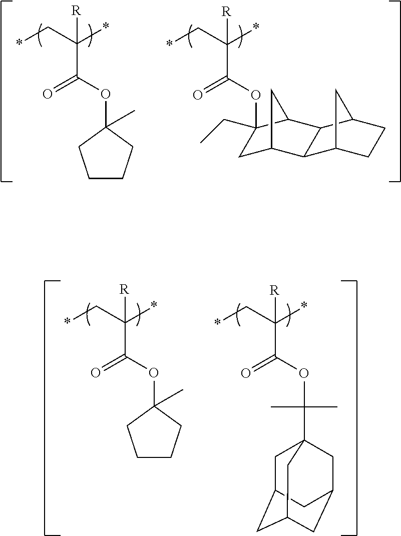

The resin (A) preferably contains a repeating unit that is represented by the following general formula (III) and has a lactone structure.

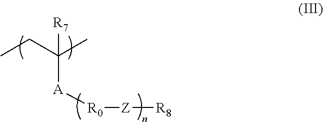

In Formula (III),

A represents an ester bond (a group represented by —COO—) or an amide bond (a group represented by —CONH—).

Each R₀ independently represents an alkylene group, a cycloalkylene group, or a combination thereof, when there is a plurality of R₀s.

Each Z independently represents an ether bond, an ester bond, an amide bond, a urethane bond

(a group represented by

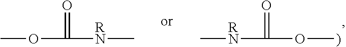

or a urea bond (a group represented by

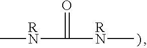

when there is a plurality of Zs.

Herein, R represents a hydrogen atom, an alkyl group, a cycloalkyl group, or an aryl group.

R₈ represents a monovalent organic group having a lactone structure. n is a number of repetitions of a structure represented by —R₀—Z— and represents an integer of 1 to 5.

R₇ represents a hydrogen atom, a halogen atom, or an alkyl group.

The alkylene group and the cycloalkylene group of R₀ may have a substituent. Z is preferably an ether bond or an ester bond, and particularly preferably an ester bond.

The alkyl group of R₇ is preferably an alkyl group having 1 to 4 carbon atoms, more preferably a methyl group or an ethyl group, and particularly preferably a methyl group. The alkyl group in R₇ may be substituted, and examples of the substituent include halogen atoms such as a fluorine atom, a chlorine atom, and a bromine atom; alkoxy groups such as a mercapto group, a hydroxy group, a methoxy group, an ethoxy group, an isopropoxy group, a t-butoxy group, and a benzyloxy group; and acyl groups such as an acetyl group and a propionyl group. R₇ is preferably a hydrogen atom, a methyl group, a trifluoromethyl group, or a hydroxymethyl group.

The linear alkylene group in R₀ is preferably linear alkylene having 1 to 10 carbon atoms, and the number of carbon atoms is more preferably 1 to 5. Examples of a preferable linear alkylene group include a methylene group, an ethylene group, a propylene group, and the like. The cycloalkylene is preferably cycloalkylene having 1 to 20 carbon atoms, and examples thereof include cyclohexylene, cyclopentylene, norbornylene, adamantylene, and the like. In order to bring about the effects of the present invention, a linear alkylene group is more preferable, and a methylene group is particularly preferable.

The organic group having a lactone structure represented by R₈ is not limited as long as the substituent has a lactone structure. Specific examples of the lactone structure include lactone structures represented by general formulae (LC1-1) to (LC1-17) described later, and among these, a structure represented by (LC1-4) is particularly preferable. In addition, n₂ in (LC1-1) to (LC1-17) is more preferably 2 or less.

R₈ is preferably a monovalent organic group having an unsubstituted lactone structure or a monovalent organic group having a lactone structure that includes a methyl group, a cyano group, or an alkoxycarbonyl group as a substituent, and more preferably a monovalent organic group having a lactone structure (cyanolactone) that includes a cyano group as a substituent.

Hereinbelow, specific examples of the repeating unit having a lactone structure that is represented by general formula (III) will be shown, but the present invention is not limited thereto.

In the following specific examples, R represents a hydrogen atom, an alkyl group that may have a substituent, or a halogen atom, and preferably represents a hydrogen atom, a methyl group, a hydroxymethyl group, or an acetoxymethyl group.

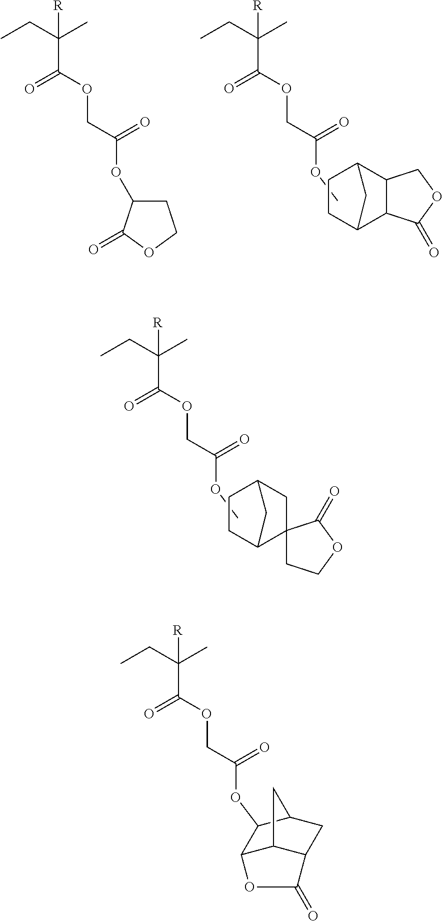

As the repeating unit having a lactone structure, a repeating unit represented by the following general formula (III-I) is more preferable.

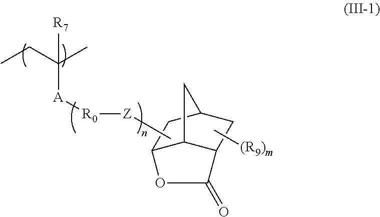

In general formula

R₇, A, R₀, Z, and n have the same definitions as those in general formula (III).

When there is a plurality of R₉s, each R₉ independently represents an alkyl group, a cycloalkyl group, an alkoxycarbonyl group, a cyano group, a hydroxyl group, or an alkoxy group, and two R₉s may form a ring by binding to each other.

X represents an alkylene group, an oxygen atom, or a sulfur atom. m is the number of substituents and represents an integer of 0 to 5. m is preferably 0 or 1.

The alkyl group of R₉ is preferably an alkyl group having 1 to 4 carbon atoms, more preferably a methyl group or an ethyl group, and most preferably a methyl group. Examples of the cycloalkyl group include a cyclopropyl group, a cyclobutyl group, a cyclopentyl group, and a cyclohexyl group. Examples of the alkoxycarbonyl group include a methoxycarbonyl group, an ethoxycarbonyl group, an n-butoxycarbonyl group, a t-butoxycarbonyl group, and the like. Examples of the alkoxy group include a methoxy group, an ethoxy group, a propoxy group, an isopropoxy group, a butoxy group, and the like. These groups may have a substituent, and examples of the substituent include alkoxy groups such as a hydroxy group, a methoxy group, and an ethoxy group; a cyano group; and halogen atoms such as a fluorine atom. R₉ is more preferably a methyl group, a cyano group, or an alkoxycarbonyl group, and still more preferably a cyano group.

Examples of the alkylene group of X include a methylene group, an ethylene group, and the like. X is preferably an oxygen atom or a methylene group, and more preferably a methylene group.

When m is 1 or greater, at least one R₉ is preferably substituted with an α position or a β position of the carbonyl group of lactone, and particularly preferably substituted with the α position.

Specific examples of the repeating unit having a lactone structure represented by general formula (III-I) will be shown, but the present invention is not limited thereto. In the following specific examples, R represents a hydrogen atom, an alkyl group that may have a substituent, or a halogen atom, and preferably represents a hydrogen atom, a methyl group, a hydroxymethyl group, or an acetoxymethyl group.

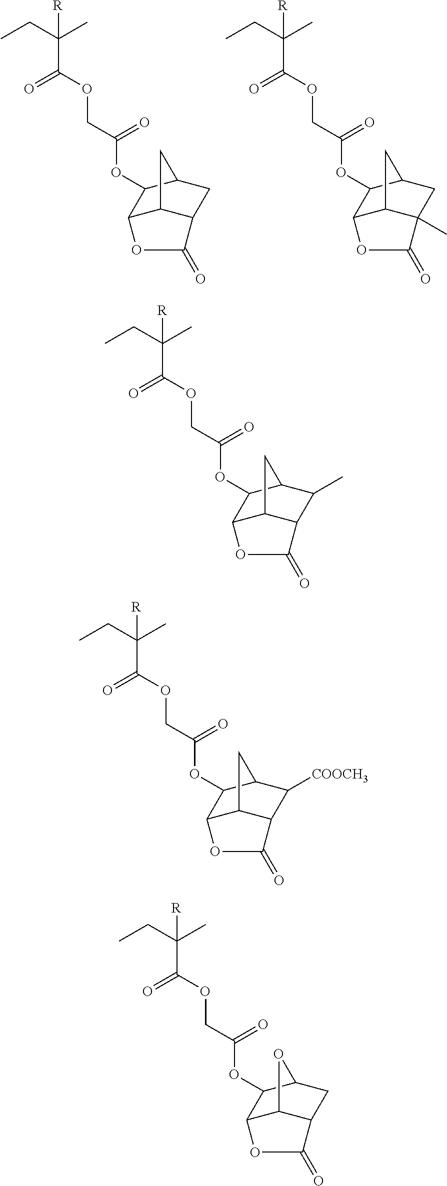

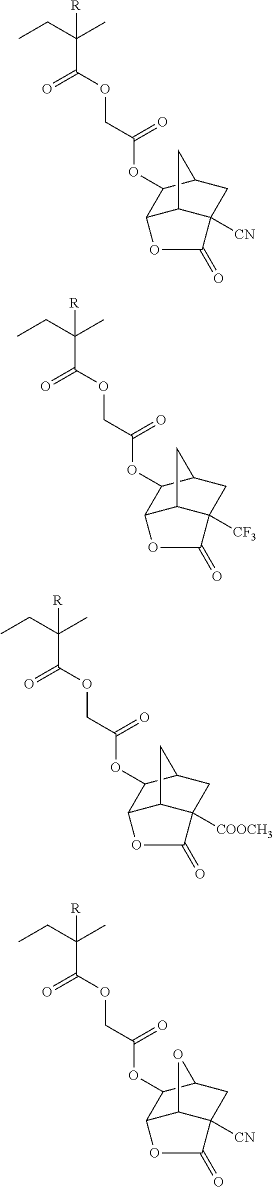

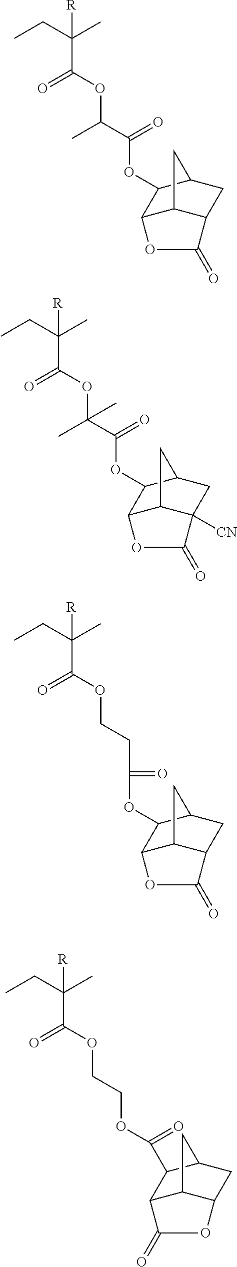

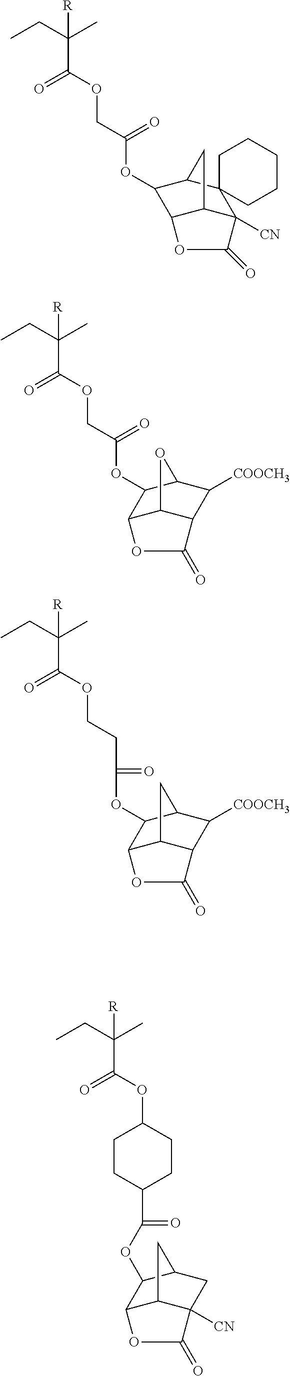

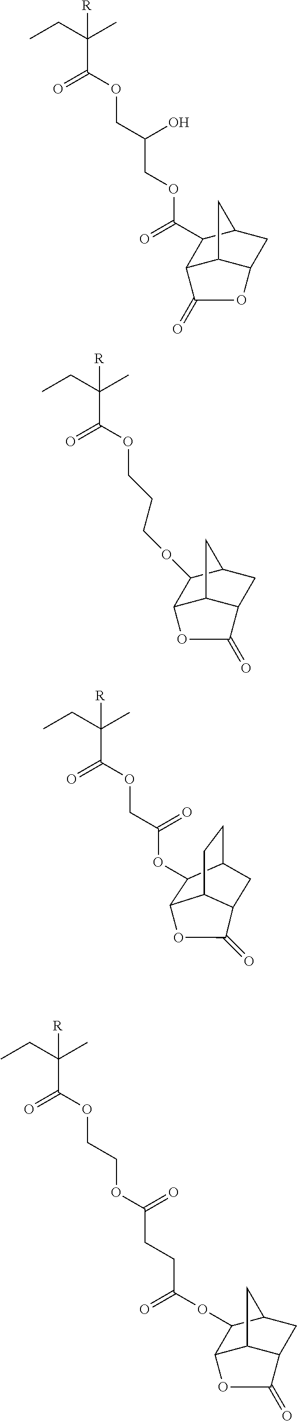

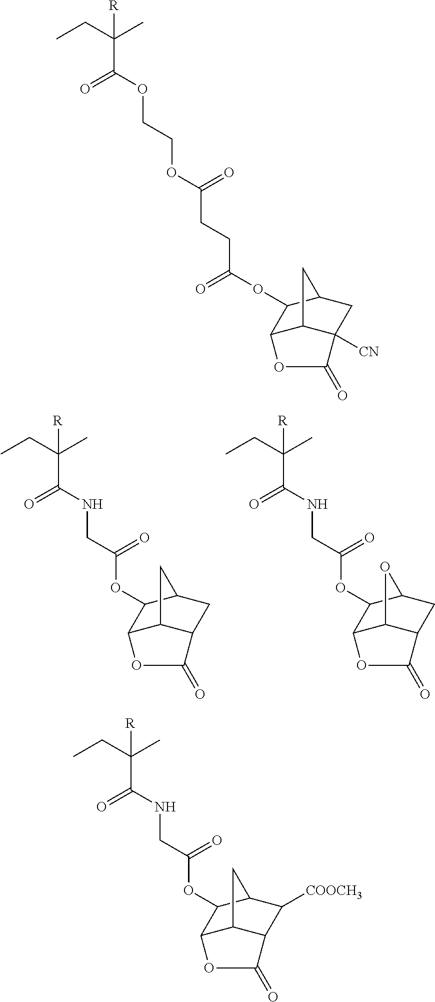

The content of the repeating unit represented by general formula (III) is preferably 15 mol % to 60 mol %, more preferably 20 mol % to 60 mol %, and still more preferably 30 mol % to 50 mol % in total, based on all the repeating units in the resin (A), when a plurality of kinds of the repeating units are contained.

The resin (A) may contain a repeating unit having a lactone group, in addition to the repeating units represented by general formula (III).

Any lactone group can be used as long as the lactone group has a lactone structure, and the lactone structure is preferably a 5 to 7-membered lactone ring structure. The lactone group is preferably a group in which another ring structure is condensed with the 5 to 7-membered lactone ring structure while forming a bicyclo structure or a spiro structure. The lactone group more preferably includes a repeating unit having a lactone structure that is represented by any one of the following general formulae (LC1-1) to (LC1-17). In addition, the lactone structure may directly bind to the main chain. Preferable lactone structures include (LC1-1), (LC1-4), (LC1-5), (LC1-6), (LC1-13), (LC1-14), and (LC1-17). The LWR and development defects are improved by the use of a specific lactone structure.

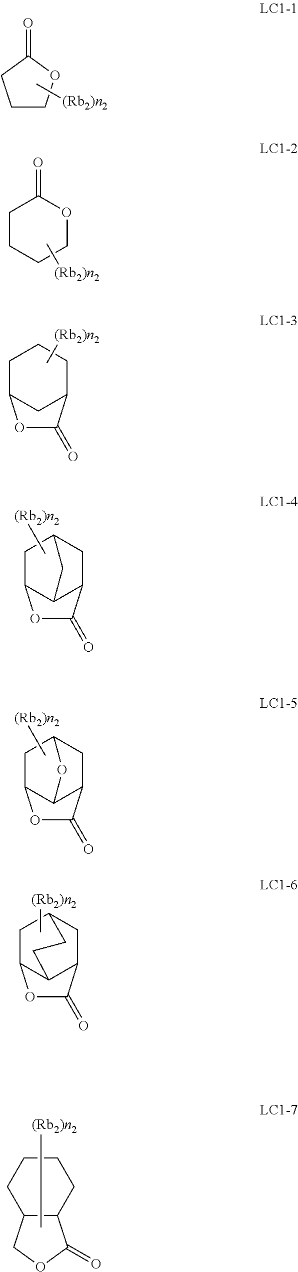

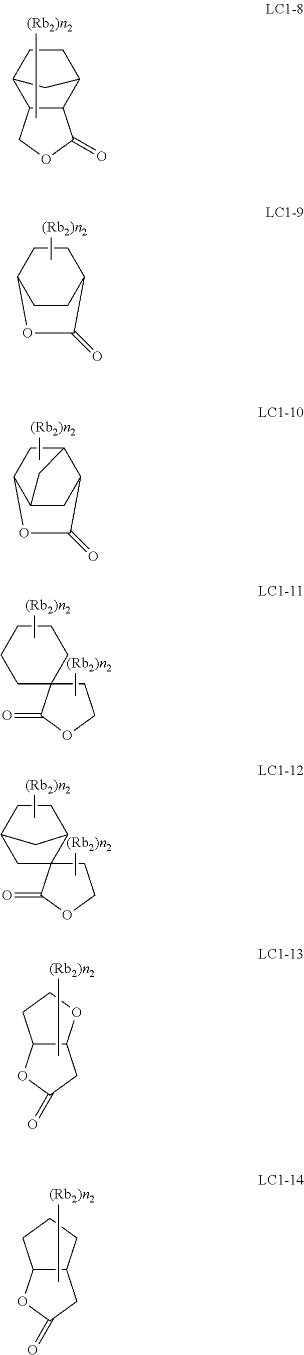

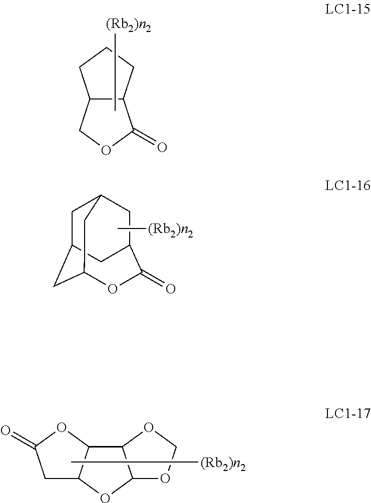

The lactone structure portion may or may not include a substituent (Rb₂). Examples of a preferable substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group, and the like. The substituent (Rb₂) is more preferably an alkyl group having 1 to 4 carbon atoms, a cyano group, or an acid-decomposable group. n₂ represents an integer of 0 to 4. When n₂ is 2 or greater, a plurality of substituents (Rb₂) may be the same as or different from each other, and the plurality of substituents (Rb₂) may form a ring by binding to each other.

As a repeating unit having a lactone structure, which is a unit other than the units represents by general formula (III), a repeating unit represented by the following general formula (AII′) is also preferable.

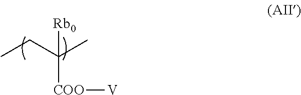

In general formula (AII′),

Rb₀ represents a hydrogen atom, a halogen atom or an alkyl group having 1 to 4 carbon atoms. Examples of a preferable substituent that the alkyl group of Rb₀ may have include a hydroxyl group, a halogen atom, and the like. Examples of the halogen atom of Rb₀ include a fluorine atom, a chlorine atom, a bromine atom, and an iodine atom. Rb₀ is preferably a hydrogen atom, a methyl group, a hydroxymethyl group, or a trifluoromethyl group, and particularly preferably a hydrogen atom or a methyl group.

V represents a group having a structure represented by any one of general formulae (LC1-1) to (LC1-17).

Specific examples of a repeating unit having a lactone group, which is a repeating unit other than the units represented by general formula (III), are shown below, but the present invention is not limited thereto.

(In the formula, Rx is H, CH₃, CH₂OH, or CF₃.)

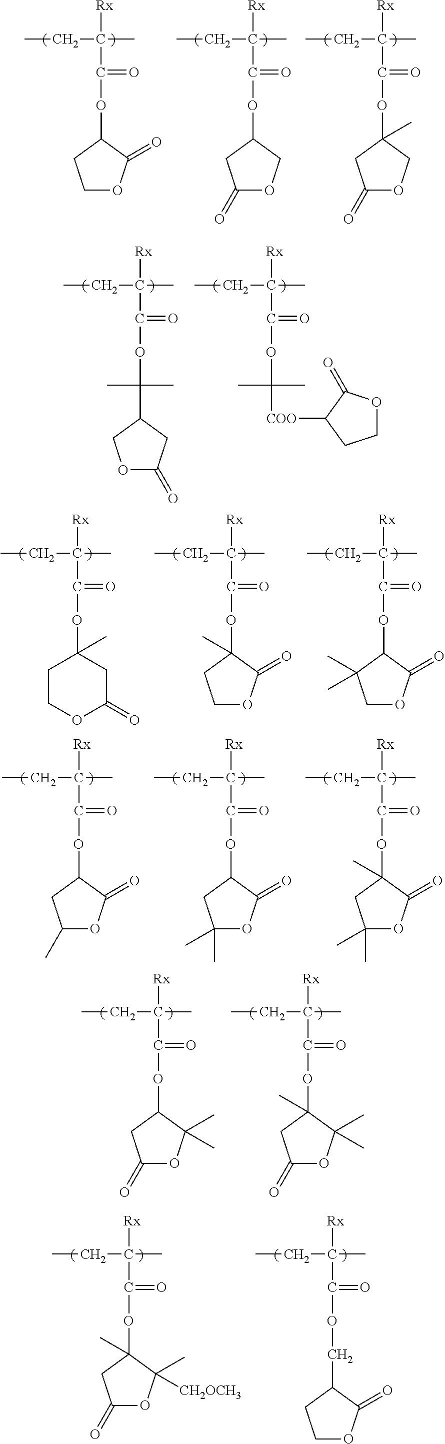

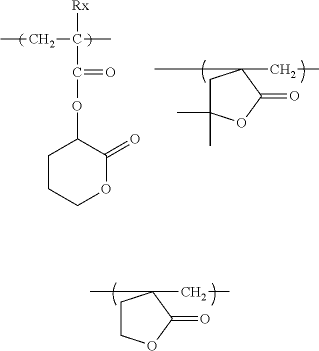

(In the formula, Rx is H, CH₃, CH₂OH, or CF₃.)

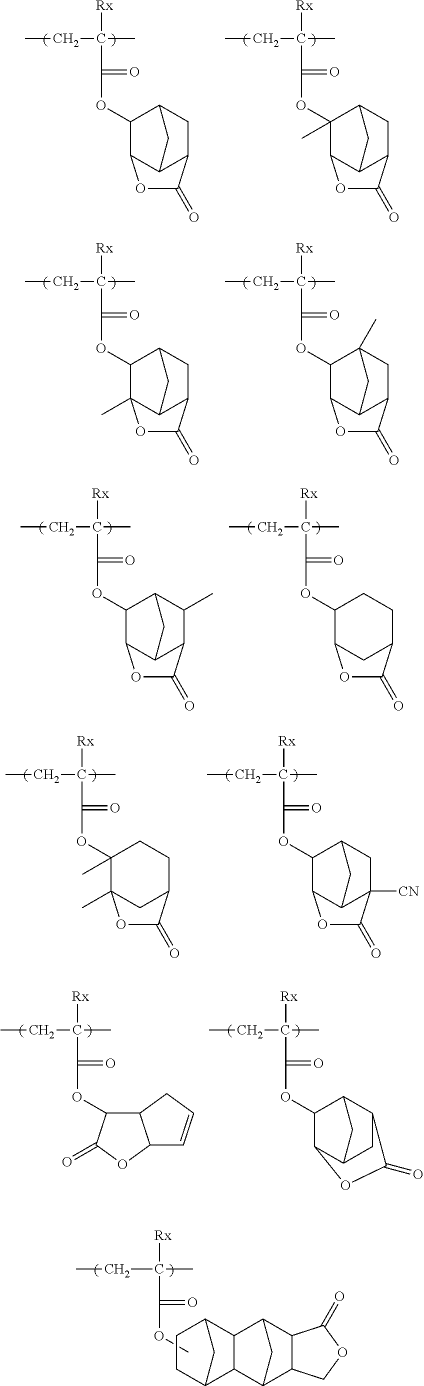

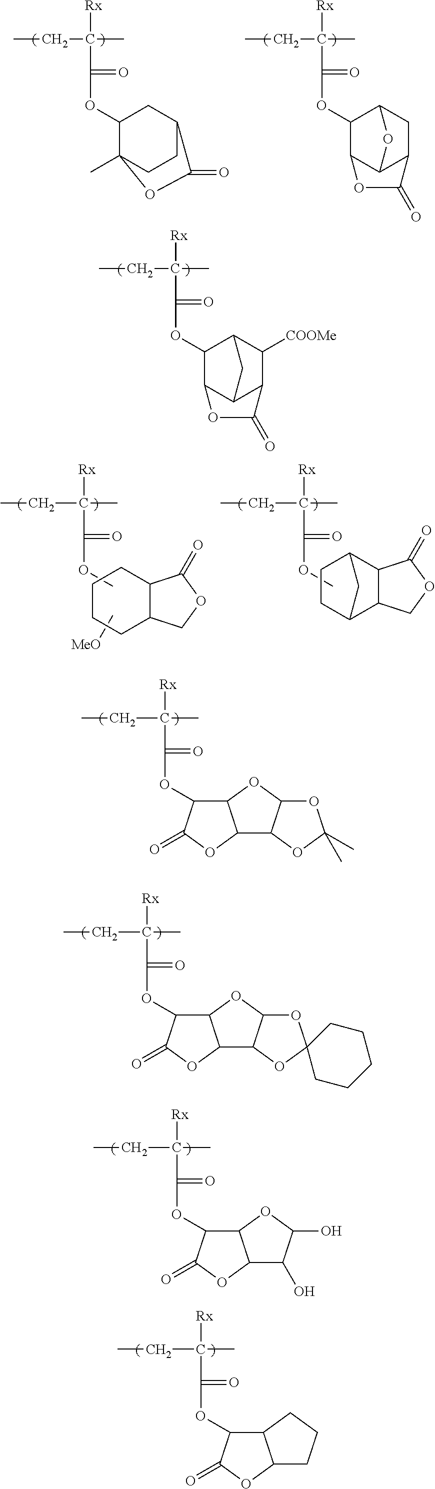

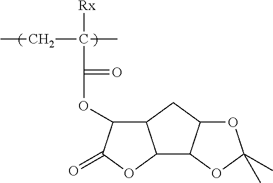

(In the formula, Rx is H, CH₃, CH₂OH, or CF₃.)

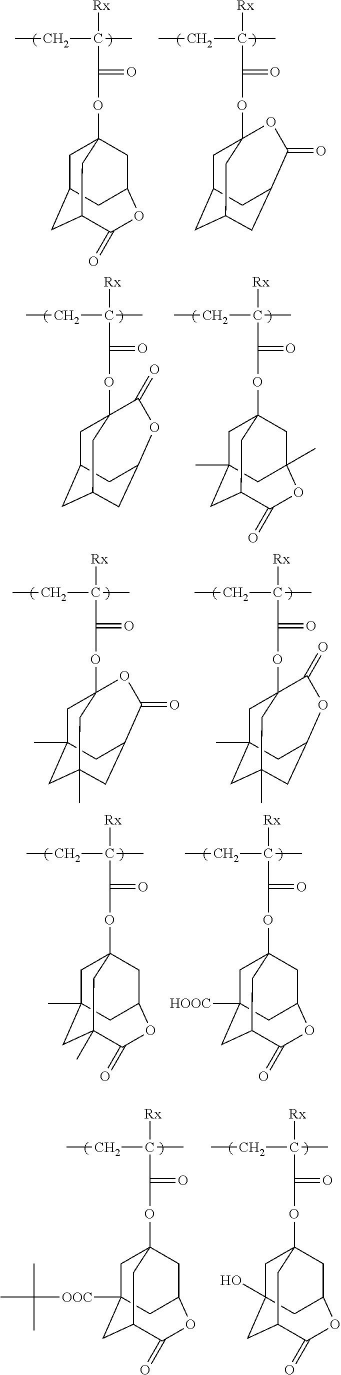

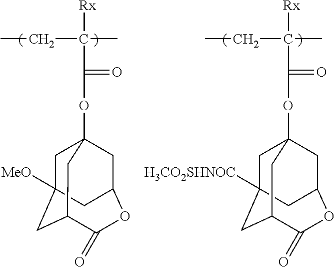

Particularly preferable examples of the repeating unit having a lactone structure, which is a repeating unit other than the units represented by general formula (III), include the following repeating units. By selecting an optimal lactone group, pattern profile and density distribution dependency are improved.

(In the formula, Rx is H, CH₃, CH₂OH, or CF₃.)

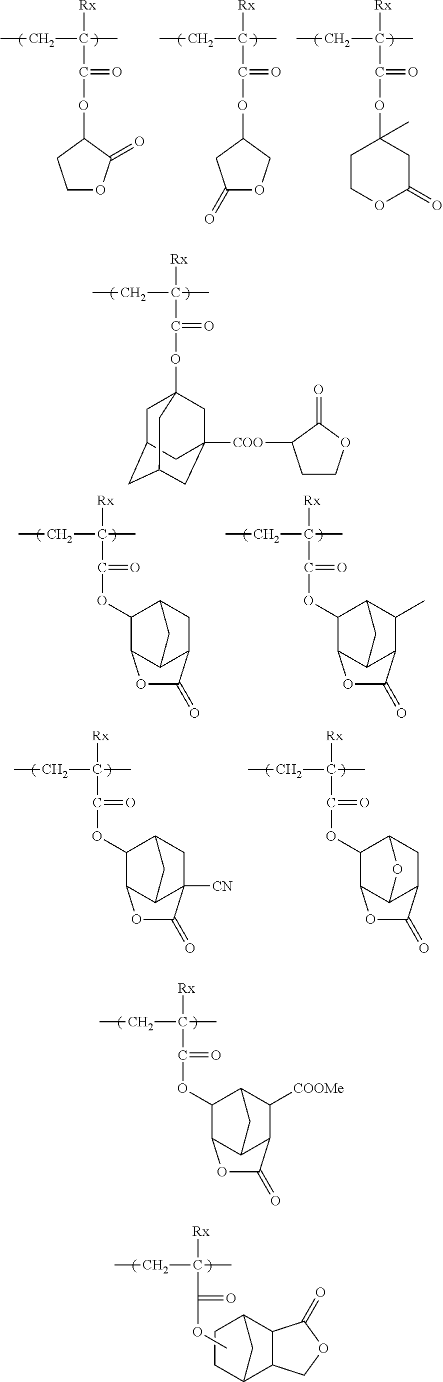

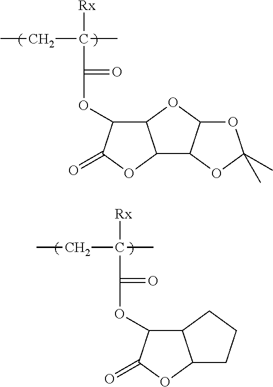

For the repeating unit having a lactone structure, there are optical isomers in general, and any of the optical isomers may be used. Furthermore, one kind of optical isomer may be used alone, or a plurality of optical isomers may be used in combination. When one kind of optical isomer is mainly used, the optical purity (ee) thereof is preferably 90% or higher, and more preferably 95% or higher.

The content of the repeating unit having lactone, which is a repeating unit other than those represented by general formula (III), is preferably 15 mol % to 60 mol %, more preferably 20 mol % to 50 mol %, and still more preferably 30 mol % to 50 mol % in total, based on all repeating units in the resin, when a plurality of kinds of the repeating units are contained.

In order to enhance the effects of the present invention, two or more kinds of lactone repeating units selected from general formula (III) can be used in combination. When the units are used in combination, it is preferable to select two or more kinds from lactone repeating units in which n is 1 in general formula (III).

The resin (A) preferably includes a repeating unit having a hydroxyl group or a cyano group, which is a repeating unit other than repeating units in general formulae (AI) and (III), and as a result, substrate adhesion and affinity for a developer are improved. The repeating unit having a hydroxyl group or a cyano group is preferably a repeating unit that has an alicyclic hydrocarbon structure substituted with a hydroxyl group or a cyano group and does not include an acid-decomposable group. In the alicyclic hydrocarbon structure substituted with a hydroxyl group or a cyano group, the alicyclic hydrocarbon structure is preferably an adamantyl group, a diamantyl group, or a norbornane group. Preferable alicyclic hydrocarbon structures substituted with a hydroxyl group or a cyano group include partial structures represented by the following general formulae (VIIa) to (VIId).

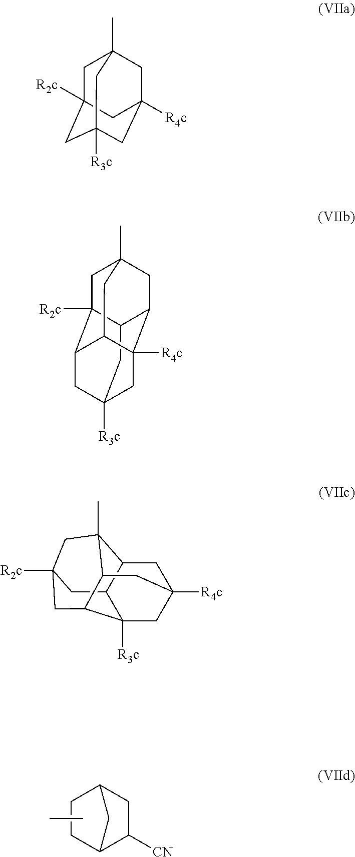

In general formulae (VIIa) to (VIIc),

each of R₂c to R₄c independently represents a hydrogen atom, a hydroxyl group, or a cyano group. Here, at least one of R₂c to R₄c represents a hydroxyl group or a cyano group. Preferably, one or two of R₂c to R₄c is a hydroxyl group, and the remainder is a hydrogen atom. In general formula (VIIa), two of R₂c to R₄c are more preferably hydroxyl groups, and the remainder is a hydrogen atom.

Examples of the repeating unit having the partial structure represented by general formulae (VIIa) to (VIId) include repeating units represented by the following general formulae (Alla) to (AIId).

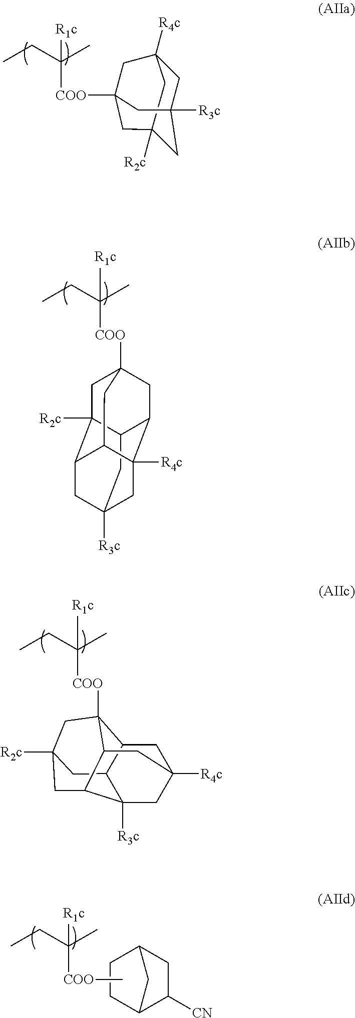

In general formulae (Alla) to (AIId),

R₁c represents a hydrogen atom, a methyl group, a trifluoromethyl group, or a hydroxymethyl group.

R₂c to R₄c have the same definitions as those of R₂c to R₄c in general formulae (VIIa) to (VIIc).

The content of the repeating unit having a hydroxyl group or a cyano group is preferably 5 mol % to 40 mol %, more preferably 5 mol % to 30 mol %, and still more preferably 10 mol % to 25 mol %, based on all repeating units in the resin (A).

Specific examples of the repeating unit having a hydroxyl group or a cyano group are shown below, but the present invention is not limited thereto.

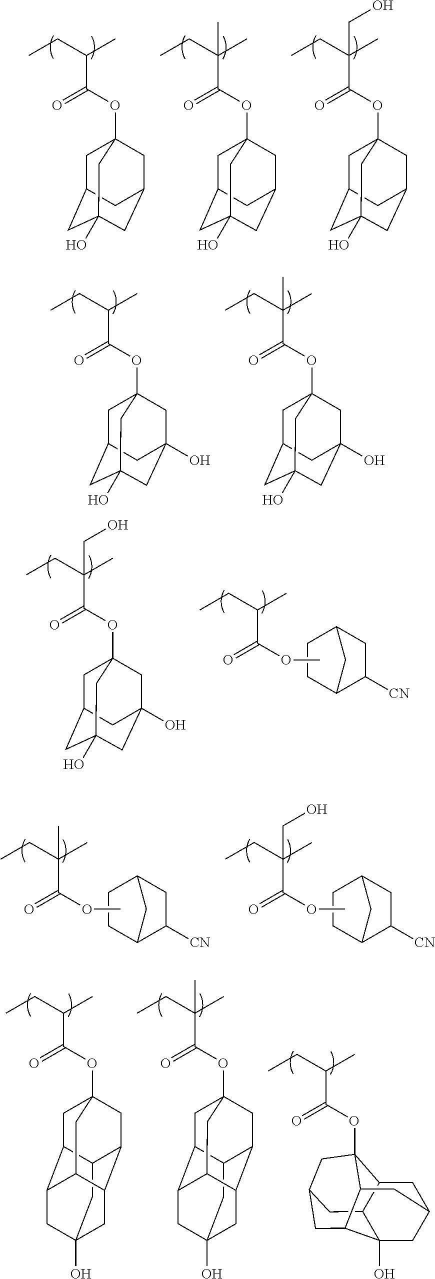

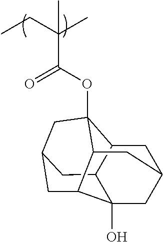

The resin (A) may include a repeating unit having an alkali-soluble group. Examples of the alkali-soluble group include a carboxyl group, a sulfonamide group, a sulfonylimide group, a bis-sulfonylimide group, and aliphatic alcohol (for example, a hexafluoroisopropanol group) in which an α position has been substituted with an electron-attracting group. The resin (A) more preferably includes a repeating unit having a carboxyl group. If the resin (A) contains a repeating unit having an alkali-soluble group, resolution for the use of the resin as a contact hole increases. As the repeating unit having an alkali-soluble group, any of a repeating unit in which an alkali-soluble group directly binds to the main chain of a resin, such as a repeating unit of acrylic acid or methacrylic acid, a repeating unit in which an alkali-soluble group binds to the main chain of a resin through a linking group, and introducing a polymerization initiator or a chain transfer agent having an alkal-soluble group to the terminal of a polymer chain during polymerization are preferable. The linking group may have a monocyclic or polycyclic hydrocarbon structure. Particularly preferable repeating units are repeating units of acrylic acid or methacrylic acid.

The content of the repeating unit having an alkali-soluble group is preferably 0 mol % to 20 mol %, more preferably 3 mol % to 15 mol %, and still more preferably 5 mol % to 10 mol %, based on all repeating units in the resin (A).

Specific examples of the repeating unit having an alkali-soluble group are shown below, but the present invention is not limited thereto.

In the specific examples, Rx represents H, CH₃, CH₂OH, or CF₃.

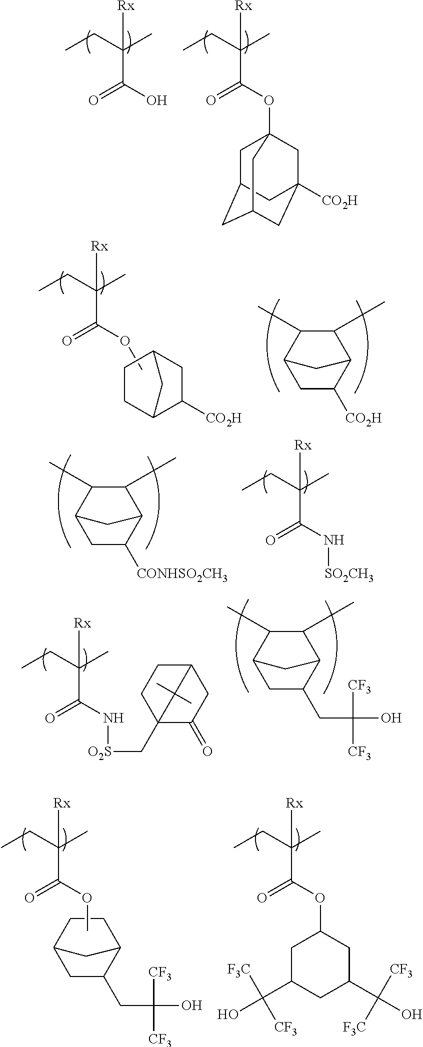

The resin (A) of the present invention can further include an alicyclic hydrocarbon structure that does not have a polar group and a repeating unit that does not exhibit acid degradability. Examples of such a repeating unit include a repeating unit represented by general formula (IV).

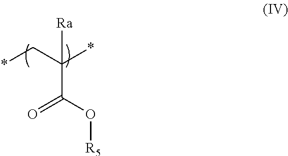

In general formula (IV), R₅ represents a hydrocarbon group that includes at least one cyclic structure and does not include any of a hydroxyl group and a cyano group.

Ra represents a hydrogen atom, an alkyl group, or a —CH₂—O—Ra₂ group. In the formula, Ra₂ represents a hydrogen atom, an alkyl group, or a cyano group. Ra is preferably a hydrogen atom, a methyl group, a hydroxymethyl group, or a trifluoromethyl group, and particularly preferably a hydrogen atom or a methyl group.

The cyclic structure of R₅ includes a monocyclic hydrocarbon group and a polycyclic hydrocarbon group. Examples of the monocyclic hydrocarbon group include cycloalkyl groups having 3 to 12 carbon atoms such as a cyclopentyl group, a cyclohexyl group, a cycloheptyl group, and a cyclooctyl group and cycloalkenyl groups having 3 to 12 carbon atoms such as a cyclohexenyl group. Examples of the preferable monocyclic hydrocarbon group include a monocyclic hydrocarbon group having 3 to 7 carbon atoms, and a cyclopentyl group and a cyclohexyl group are more preferable.

The polycyclic hydrocarbon group includes a ring-aggregated hydrocarbon group and a crosslinked cyclic hydrocarbon group. Examples of the ring-aggregated hydrocarbon group include a bicyclohexyl group, a perhydronaphthalenyl group, and the like. Examples of the crosslinked cyclic hydrocarbon ring include bicycic hydrocarbon rings such as a pinane ring, a bornane ring, a norpinane ring, a norbornane ring, and a bicyclooctane ring (bicyclo[2.2.2]octane ring, bicyclo[3.2.1]octane ring, and the like); tricyclic hydrocarbon rings such as a homobrendane ring, an adamantane ring, a tricyclo[5.2.1.0^{2,6}]decane ring, and tricyclo[4.3.1.1^{2,5}]undecane ring; and tetracyclic hydrocarbon rings such as a tetracyclo[4.4.0.1^{2,5}.1^{7,10}]dodecane ring and a perhydro-1,4-methano-5,8-methanonaphthalene ring. The crosslinked cyclic hydrocarbon ring also includes a hydrocarbon ring of a condensed ring, for example, a condensed ring in which a plurality of 5 to 8-membered cycloalkane rings such as a perhydronaphthalene ring (decalin), a perhydroanthracene ring, a perhydrophenanthrene ring, a perhydroacenaphthene ring, a perhydrofluorene ring, a perhydroindene ring, and a perhydrophenalene ring are condensed.

Examples of a preferable crosslinked cyclic hydrocarbon ring include a norbornyl group, an adamantyl group, a bicyclooctanyl group, a tricyclo[5,2,1,0^{2,6}]decanyl group, and the like. Examples of the more preferable crosslinked cyclic hydrocarbon ring include a norbornyl group, and an adamantyl group.

These alicyclic hydrocarbon groups may include a substituent, and examples of a preferable substituent include a halogen atom, an alkyl group, a hydroxyl group protected with a protecting group, an amino group protected with a protecting group, and the like. Examples of a preferable halogen atom include a bromine atom, a chlorine atom, and a fluorine atom, and examples of a preferable alkyl group include a methyl group, an ethyl group, a butyl group, and a t-butyl group. This alkyl group may further have a substituent, and examples of this substituent that may be further included include a halogen atom, an alkyl group, a hydroxyl group protected with a protecting group, and an amino group protected with a protecting group.

Examples of the protecting group include an alkyl group, a cycloalkyl group, an aralkyl group, a substituted methyl group, a substituted ethyl group, an alkoxycarbonyl group, and an aralkyloxycarbonyl group. Examples of a preferable alkyl group include an alkyl group having 1 to 4 carbon atoms; examples of a preferable substituted methyl group include a methoxymethyl group, a methoxythiomethyl group, a benzyloxymethyl group, a t-butoxymethyl group, and a 2-methoxyethoxymethyl group; examples of a preferable substituted ethyl group include 1-ethoxyethyl and 1-methyl-1-methoxyethyl; examples of a preferable acyl group include an aliphatic acyl group having 1 to 6 carbon atoms such as a formyl group, an acetyl group, a propionyl group, a butyryl group, an isobutyryl group, a valeryl group, and a pivaloyl group; and examples of the alkoxycarbonyl group include an alkoxycarbonyl group having 1 to 4 carbon atoms.

The content of the repeating unit that has an alicyclic hydrocarbon structure not having a polar group and does not exhibit acid degradability is preferably 0 mol % to 40 mol %, and more preferably 0 mol % to 20 mol %, based on all repeating units in the resin (A).

Specific examples of the repeating unit that has an alicyclic hydrocarbon structure not having a polar group and does not exhibit acid degradability are shown below, but the present invention is not limited thereto. In the formula, Ra represents H, CH₃, CH₂OH, or CF₃.

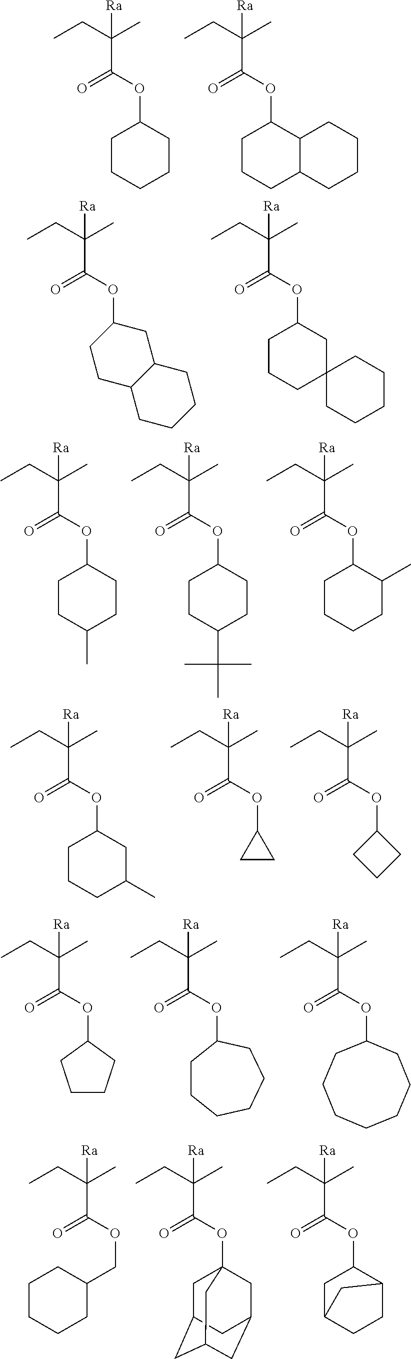

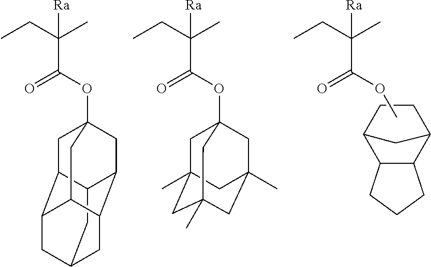

The resin (A) can include various repeating units in addition to the repeating structural unit described above, for controlling dry etching resistance, suitability to a standard developer, substrate adhesion, pattern profile, resolution, heat resistance, sensitivity, and the like.

Examples of such a repeating structural unit include repeating structural units corresponding to the following monomers, but the present invention is not limited thereto.

If the resin (A) includes such repeating structural units, performances required for the resin (A), particularly, (1) solubility with respect to a coating solvent, (2) film formability (glass transition point), (3) alkali developability, (4) film thinning (selection of a hydrophilic or hydrophobic group and an alkali-soluble group), (5) adhesion of an unexposed portion to a substrate, (6) dry etching resistance, and the like can be finely adjusted.

Examples of such monomers include compounds having one addition-polymerizable unsaturated bond selected from acrylic acid esters, methacrylic acid esters, acrylamides, methacrylamides, allyl compounds, vinyl ethers, vinyl esters, and the like.

In addition, other addition-polymerizable unsaturated compounds may be copolymerized so long as these compounds are copolymerizable with the monomers corresponding to the various repeating structural units described above.

The molar ratio of the respective repeating structural units contained in the resin (A) is appropriately set so as to control the dry etching resistance, suitability to a standard developer, substrate adhesion, pattern profile, resolution, heat resistance, sensitivity, and the like of the composition. Here, needless to say, the total content of the respective repeating structural units does not exceed 100 mol %.

When the composition of the present invention is for ArF exposure, it is preferable that the resin (A) substantially not include an aromatic group and include a monocyclic or polycyclic alicyclic hydrocarbon structure, from the viewpoint of transparency to ArF light.

In addition, the resin (A) preferably does not contain a fluorine atom and a silicon atom, from the viewpoint of compatibility with the hydrophobic resin described later.

As the resin (A), a resin in which all repeating units are constituted with a (meth)acrylate-based repeating unit is preferable. In this case, any of a resin in which all repeating units are methacrylate-based repeating units, a resin in which all repeating units are acrylate-based repeating units, and a resin in which all repeating units are methacrylate-based repeating units and acrylate-based repeating units can be used, but the acrylate-based repeating units are preferably 50 mol % or less of all repeating units. It is more preferable to use a copolymer which includes 20 mol % to 50 mol % of (meth)acrylate-based repeating units having an acid-decomposable group, 20 mol % to 50 mol % of (meth)acrylate-based repeating units having a lactone group, 5 mol % to 30 mol % of (meth)acrylate-based repeating units having an alicyclic hydrocarbon structure substituted with a hydroxyl group or a cyano group, and 0 mol % to 20 mol % of other (meth)acrylate-based repeating units.

When the composition of the present invention is irradiated with KrF excimer laser light, electron beams, X-rays, or high energy light rays (EUV and the like) having a wavelength of 50 nm or less, the resin (A) preferably further includes a hydroxystyrene-based repeating unit. More preferably, the resin (A) includes the hydroxystyrene-based repeating unit, a hydroxystyrene-based repeating unit protected with an acid-decomposable group, and an acid-decomposable repeating unit such as (meth)acrylic acid tertiary alkyl ester.

Examples of a preferable hydroxystyrene-based repeating unit having an acid-decomposable group include t-butoxycarbonyloxystyrene, 1-alkoxyethoxystyrene, a repeating unit of (meth)acrylic acid tertiary alkyl ester, and the like, and repeating units of 2-alkyl-2-adamantyl (meth)arcylate and dialkyl(1-adamantyl)methyl (meth)acrylate are more preferable.

The resin (A) of the present invention can be synthesized by a common method (for example, radical polymerization). Example of the general synthesis method include batch polymerization in which polymerization is performed by dissolving polymer materials and initiators in a solvent and heating the resultant, and drop polymerization in which a solution including monomer materials and initiators is added dropwise to a heated solvent for 1 to 10 hours. A preferable method is the drop polymerization. Examples of a reaction solvent include tetrahydrofuran, 1,4-dioxane, ethers such as diisopropyl ether, ketones such as methyl ethyl ketone and methyl isobutyl ketone, ester solvents such as ethyl acetate, amide solvents such as dimethylformamide and dimethylacetamide, and solvents dissolving the composition of the present invention, such as propylene glycol monomethyl ether acetate, propylene glycol monomethyl ether, and cyclohexanone described later. It is more preferable to perform polymerization by using the same solvents as those used in the light sensitive composition of the present invention, and by doing this, the generation of particles during storage can be inhibited.

It is preferable to perform the polymerization reaction in an atmosphere of inert gas such as nitrogen or argon. As the polymerization initiator, a commercially available radical initiator (azo-based initiator, peroxide, or the like) is used to initiate the polymerization. As the radical initiator, an azo-based initiator is preferable, and an azo-based initiator having an ester group, a cyano group, or a carboxyl group is preferable. Examples of preferable azo-based initiators include azobisisobutyronitrile, azobisdimethylvaleronitrile, dimethyl 2,2′-azobis(2-methylpropionate), and the like. The initiator is added as desired or added in divided portions, and then introduced to a solvent after the reaction ends, thereby recovering desired polymers by methods of recovering powder or solids. The concentration of reaction is 5% to 50% by mass, and preferably 10% to 30% by mass. The reaction temperature is generally 10° C. to 150° C., preferably 30° C. to 120° C., and more preferably 60° C. to 100° C.

In order to inhibit the resin from aggregating after the composition is prepared, for example, a step may be added in which the resin is made into a solution by being dissolved in a solvent, and this solution is heated for about 30 minutes to 4 hours at about 30° C. to 90° C., as described in JP2009-037108A.

The weight average molecular weight of the resin (A) of the present invention is preferably 1,000 to 200,000, more preferably 2,000 to 20,000, still more preferably 3,000 to 15,000, and particularly preferably 3,000 to 10,000, as a polystyrene-converted value measured by GPC. If the weight average molecular weight is 1,000 to 200,000, the deterioration of heat resistance, dry etching resistance, developability, and the deterioration of film formability caused by the viscosity increase can be prevented.

The degree of dispersion (molecular weight distribution) of the resin (A) used is generally in a range of from 1 to 3, preferably from 1 to 2.6, more preferably from 1 to 2, and particularly preferably from 1.4 to 2.0. The smaller the molecular weight distribution, the more excellent the resolution, pattern shape, and roughness, and the smoother the side wall of pattern.

One kind of the resin (A) may be used, or two or more kinds thereof may be used in combination.

The proportion of the resin (A) mixed in the composition is preferably 30% to 99% by mass, and more preferably 60% to 95% by mass, based on the total solid content.

(B) Hydrophobic Resin

The composition of the present invention further contains a hydrophobic resin (which will be also referred to as a resin (B) hereinafter). The hydrophobic resin includes at least one of a fluorine atom and a silicon atom.

At least any of the fluorine atom and silicon atom in the hydrophobic resin may be included in the main chain or side chain of the resin.

When the hydrophobic resin includes a fluorine atom, the resin is preferably a resin including an alkyl group having a fluorine atom, a cycloalkyl group having a fluorine atom, or an aryl group having a fluorine atom, as a partial structure having a fluorine atom.

The alkyl group having a fluorine atom is a linear or branched alkyl group in which at least one hydrogen atom has been substituted with a fluorine atom. The number of carbon atoms thereof is preferably 1 to 10, and more preferably 1 to 4, and the alkyl group may further include other substituents.

The cycloalkyl group having a fluorine atom is a monocyclic or polycyclic cycloalkyl group in which at least one hydrogen atom has been substituted with a fluorine atom, and may further include other substituents.

Examples of the aryl group having a fluorine atom include aryl groups such as a phenyl group and naphthyl group in which at least one hydrogen atom has been substituted with a fluorine atom. The aryl group may further include other substituents.

Examples of the alkyl group having a fluorine atom, the cycloalkyl group having a fluorine atom, or the aryl group having a fluorine atom preferably include groups represented by the following general formulae (F2) to (F4), but the present invention is not limited thereto.

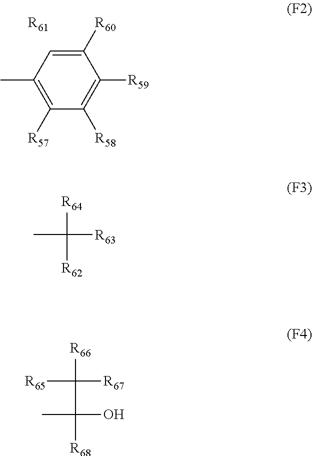

In general formulae (F2) to (F4),

Each of R₅₇ to R₆₈ independently represents a hydrogen atom, a fluorine atom, or a (linear or branched) alkyl group. Here, at least one of R₅₇ to R₆₁, at least one of R₆₂ to R₆₄, and at least one of R₆₅ to R₆₈ represent a fluorine atom or an alkyl group (preferably having 1 to 4 carbon atoms) in which at least one hydrogen atom has been substituted with a fluorine atom.

All of R₅₇ to R₆₁ and R₆₅ to R₆₇ are preferably fluorine atoms. R₆₂, R₆₃, and R₆₈ are preferably fluoroalkyl groups (preferably having 1 to 4 carbon atoms), and more preferably perfluoroalkyl groups having 1 to 4 carbon atoms. When R₆₂ and R₆₃ are perfluoroalkyl groups, R₆₄ is preferably a hydrogen atom. R₆₂ and R₆₃ may form a ring by being linked to each other.

Specific examples of the group represented by general formula (F2) include a p-fluorophenyl group, a pentafluorophenyl group, a 3,5-di(trifluoromethyl)phenyl group, and the like.

Specific examples of the group represented by general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. Among these, a hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable, and a hexafluoroisopropyl group and a heptafluoroisopropyl group are more preferable.

Specific examples of the group represented by general formula (F4) include —C(CF₃)₂OH, —C(C₂F₅)₂OH, —C(CF₃)(CH₃)OH, —CH(CF₃)OH, and the like, and —C(CF₃)₂OH is preferable.

The partial structure having a fluorine atom may directly bind to the main chain, or may bind to the main chain through a group selected from a group consisting of an alkylene group, a phenylene group, an ether bond, a thioether bond, a carbonyl group, an ester bond, an amide bond, a urethane bond, and a ureylene bond, or through a group including a combination of two or more kinds of the above ones.

Examples of preferable repeating units having a fluorine atom include units shown below.

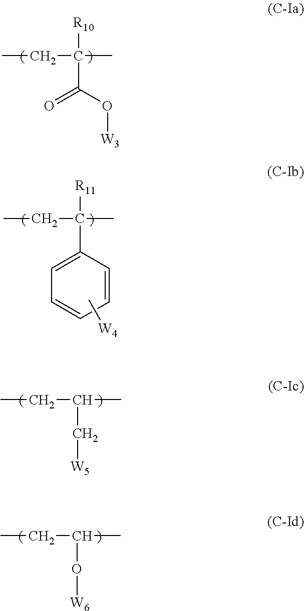

In the formulae, each of R₁₀ and R₁₁ independently represents a hydrogen atom, a fluorine atom, or an alkyl group. The alkyl group is preferably a linear or branched alkyl group having 1 to 4 carbon atoms, and may have a substituent. Examples of the alkyl group having a substituent include a fluorinated alkyl group particularly.

Each of W₃ to W₆ independently represents an organic group containing at least one fluorine atom. Specific examples thereof include atomic groups of (F2) to (F4) described above.

In addition to the above components, the hydrophobic resin may include units shown below as the repeating unit having a fluorine atom.

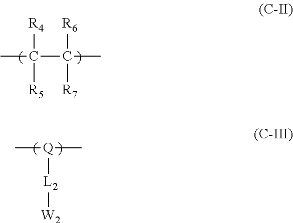

In the formulae, each of R₄ to R₇ independently represents a hydrogen atom, a fluorine atom, or an alkyl group. The alkyl group is preferably a linear or branched alkyl group having 1 to 4 carbon atoms, and may have a substituent. Examples of the alkyl group having a substituent include a fluorinated alkyl group particularly.

Here, at least one of R₄ to R₇ represents a fluorine atom. R₄ and R₅ or R₆ and R₇ may form a ring.

W₂ represents an organic group containing at least one fluorine atom, and specific examples thereof include atomic groups of (F2) to (F4) described above.

L₂ represents a single bond or a divalent linking group. The divalent linking group represents a substituted or unsubstituted aryl group, a substituted or unsubstituted alkylene group, a substituted or unsubstituted cycloalkylene group, —O—, —SO₂—, —CO—, —N(R)— (wherein R represents a hydrogen atom or alkyl), —NHSO₂—, or a divalent linking group including a combination of a plurality of the above ones.

Q represents an alicyclic structure. The alicyclic structure may have a substituent, and may be a monocyclic or polycyclic. If the structure is polycyclic, the structure may be a bridged structure. The monocyclic structure is preferably a cycloalkyl group having 3 to 8 carbon atoms, and examples thereof include a cyclopentyl group, a cyclohexyl group, a cyclobutyl group, a cyclooctyl group, and the like. Examples of the polycyclic structure include groups having a bicyclo, tricyclo, or tetracyclo structure having 5 or more carbon atoms, and a cycloalkyl group having 6 to 20 carbon atoms is preferable. Examples thereof include an adamantyl group, a norbornyl group, a dicyclopentyl group, a tricyclodecanyl group, a tetracyclododecyl group, and the like. A portion of the carbon atoms of the cycloalkyl group may be substituted with hetero atoms such as oxygen atoms. Preferable examples of Q include a norbornyl group, a tricyclodecanyl group, a tetracyclododecyl group, and the like.

The hydrophobic resin may contain a silicon atom.

The hydrophobic resin preferably includes an alkylsilyl structure (preferably a trialkylsilyl group) or a cyclic siloxane structure as a partial structure having a silicon atom.

Specific examples of an alkylsilyl structure or a cyclic siloxane structure include groups represented by the following general formulae (CS-1) to (CS-3).

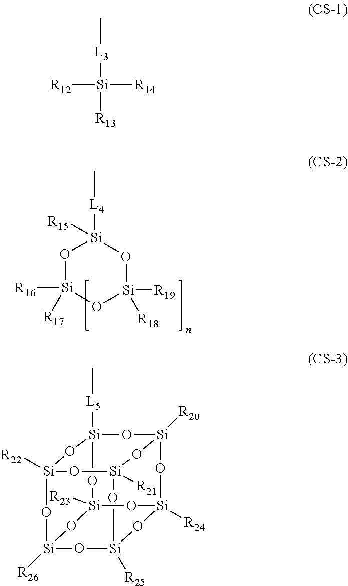

In general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

L₃ to L₅ represent a single bond or a divalent linking group. Examples of the divalent linking group include a single group or a combination of two or more kinds of groups selected from a group consisting of an alkylene group, a phenylene group, an ether bond, a thioether bond, a carbonyl group, an ester bond, an amide bond, a urethane bond, and a ureylene bond.

n represents an integer of 1 to 5, and is preferably an integer of 2 to 4.

The repeating unit having at least one of a fluorine atom and a silicon atom is preferably a (meth)acrylate-based repeating unit.

Specific examples of the repeating unit having at least one of a fluorine atom and a silicon atom will be shown below, but the present invention is not limited thereto. In the specific examples, X₁ represents a hydrogen atom, —CH₃, —F, or —CF₃, and X₂ represents —F or —CF₃.

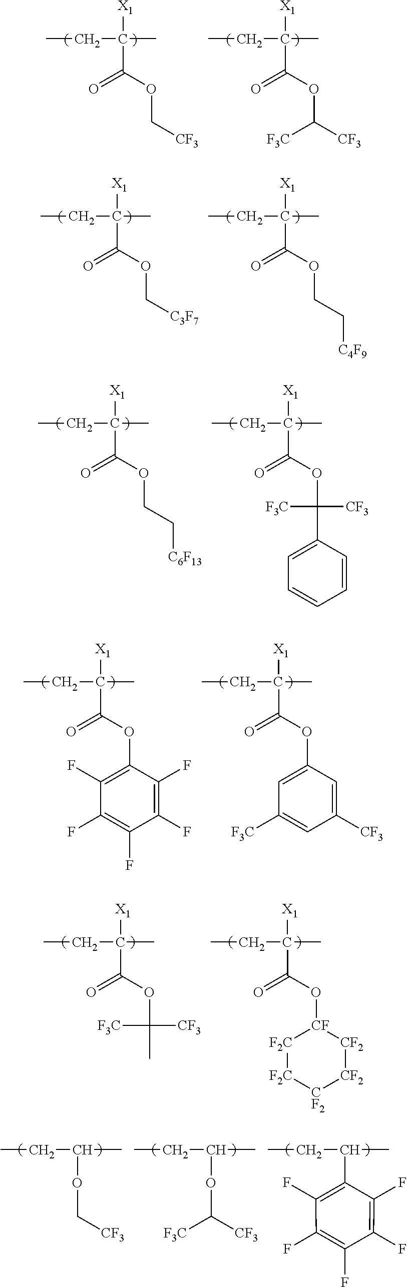

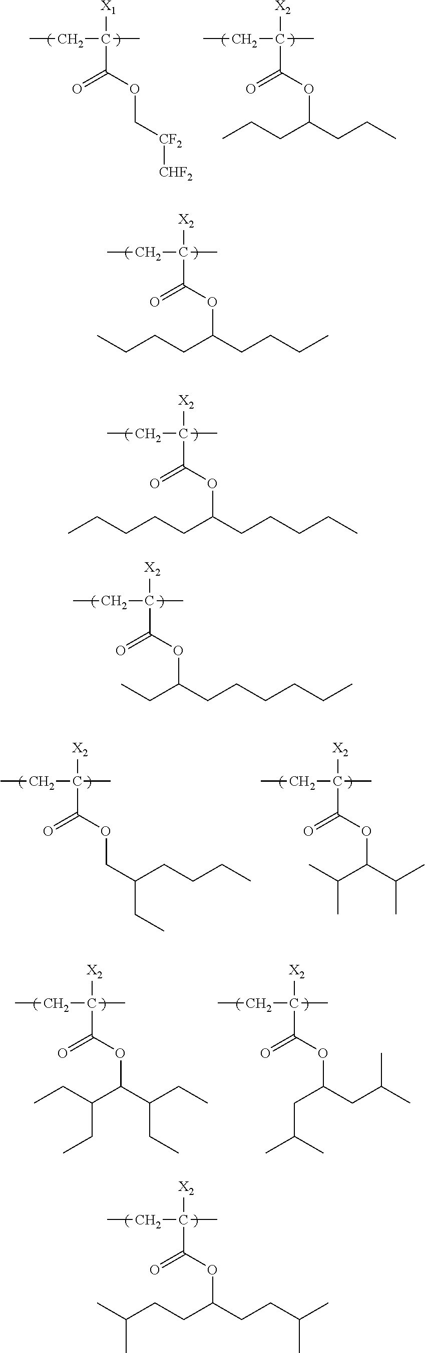

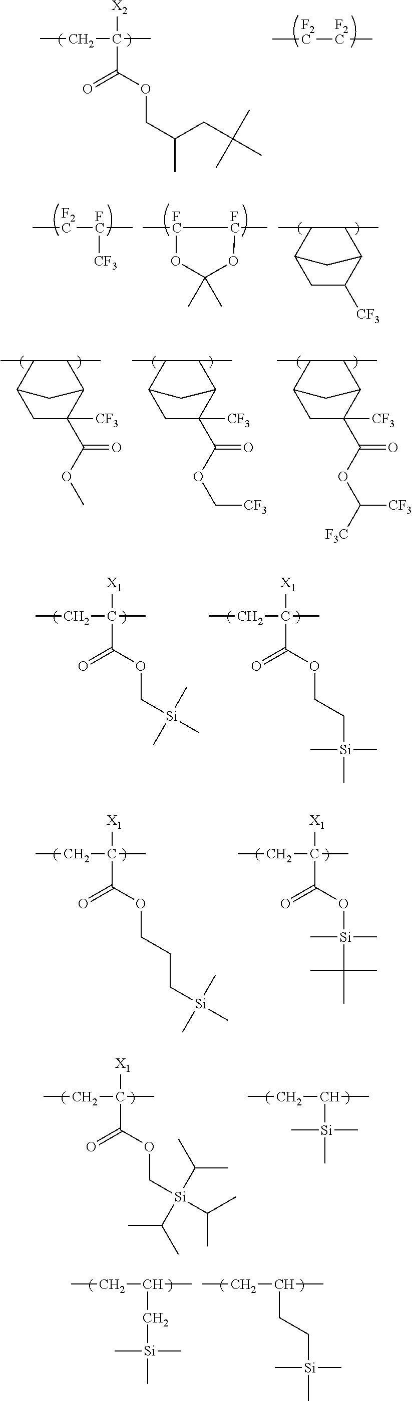

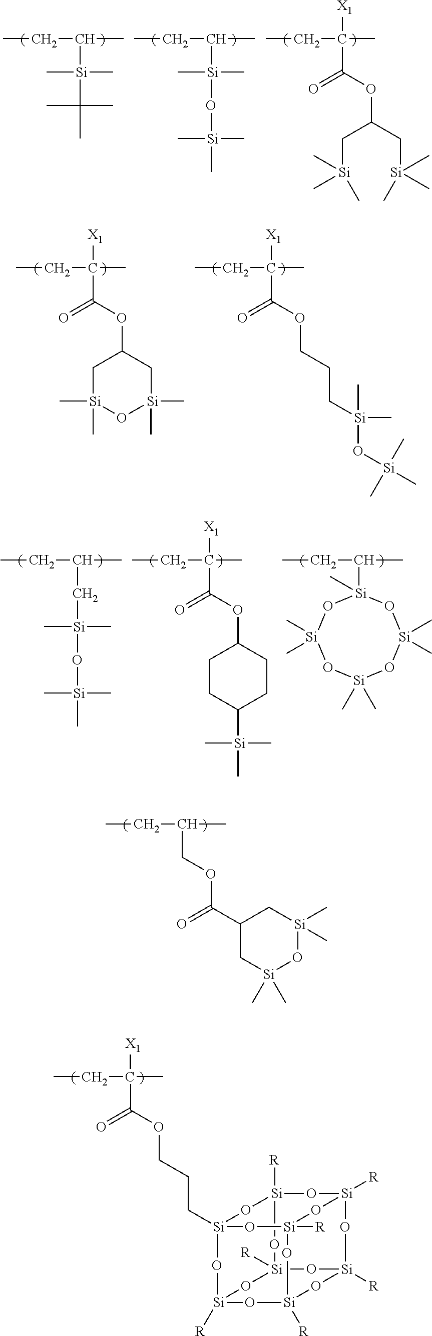

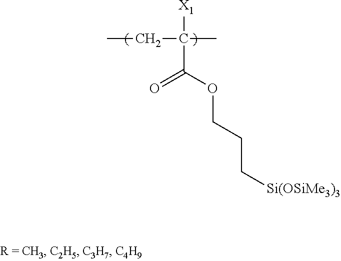

The hydrophobic resin preferably includes a repeating unit (b) having at least one group selected from a group consisting of (x) to (z) shown below.

(x) an alkali-soluble group

(y) a group (polarity converting group) which decomposes by an action of an alkaline developer to increase a solubility of the second resin in the alkaline developer

(z) a group which decomposes by an action of an acid to increase a solubility of the second resin in an alkaline developer

Examples of the types of the repeating unit (b) include the following ones.
A repeating unit (b′) that includes at least one of a fluorine atom and a silicon atom and at least one group selected from a group consisting of the above (x) to (z), in one side chain
A repeating unit (b*) that includes at least one group selected from a group consisting of the (x) to (z) and does not include a fluorine atom and a silicon atom
A repeating unit (b″) that includes at least one group selected from a group consisting of the (x) to (z) in one side chain, and at least one of a fluorine atom and a silicon atom in another side chain different from the above side chain in the same repeating unit

It is more preferable that the hydrophobic resin include the repeating unit (b′) as the repeating unit (b). That is, it is more preferable that the repeating unit (b) including at least one group selected from a group consisting of the (x) to (z) include at least one of a fluorine atom and a silicon atom.

When the hydrophobic resin includes the repeating unit (b*), the hydrophobic resin preferably forms a copolymer with a repeating unit (which is different from the repeating units (b′) and (b″)) having at least one of a fluorine atom and a silicon atom. Moreover, in the repeating unit (b″), the side chain having at least one group selected from a group consisting of the (x) to (z) and the side chain having at least one of a fluorine atom and a silicon atom are preferably in a positional relationship in which these side chains bind to the same carbon atom in the main chain, that is, in a positional relationship as the following Formula (K1).

In the formula, B1 represents a partial structure having at least one group selected from a group consisting of the (x) to (z), and B2 represents a partial structure having at least one of a fluorine atom and a silicon atom.

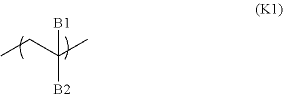

The group selected from a group consisting of the (x) to (z) is preferably an (x) alkali-soluble group or a (z) acid-decomposable group, and more preferably the (z) acid-decomposable group.

Examples of the alkali-soluble group (x) include a phenolic hydroxyl group, a carboxylic group, a fluorinated alcohol group, a sulfonic acid group, a sulfonamide group, a sulfonylimide group, an (alkyl sulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Examples of the preferable alkali-soluble group (x) include a fluorinated alcohol group (preferably a hexafluoroisopropyl), a sulfonimide group, and a bis(carbonyl)methylene group.

The alkali-soluble group (x) is preferably a group having a sulfonamide group represented by the following general formulae (SF1) to (SF2).

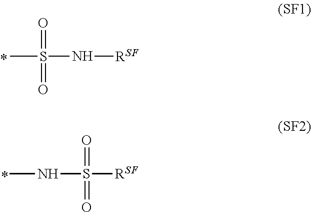

In formula (SF), * represents a direct link, Rf represents an organic group.

The organic group represented by R^{SF} is preferably an organic group having at least one fluorine atom, and more preferably an alkyl group substituted with at least one fluorine atom.

Specifically, the alkyl group represented by R^{SF} is, for example, an alkyl group (here, a group in which 1 or more hydrogen atoms have been substituted with a fluorine atom) having 1 to 15 carbon atoms and a cycloalkyl group (here, a group in which 1 or more hydrogen atoms have been substituted with a fluorine atom) having 3 to 30 carbon atoms, more preferably an alkyl group (here, a group in which 1 or more hydrogen atoms have been substituted with a fluorine atom) having 1 to 12 carbon atoms and a cycloalkyl group (here, a group in which 1 or more hydrogen atoms have been substituted with a fluorine atom) having 3 to 20 carbon atoms, and more preferably an alkyl group (here, a group in which 1 or more hydrogen atoms have been substituted with a fluorine atom) having 1 to 10 carbon atoms and a cycloalkyl group (here, a group in which 1 or more hydrogen atoms are substituted with a fluorine atom) having 3 to 15 carbon atoms.

Specific examples of the repeating unit that includes the sulfonamide group represented by general formula (SF1) or (SF2) will be shown below, but the present invention is not limited thereto.

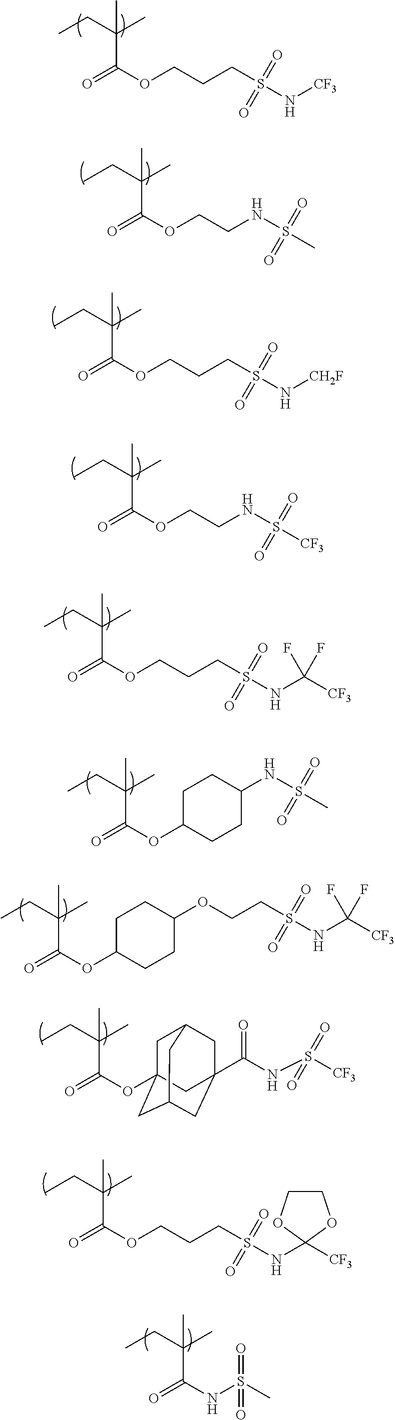

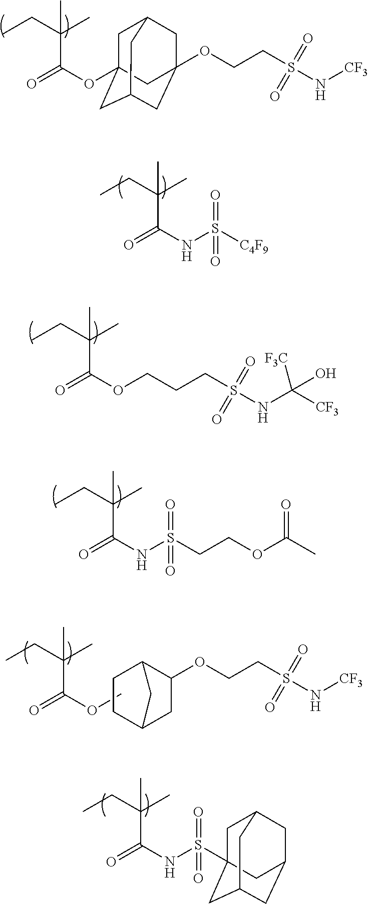

Examples of a repeating unit (bx) having the alkali-soluble group (x) include a repeating unit in which the alkali-soluble group directly binds to the main chain of a resin, such as a repeating unit of acrylic acid or methacrylic acid, a repeating unit in which the alkali-soluble group binds to the main chain of a resin through a linking group, and the like. In addition, a polymerization initiator and a chain transfer agent having an alkali-soluble group can be introduced to the terminal of a polymer chain during polymerization, and any of cases is preferable.

When the repeating unit (bx) is a repeating unit having at least one of a fluorine atom and a silicon atom (that is, when the repeating unit (bx) corresponds to the repeating unit (b′) or (b″)), examples of a partial structure having a fluorine atom in the repeating unit (bx) include the same structures as those exemplified for the repeating unit having at least one of a fluorine atom and a silicon atom, and preferably, the groups represented by the general formulae (F2) to (F4) can be exemplified. Moreover, in this case, examples of the partial structure having a silicon atom in the repeating unit (bx) include the same structures as those exemplified for the repeating unit having at least one of fluorine atom and a silicon atom, and preferably, the groups represented by the general formulae (CS-1) to (CS-3) can be exemplified.

The content of the repeating unit (bx) having the alkali-soluble group (x) is preferably 1 mol % to 50 mol %, more preferably 3 mol % to 35 mol %, and still more preferably 5 mol % to 20 mol %, based on all repeating units in the hydrophobic resin.

Specific examples of the repeating unit (bx) having the alkali-soluble group (x) will be shown below, but the present invention is not limited thereto. In the specific examples, X₁ represents a hydrogen atom, —CH₃, —F, or —CF₃.

In the formula, Rx represents H, CH₃, CF₃, or CH₂OH.

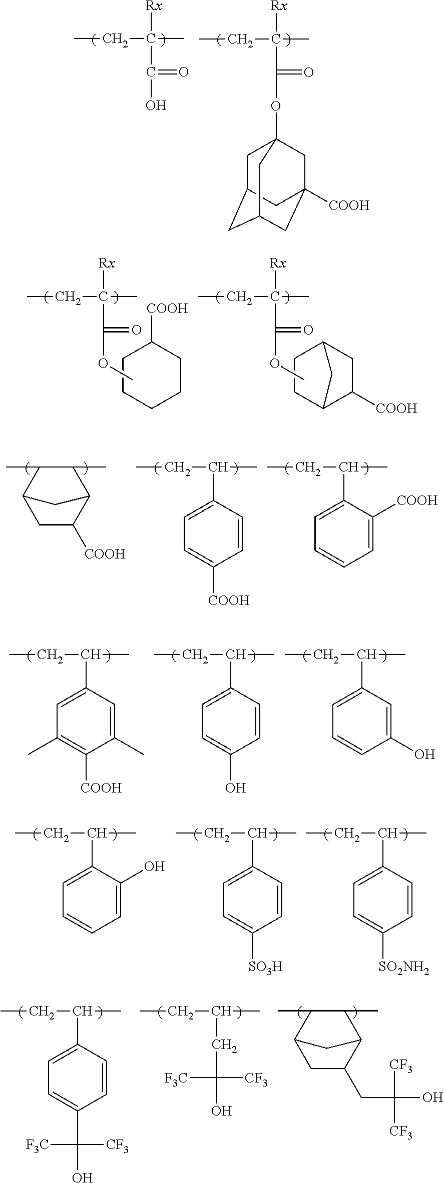

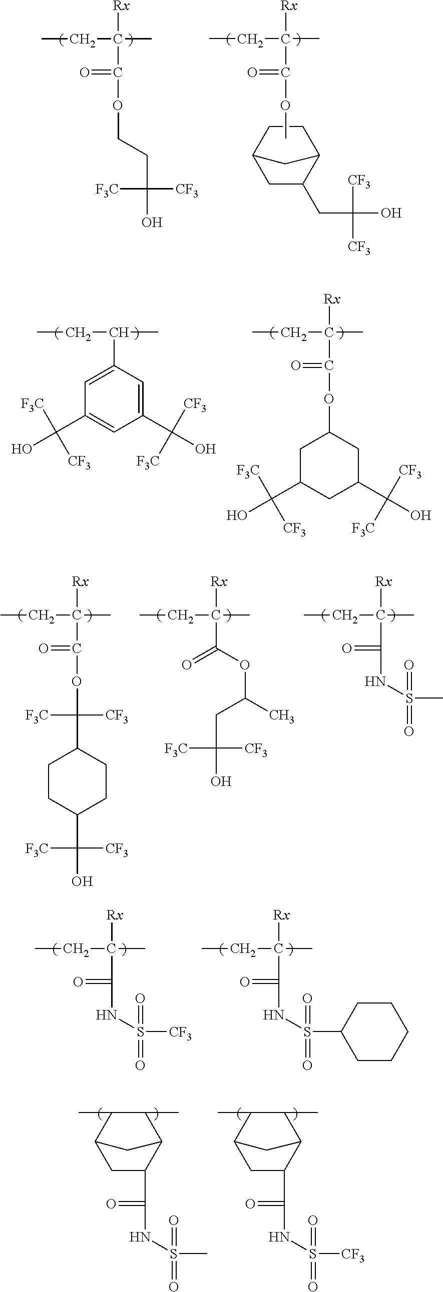

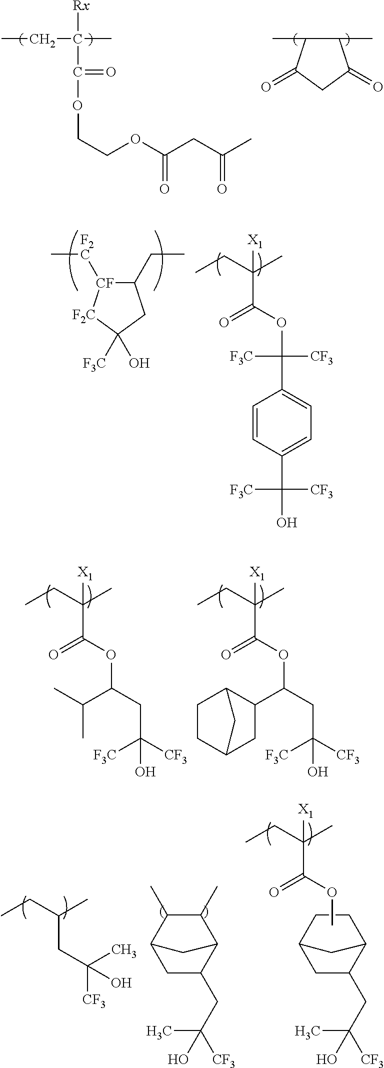

Examples of a polarity converting group (y) include a lactone group, a carboxylic acid ester group (—COO—), an acid anhydride group (—C(O)OC(O)—), an acid imide group (—NHCONH—), a carboxylic acid thioester group (—COS—), a carbonic acid ester group (—OC(O)O—), a sulfuric acid ester group (—OSO₂O—), a sulfonic acid ester group (—SO₂O—), and the like, and a lactone group is preferable.

For the polarity converting group (y), any forms are preferable which include a form in which the polarity converting group (y) is introduced to the side chain of the resin by being included in the repeating unit of acrylic acid ester or methacrylic acid ester, and a form in which a polymerization initiator and a chain transfer agent having the polarity converting group (y) is introduced to the terminal of the polymer chain during polymerization.

Specific examples of a repeating unit (by) having the polarity converting group (y) include repeating units having lactone structures represented by formulae (KA-1-1) to (KA-1-17) described later.

The repeating unit (by) having the polarity converting group (y) preferably corresponds to a repeating unit having at least one of a fluorine atom and a silicon atom (that is, the repeating unit (by) preferably corresponds to the repeating units (b′) and (b″)). The resin having the repeating unit (by) is preferably hydrophobic, particularly in respect of reducing development defects.

Examples of the repeating unit (by) include a repeating unit represented by Formula (K0).

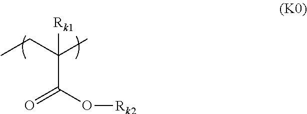

In the formula, Rₖ₁ represents a hydrogen atom, a halogen atom, a hydroxyl group, an alkyl group, a cycloalkyl group, an aryl group, or a group including a polarity converting group.

Rₖ₂ represents an alkyl group, a cycloalkyl group, an aryl group, or a group including a polarity converting group.

Here, at least one of Rₖ₁ and Rₖ₂ represents a group including a polarity converting group.

The polarity converting group represents a group of which the solubility increases in the alkaline developer by being decomposed by the action of the alkaline developer, as described above. The polarity converting group is preferably a group represented by X in a partial structure represented by general formula (KA-1) or (KB-1).

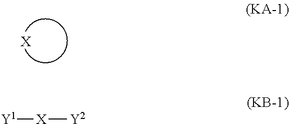

X in general formula (KA-1) or (KB-1) represents a carboxylic acid ester: —COO—, an acid anhydride group: —C(O)OC(O)—, an acid imide group: —NHCONH—, a carboxylic acid thioester group: —COS—, a carbonic acid ester group: —OC(O)O—, a sulfuric acid ester group: —OSO₂O—, and a sulfonic acid ester group: —SO₂O—.

Y¹ and Y² may be the same as or different from each other, and represent an electron-attracting group.

Having a group including the partial structure represented by general formula (KA-1) or (KB-1), the repeating unit (by) includes a group of which the solubility increases in a preferable alkaline developer. However, when the partial structure does not have a direct link as the case of the partial structure represented by general formula (KA-1) and the partial structure represented by (KB-1) wherein Y¹ and Y² are monovalent groups, the group having the partial structure is a group which includes a group having a valency of 1 or more from which at least one arbitrary hydrogen atom in the partial structure has been removed.

The partial structure represented by general formula (KA-1) or (KB-1) is linked to the main chain of the hydrophobic resin at an arbitrary position through a substituent.

The partial structure represented by general formula (KA-1) is a structure forming a ring structure with a group represented by X.

X in general formula (KA-1) is preferably a carboxylic acid ester group (that is, a case of forming a lactone ring structure as KA-1), an acid anhydride group, and a carbonic acid ester, and more preferably a carboxylic acid ester group.

The ring structure represented by general formula (KA-1) may have a substituent. For example, the ring structure may have nka of a substituent Zₖₐ₁.

When there is a plurality of Zₖₐ₁s, each Zₖₐ₁ independently represents a hydrogen atom, an alkyl group, a cycloalkyl group, an ether group, a hydroxyl group, an amide group, an aryl group, a lactone ring group, or an electron-attracting group.

The Zₖₐ₁s may form a ring by binding to each other. Examples of the ring that the Zₖₐ₁s form by binding to each other include a cycloalkyl ring, a hetero ring (such as a cyclic ether ring and a lactone ring), and the like.

nka represents an integer of 0 to 10. The integer is preferably 0 to 8, more preferably 0 to 5, still more preferably 1 to 4, and most preferably 1 to 3.

The electron-attracting group represented by Zₖₐ₁ is the same as the electron-attracting group represented by Y¹ and Y² described later, and may be substituted with other electron-attracting groups.

Zₖₐ₁ is preferably an alkyl group, a cycloalkyl group, an ether group, a hydroxyl group, or an electron-attracting group, and more preferably an alkyl group, a cycloalkyl group, or an electron-attracting group. The ether group is preferably substituted with an alkyl group, a cycloalkyl group, and the like. That is, the ether group is preferably an alkyl ether group, or the like. The electron-attracting group has the same definition as described above.

Examples of the halogen atom represented by Zₖₐ₁ include a fluorine atom, a chlorine atom, a bromine atom, an iodine atom, and the like, and a fluorine atom is preferable.

The alkyl group represented by Zₖₐ₁ may have a substituent and may be linear or branched. The number of carbon atoms of the linear alkyl group is preferably 1 to 30, and more preferably 1 to 20. Examples of the linear alkyl group include a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group, and the like. The number of carbon atoms of the branched alkyl group is preferably 3 to 30, and more preferably 3 to 20. Examples of the branched alkyl group include an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanyl group, and the like. Among these, a methyl group, an ethyl group, an n-propyl group, an i-propyl group, an n-butyl group, an i-butyl group, a t-butyl group, and the like having 1 to 4 carbon atoms are preferable.

The cycloalkyl group represented by Zₖₐ₁ may have a substituent, and may be monocyclic or polycyclic. When the cycloalkyl group is polycyclic, the cycloalkyl group may be a bridged group. That is, in this case, the cycloalkyl group may have a bridged structure. The monocyclic cycloalkyl group is preferably a cycloalkyl group having 3 to 8 carbon atoms, and examples thereof include a cyclopropyl group, a cyclopentyl group, a cyclohexyl group, a cyclobutyl group, a cyclooctyl group, and the like. Examples of the polycyclic cycloalkyl group include groups having a bicyclo, tricyclo, or tetracyclo structure having 5 or more carbon atoms. A cycloalkyl group having 6 to 20 carbon atoms is preferable, and the examples thereof include an adamantyl group, a norbornyl group, an isobornyl group, a camphanyl group, a dicyclopentyl group, an α-pinenyl group, a tricyclodecanyl group, a tetracyclododecyl group, an androstanyl group, and the like. As the cycloalkyl group, the following structures are also preferable. A portion of the carbon atoms in the cycloalkyl group may be substituted with hetero atoms such as oxygen atoms.

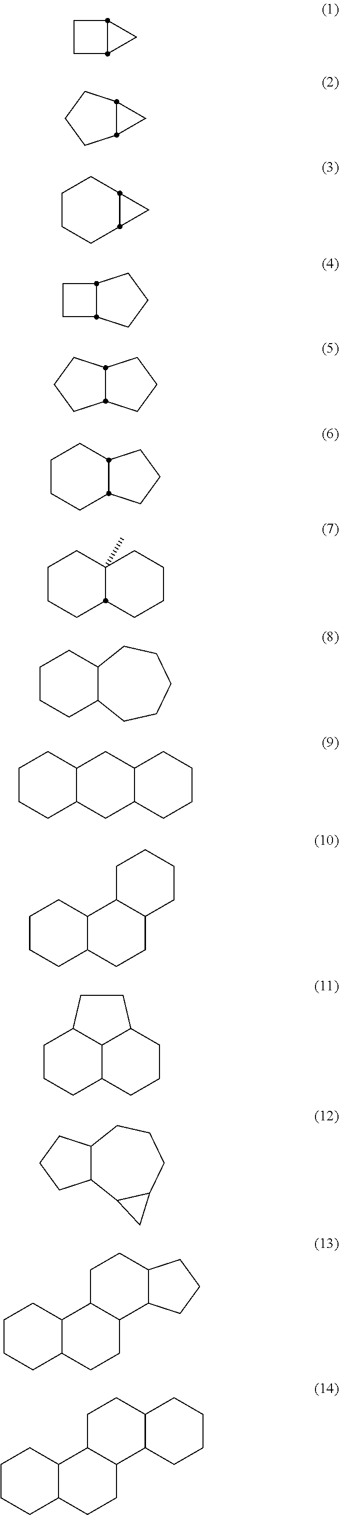

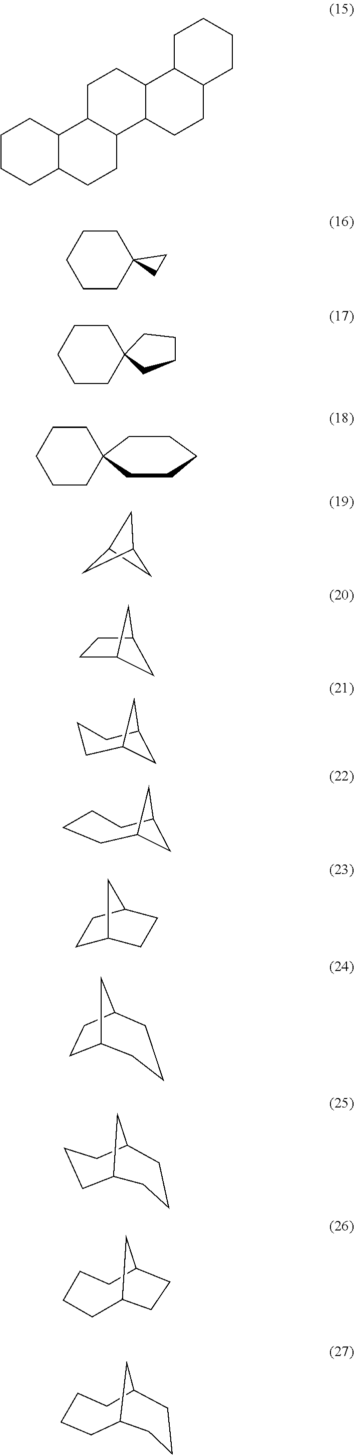

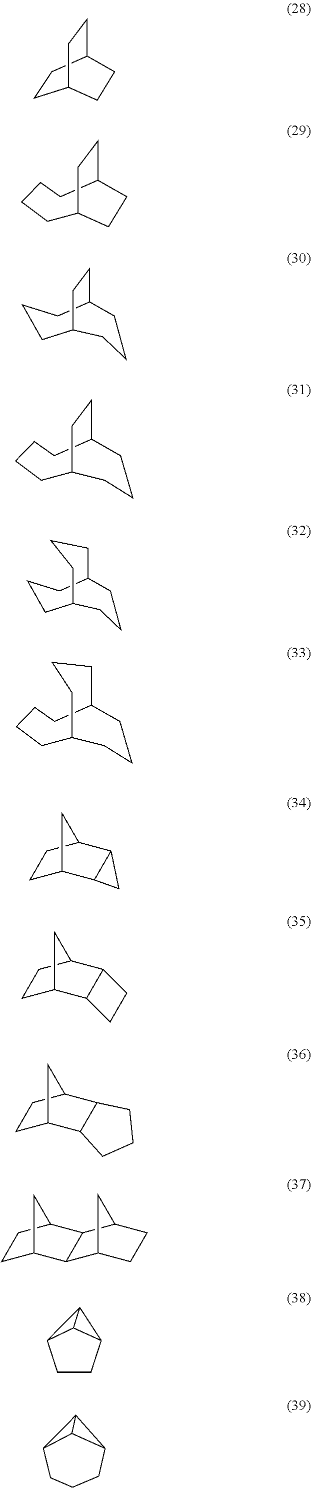

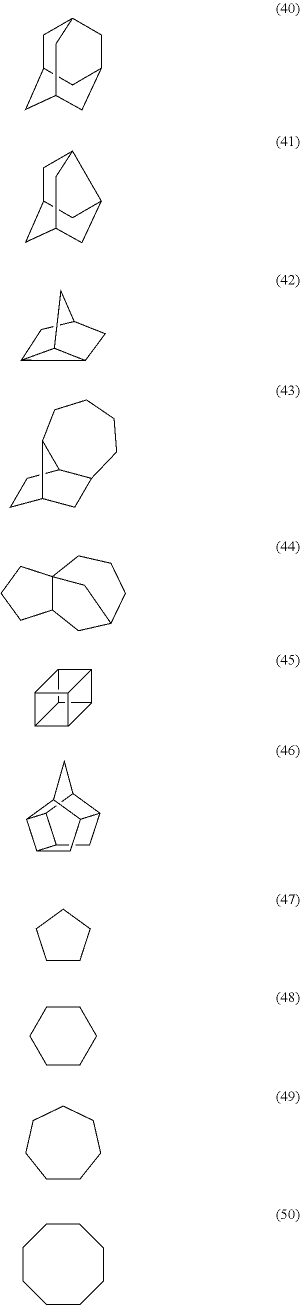

Preferable examples of the above alicyclic portion include an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group, and a cyclododecanyl group. Among these, an adamantyl group, a decalin group, a norbornyl group, a cedrol group, a cyclohexyl group, a cycloheptyl group, a cyclooctyl group, a cyclodecanyl group, and a cyclododecanyl group, and a tricyclodecanyl group are more preferable.

Examples of the substituent of these alicyclic structures include an alkyl group, a halogen atom, a hydroxyl group, an alkoxy group, a carboxyl group, and an alkoxycarbonyl group. As the alkyl group, lower alkyl groups such as a methyl group, an ethyl group, a propyl group, an isopropyl group, and a butyl group are preferable. The alkyl group more preferably represents a methyl group, an ethyl group, a propyl group, or an isopropyl group. Preferable example of the above alkoxy group include alkoxy groups having 1 to 4 carbon atoms such as a methoxy group, an ethoxy group, a propoxy group, a butoxy group, and the like. Examples of the substituent that the alkyl group and the alkoxy group may have include a hydroxyl group, a halogen atom, an alkoxy group (preferably having 1 to 4 carbon atoms), and the like.

Examples of other substituents that the above groups may further have include a hydroxyl group, a halogen atom (fluorine, chlorine, bromine, and iodine), a nitro group, a cyano group, alkyl groups described above, an alkoxy group such as a methoxy group, an ethoxy group, a hydroxyethoxy group, a propoxy group, a hydroxypropoxy group, an n-butoxy group, an isobutoxy group, a sec-butoxy group, and a t-butoxy group, an alkoxycarbonyl group such as a methoxycarbonyl group and an ethoxycarbonyl group, an aralkyl group such as a benzyl group, a phenethyl group, and a cumyl group, an aralkyloxy group, an acyl group such as a formyl group, an acetyl group, a butyryl group, a benzoyl group, a cyanamyl group, and a valeryl group, an acyloxy group such as a butyryloxy group, alkenyl groups described above, an alkenyloxy group such as a vinyloxy group, a propenyloxy group, an allyloxy group, and a butenyloxy group, aryl groups described above, an aryloxy group such as a phenoxy group, an aryloxycarbonyl group such as a benzoyloxy group, and the like.

X in general formula (KA-1) is preferably a carboxylic acid ester, and the partial structure represented by general formula (KA-1) is preferably a 5 to 7-membered lactone ring.

As shown in (KA-1-1) to (KA-1-17) below, it is preferable that other ring structures be condensed with the 5 to 7-membered lactone ring as the partial structure represented by general formula (KA-1) while forming a bicyclo structure or a spiro structure.

Examples of surrounding ring structures to which the ring structure represented by general formula (KA-1) may bind includes the ring structures in (KA-1-1) to (KA-1-17) below or ring structures based on these structures.

As the structures containing the lactone ring structures represented by general formula (KA-1), the structure represented by any of (KA-1-1) to (KA-1-17) below is preferable, and the lactone structure may directly bind to the main chain. Preferable structures are (KA-1-1), (KA-1-4), (KA-1-5), (KA-1-6), (KA-1-13), (KA-1-14), and (KA-1-17).

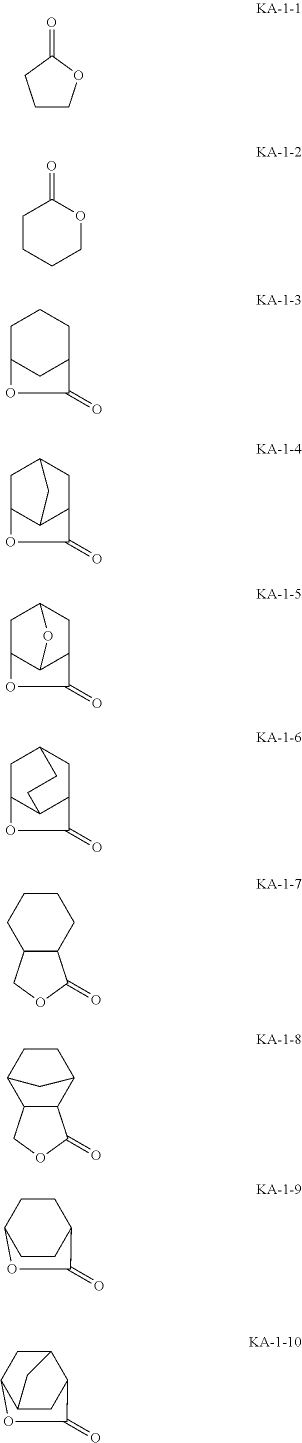

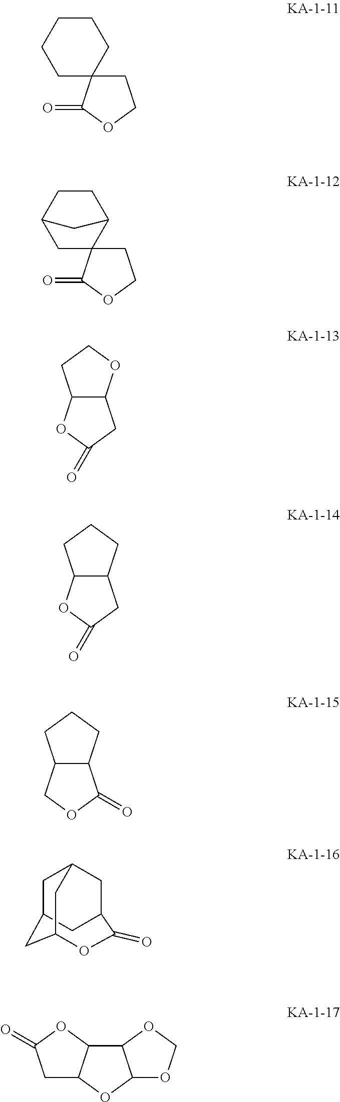

The structures containing the above lactone ring structures may or may not have a substituent. Examples of preferable substituents include the same substituent as the substituent Zₖₐ₁ that the ring structure represented by the general formula (KA-1) may have.

Preferable examples of X of general formula (KB-1) include a carboxylic acid ester group (—COO—).

Each of Y¹ and Y² in general formula (KB-1) independently represents an electron-attracting group.

The electron-attracting group is the partial structure represented by the following formula (EW). In Formula (EW), * represents a direct link that is directly linked to (KA-1) or a direct link that is directly linked to X in (KB-1).

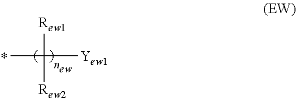

In Formula (EW),

n_{ew} is a number of repetitions of the linking group represented by —C(R_{ew1})(R_{ew2})—, and represents an integer of 0 or 1. When n_{ew} is 0, this represents a single bond and shows that Y_{ew1} binds directly.

Examples of Y_{ew1} include a halogen atom, a cyano group, a nitrile group, a nitro group, a halo(cyclo)alkyl group or a haloaryl group represented by —C(R^{f1})(R_{f2})—R_{f3}, an oxy group, a carbonyl group, a sulfonyl group, a sulfinyl group, and a combination thereof. The electron-attracting group may have the following structures, for example. The “halo(cyclo)alkyl group” represents an alkyl group and a cycloalkyl group in which at least a portion thereof has been halogenated, and the “haloaryl group” represents an aryl group in which at least a portion thereof has been halogenated. In the following structural formulae, each of R_{ew3} and R_{ew4} independently represents an arbitrary structure. No matter what structure R_{ew3} and R_{ew4} have, the partial structure represented by Formula (EW) includes the electron-attracting group. For example, the partial structure may be linked to the main chain of the resin, and is preferably an alkyl group, a cycloalkyl group, or a alkyl fluoride group.

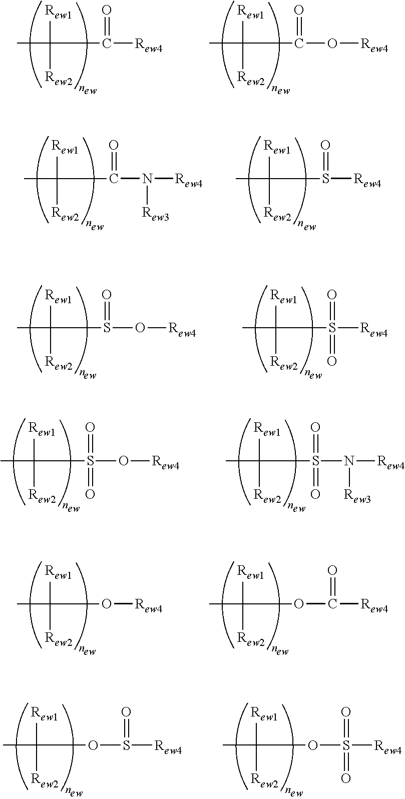

When Y_{ew1} is a group having a valency of 2 or more, the remaining direct link forms a bond with an arbitrary atom or substituent. At least any group of Y_{ew1}, Rew₁ and R_{ew2} may be linked to the main chain of the hydrophobic resin through another substituent.

Y_{ew1} is preferably a halogen atom, or a halo(cyclo)alkyl group or haloaryl group represented by —C(R_{f1})(R_{f2})—R_{f3}.

Each of R_{ew1} and R_{ew2} independently represents an arbitrary substituent, and represents a hydrogen atom, an alkyl group, a cycloalkyl group, or an aryl group, for example.

At least two of R_{ew1}, R_{ew2}, and Y_{ew1} may form a ring by being linked to each other.

Here, R_{f1} represents a halogen atom, a perhaloalkyl group, a perhalocycloalkyl group, or a perhaloaryl group, more preferably a fluorine atom, a perfluoroalkyl group, or a perfluorocycloalkyl group, and still more preferably a fluorine atom or a trifluoromethyl group.

Each of R_{f2} and R_{f3} independently represents a hydrogen atom, a halogen atom or an organic group, and R_{f2} and R_{f3} may form a ring by being linked to each other. The organic group represents an alkyl group, a cycloalkyl group, or an alkoxy group, for example. Rₙ and R_{f1} more preferably represent the same group, or form a ring by being linked to R_{f3}.

R_{f1} to R_{f3} may form a ring by being linked to each other, and examples of the formed ring include a (halo)cycloalkyl ring, a (halo)aryl ring, and the like.

Examples of the (halo)alkyl group in R_{f1} to R_{f3} include the alkyl group in Zₖₐ₁ described above and a structure formed by the halogenation of this alkyl group.

Examples of the (per)halocycloalkyl group and (per)haloaryl group in R_{f1} to R_{f3} or in the ring that R_{f1} and R_{f3} form by being linked to each other include a structure formed by the halogenation of the cycloalkyl group in Zₖₐ₁ described above, and more preferably a fluorocycloalkyl group represented by —C₍ₙ₎F₍₂ₙ₋₂₎H and a perfluoraryl group represented by —C₍ₙ₎F₍ₙ₋₁₎. Herein, n which is the number of carbon atoms is not particularly limited, but is preferably 5 to 13, and more preferably 6.

Preferable examples of the ring that at least two of R_{ew1}, R_{ew2}, and Y_{ew1} form by being linked to each other include a cycloalkyl group or a heterocyclic group. As the heterocyclic group, a lactone ring group is preferable. Examples of the lactone ring include structures represented by Formulae (KA-1-1) to (KA-1-17) described above.

The repeating unit (by) may include a plurality of partial structures represented by general formula (KA-1), a plurality of partial structures represented by general formula (KB-1), or both the partial structures represented by general formulae (KA-1) and (KB-1).

A portion or all of the partial structure of general formula (KA-1) may also serve as the electron-attracting group represented by Y¹ or Y² in general formula (KB-1). For example, when X of general formula (KA-1) is a carboxylic acid ester group, this carboxylic acid ester group can also function as the electron-attracting group represented by Y¹ or Y² in general formula (KB-1).

When the repeating unit (by) corresponds to the repeating unit (b*) or the repeating unit (b″) and includes the partial structure represented by general formula (KA-1), the partial structure represented by general formula (KA-1) is more preferably a partial structure having a polarity converting group which is represented by —COO— in the structure represented by general formula (KA-1).

The repeating unit (by) can be a repeating unit having a partial structure represented by general formula (KY-0).

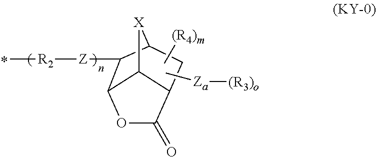

In general formula (KY-0),

each R₂ independently represents an alkylene group or a cycloalkylene group.

R₃ represents a hydrocarbon group in which a portion or all of hydrogen atoms on constituent carbon have been substituted with fluorine atoms.

When m≧2, each R₄ independently represents a halogen atom, a cyano group, a hydroxy group, an amide group, an alkyl group, a cycloalkyl group, an alkoxy group, a phenyl group, an acyl group, an alkoxycarbonyl group, or a group represented by R—C(═O)— or R—C(═O)O—. Herein, R represents an alkyl group or a cycloalkyl group. When m≧2, two or more R₄s may form a ring by binding to each other.

X represents an alkylene group, a cycloalkylene group, an oxygen atom, or a sulfur atom.

Each of Z and Za independently represents a single bond, an ether bond, an ester bond, an amide bond, a urethane bond, or a urea bond.

* represents a direct link to the main chain or side chain of the resin (B).

o represents an integer of 1 to 7.

m represents an integer of 0 to 7.

n represents an integer of 0 to 5.

The structure of —R₂—Z— is preferably a structure represented by —(CH₂)₁—COO— (1 represents an integer of 1 to 5).

The preferable range of the number of carbon atoms and specific examples of the alkylene group or cycloalkylene group represented by R₂ is the same as those described for the alkylene group or cycloalkylene group in Rt of general formula (AI).

The number of carbon atoms of a linear, branched, or cyclic hydrocarbon group represented by R₃ is preferably 1 to 30, and more preferably 1 to 20 in a case of the linear hydrocarbon group. In a case of the branched hydrocarbon group, the number of carbon atoms is preferably 3 to 30, and more preferably 3 to 20. In a case of the cyclic hydrocarbon group, the number of carbon atoms is 6 to 20. Specific examples of R₃ include the specific examples of the alkyl group and cycloalkyl group represented by Zₖₐ₁ described above.

The preferable number of carbon atoms and specific examples of the alkyl group and cycloalkyl group represented by R₄ and R are the same as those described for the alkyl group and cycloalkyl group represented by Zₖₐ₁ described above.

The acyl group represented by R₄ preferably includes 1 to 6 carbon atoms, and examples thereof include a formyl group, an acetyl group, a propionyl group, a butyryl group, an isobutyryl group, a valeryl group, a pivaloyl group, and the like.

Examples of an alkyl moiety in the alkoxy group and alkoxycarbonyl group represented by R₄ include a linear, branched, or cyclic alkyl moiety. The preferable number of carbon atoms and specific examples of the alkyl moiety are the same as those described for the alkyl group and cycloalkyl group represented by Zₖₐ₁ described above.

The preferable number of carbon atoms and specific examples of the alkylene group and cycloalkylene group represented by X are the same as those described for the alkylene group and cycloalkylene group represented by R₂.

Examples of specific structures of the repeating unit (by) also include repeating units having partial structures shown below.

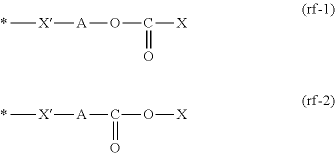

In general formulae (rf-1) and (rf-2),

X′ represents an electron-attracting substituent, which is preferably a carbonyloxy group, an oxycarbonyl group, an alkylene group substituted with a fluorine atom, or a cycloalkylene group substituted with a fluorine atom.

A represents a single bond or a divalent linking group represented by —C(Rx)(Ry)—. Herein, each of Rx and Ry independently represents a hydrogen atom, a fluorine atom, an alkyl group (which preferably has 1 to 6 carbon atoms and may be substituted with a fluorine atom and the like), or a cycloalkyl group (which preferably has 5 to 12 carbon atoms and may be substituted with a fluorine atom and the like). Rx and Ry are preferably a hydrogen atom, an alkyl group, or an alkyl group substituted with a fluorine atom.

X represents an electron-attracting group, and specific examples thereof include the electron-attracting group represented by Y¹ and Y² described above. The electron-attracting group is preferably an alkyl fluoride group, a cycloalkyl fluoride group, an aryl group substituted with a fluorine atom or an alkyl fluoride group, an aralkyl group substituted with a fluorine atom or an alkyl fluoride group, a cyano group, or a nitro group.

* represents a direct line to the main chain or side chain of the resin. That is, * represents a direct link that is linked to the main chain of the resin through a single bond or a linking group.

When X′ is a carbonyloxy group or an oxycarbonyl group, A is not a single bond.

The polarity converting group is decomposed by the action of an alkaline developer, and the polarity thereof is converted, whereby a backward contact angle between the resin composition film and water after alkali development can be reduced. The reduction of the backward contact angle between the film and water after alkali development is preferable from the viewpoints of inhibiting developments defects.

The backward contact angle between the resin composition film and water after alkali development is preferably 50° or less, more preferably 40° or less, still more preferably 35° or less, and most preferably 30° or less, at a temperature of 23±3° C. and a humidity of 45±5%.

The backward contact angle is a contact angle that is measured when a contact line in a droplet-substrate interface recedes. generally, it is known that the backward contact angle is useful for simulating how easily a droplet moves in a dynamic state. In brief, after a droplet discharged from the tip of a needle is attached onto a substrate, this drop is taken into the needle again, and the contact angle shown when the interface of the droplet recedes is defined as the backward contact angle. generally, the backward contact angle can be measured using a method of measuring a contact angle which is called an expanding-contracting method.

The backward contact angle of a film after alkali development is a contact angle which is measured for the film shown below by the expanding-contracting method described in examples described later. That is, ARC29A (available from NISSAN CHEMICAL INDUSTRIES, LTD.) for forming an organic antireflection film is coated onto a silicon wafer (8 inch bore), followed by baking at 205° C. for 60 seconds, thereby forming an antireflection film having a film thickness of 98 nm. The composition of the present invention is coated onto this antireflection film, followed by baking at 120° C. for 60 seconds, thereby forming a film having a film thickness of 120 nm. This film is developed for 30 seconds with an aqueous tetramethylammonium hydroxide solution (2.38% by mass) and then rinsed with pure water, followed by spin drying, thereby forming a film. The contact angle is measured for this film by the expanding-contracting method to obtain the backward contact angle.

The hydrolysis rate of the hydrophobic resin with respect to an alkaline developer is preferably 0.001 nm/sec or higher, more preferably 0.01 nm/sec or higher, still more preferably 0.1 nm/sec or higher, and most preferably 1 nm/sec or higher.

Herein, the hydrolysis rate of the hydrophobic resin with respect to an alkaline developer is a rate in which the thickness of a resin film formed of only the hydrophobic resin is reduced with respect to TMAH (an aqueous tetramethylammonium hydroxide solution) at 23° C.

The repeating unit (by) is more preferably a repeating unit having at least two or more polarity converting groups.

When the repeating unit (by) has at least two polarity converting groups, it is preferable that the repeating unit (by) have a partial structure having two polarity converting groups, which is represented by the following general formula (KY-1). When the structure represented by general formula (KY-1) does not include a direct link, the structure is a group having a group that has a valency of one or more from which at least one arbitrary hydrogen atom has been removed.

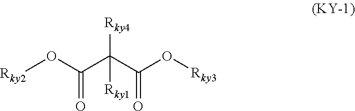

In general formula (KY-1),

each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amide group, or an aryl group. R_{ky1} and R_{ky4} may form a double bond by binding to the same atom, and for example, R_{ky1} and R_{ky4} may form a portion (═O) of a carbonyl group by binding to the same oxygen atom.

Each of R_{ky2} and R_{ky3} is independently an electron-attracting group. Alternatively, R_{ky1} and R_{ky2} are linked to form a lactone ring, and R_{ky3} is an electron-attracting group. As the lactone ring formed, the structures of the (KA-1-1) to (KA-1-17) are preferable. Examples of the electron-attracting group include the same group as Y₁ and Y₂ in the Formula (KB-1), which is preferably a halogen atom or a halo(cyclo)alkyl group or haloaryl group represented by the Formula —C(R_{f1})(R_{f2})—R_{f3}. Preferably, R_{ky3} is a halogen atom or a halo(cyclo)alkyl group or haloaryl group represented by the —C(R_{f1})(R_{f2})—R_{f3}, and R_{ky2} forms a lactone ring by being linked to R_{ky1} or is an electron-attracting group that does not have a halogen atom.

R_{ky1}, R_{ky2}, and R_{ky4} may form a monocyclic or polycyclic structure by being linked to each other respectively.

Specific examples of R_{ky1} and R_{ky4} include the same group as Zₖₐ₁ in Formula (KA-1).

As the lactone ring that R_{ky1} and R_{ky2} form by being linked to each other, the structures of the (KA-1-1) to (KA-1-17) are preferable. Examples of the electron-attracting group include the same groups as Y¹ and Y² in the Formula (KB-1).

The repeating unit (b) is not particularly limited as long as the repeating unit (b) is obtained by polymerization such as addition polymerization, condensation polymerization, and addition condensation. However, the repeating unit (b) is preferably obtained by addition polymerization of a carbon-carbon double bond. Examples of the repeating unit (b) include an acrylate-based repeating unit (which also includes repeating units having a substituent in an α position or β position), a styrene-based repeating unit (which also includes repeating units having a substituent in an α position or β position), a vinyl ether-based repeating unit, a norbornene-based repeating unit, a repeating unit of maleic acid derivatives (maleic anhydride and a derivative thereof, maleimide, and the like), and the like. Among these, an acrylate-based repeating unit, a styrene-based repeating unit, a vinyl ether-based repeating unit, and a norbornene-based repeating unit are preferable, an acrylate-based repeating unit, a vinyl ether-based repeating unit, and a norbornene-based repeating unit are more preferable, and an acrylate-based repeating unit is most preferable.

When the repeating unit (by) is a repeating unit having at least one of a fluorine atom and a silicon atom (that is, when the repeating unit (by) corresponds to the repeating unit (b′) or (b″)), examples of a partial structure having a fluorine atom in the repeating unit (by) includes the same structures that were exemplified for the repeating unit having at least one of a fluorine atom and a silicon atom, which are preferably the groups represented by the general formulae (F2) to (F4). In this case, examples of a partial structure having a silicon atom in the repeating unit (by) includes the same structures that were exemplified for the repeating unit having at least one of a fluorine atom and a silicon atom, which are preferably groups represented by the general formulae (CS-1) to (CS-3).

Monomers corresponding to the repeating unit (by) having a group of which the solubility increases in an alkaline developer can be synthesized by methods disclosed in US2010/0152400A, WO2010/067905A, or WO2010/067898A.

The content of the repeating unit (by) in the hydrophobic resin is preferably 10 mol % to 100 mol %, more preferably 20 mol % to 99 mol %, still more preferably 30 mol % to 97 mol %, and most preferably 40 mol % to 95 mol %, based on all repeating units in the hydrophobic resin.

Specific examples of the repeating unit (by) having a group of which the solubility increases in an alkaline developer will be shown below, but the present invention is not limited thereto. Ra represents a hydrogen atom, a fluorine atom, a methyl group, or a trifluoromethyl group.

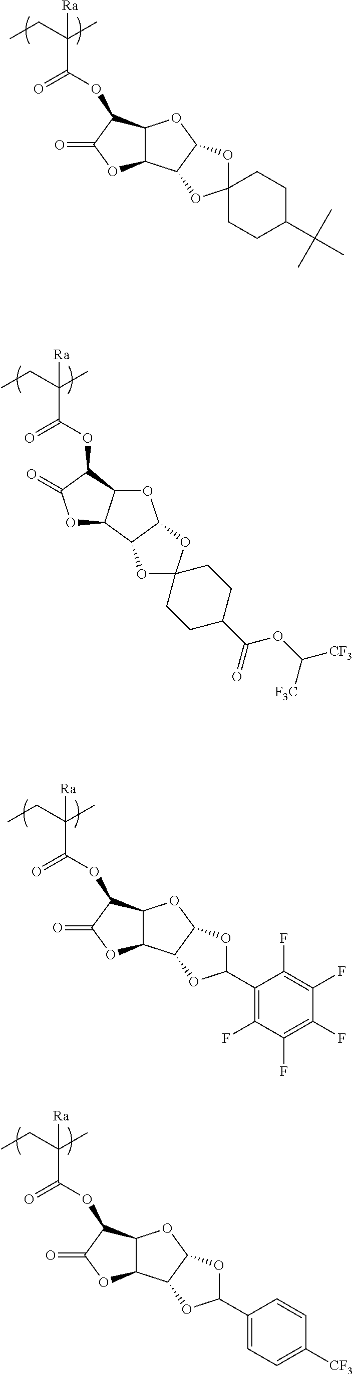

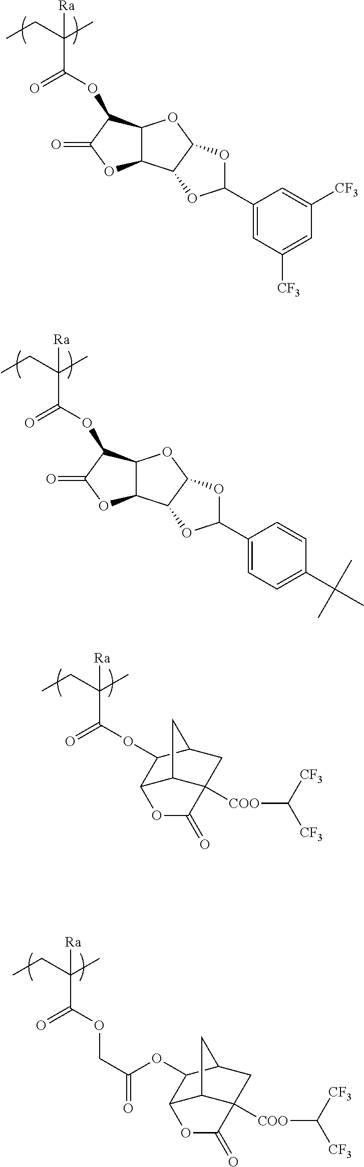

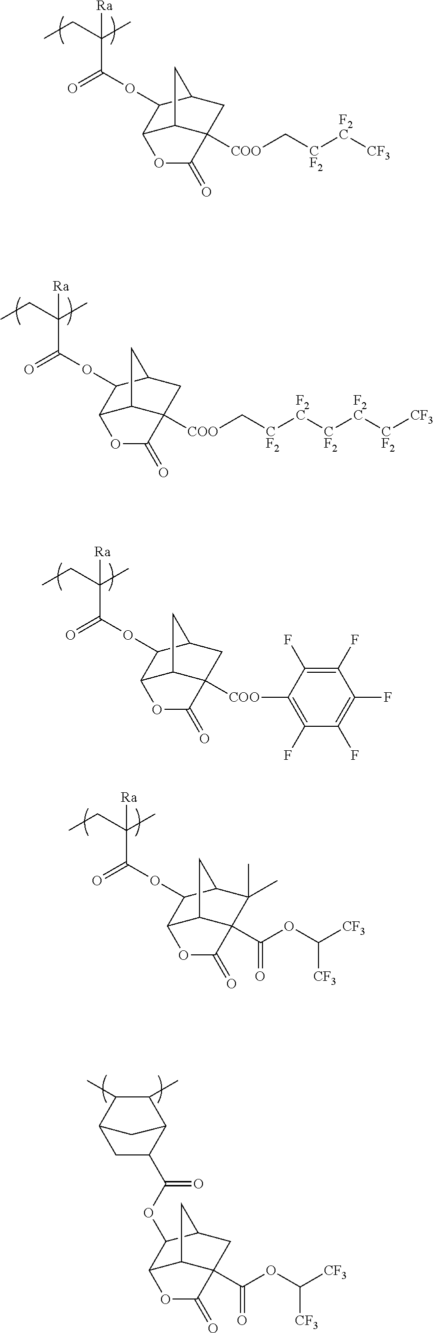

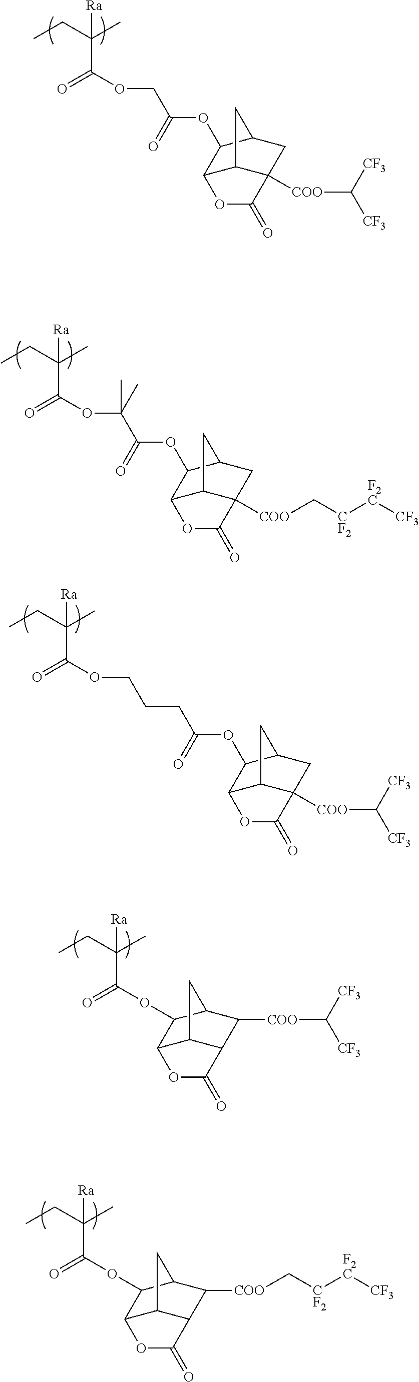

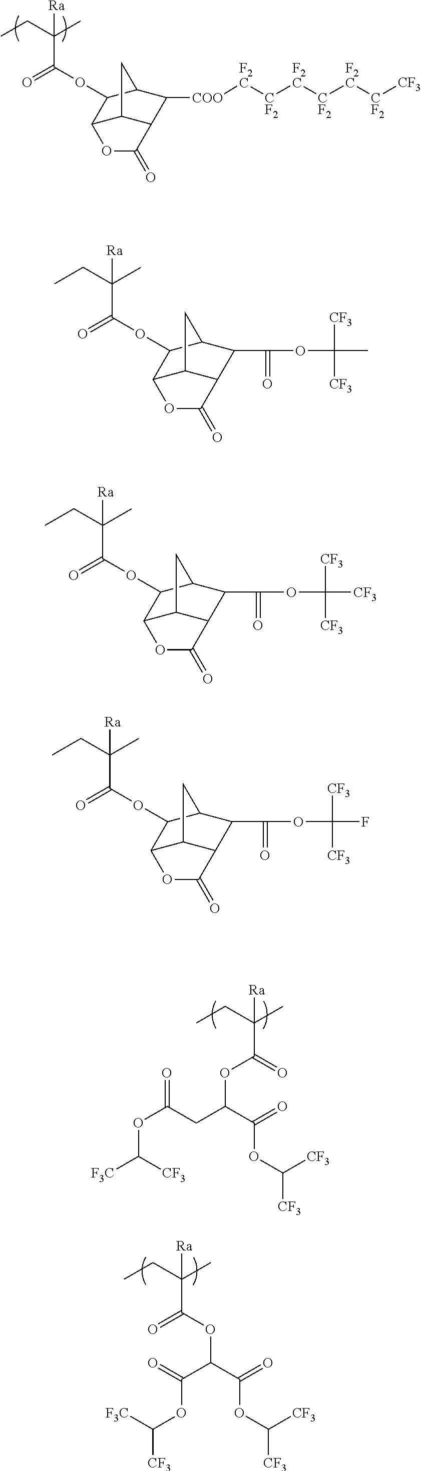

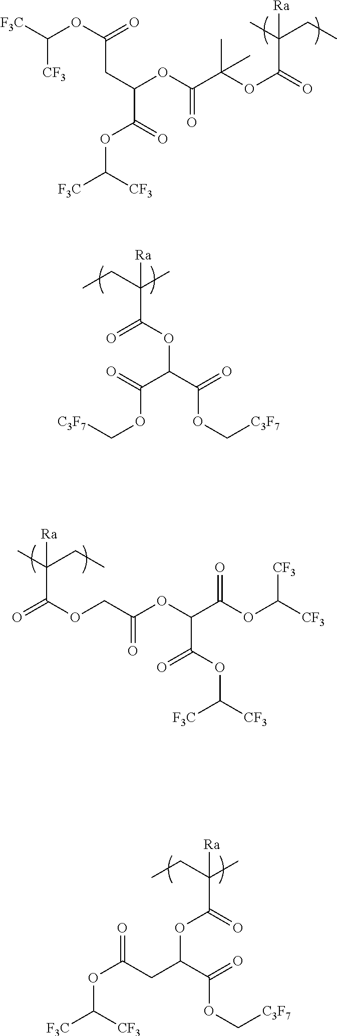

Examples of a repeating unit (bz) in the hydrophobic resin, which has a group (z) decomposed by the action of an acid, include the same repeating units as the repeating unit having an acid-decomposable group described for the resin (A).

When the repeating unit (bz) is a repeating unit having at least one of a fluorine atom and a silicon atom (that is, when the repeating unit (bz) corresponds to the repeating unit (b′) or (b″)), examples of a partial structure having a fluorine atom in the repeating unit (bz) include the same structures that were exemplified for the repeating unit having at least one of a fluorine atom and a silicon atom, which are preferably the groups represented by the general formulae (F2) to (F4). In this case, examples of the partial structure having a silicon atom in the repeating unit (bz) include the same structures that were exemplified for the repeating unit having at least one of a fluorine atom and a silicon atom, which are preferably the groups represented by the general formulae (CS-1) to (CS-3).

The content of the repeating unit (bz) in the hydrophobic resin, which has the group (z) decomposed by the action of an acid, is preferably 1 mol % to 80 mol %, more preferably 10 mol % to 80 mol %, and still more preferably 20 mol % to 60 mol %, based on all repeating units in the hydrophobic resin.

So far, the repeating unit (b) having at least one group selected from a group consisting of the (x) to (z) has been described. The content of the repeating unit (b) in the hydrophobic resin is preferably 1 mol % to 98 mol %, more preferably 3 mol % to 98 mol %, still more preferably 5 mol % to 97 mol %, and most preferably 10 mol % to 95 mol %, based on all repeating units in the hydrophobic resin.

The content of the repeating unit (b′) is preferably 1 mol % to 100 mol %, more preferably 3 mol % to 99 mol %, still more preferably 5 mol % to 97 mol %, and most preferably 10 mol % to 95 mol %, based on all repeating units in the hydrophobic resin.

The content of the repeating unit (b*) is preferably 1 mol % to 90 mol %, more preferably 3 mol % to 80 mol %, still more preferably 5 mol % to 70 mol %, and most preferably 10 mol % to 60 mol %, based on all repeating units in the hydrophobic resin. The content of the repeating unit that has at least one of a fluorine atom and a silicon atom and is used along with the repeating unit (b*) is preferably 10 mol % to 99 mol %, more preferably 20 mol % to 97 mol %, still more preferably 30 mol % to 95 mol %, and most preferably 40 mol % to 90 mol %, based on all repeating units in the hydrophobic resin.

The content of the repeating unit (b″) is preferably 1 mol % to 100 mol %, more preferably 3 mol % to 99 mol %, still more preferably 5 mol % to 97 mol %, and most preferably 10 mol % to 95 mol %, based on all repeating units in the hydrophobic resin.

The hydrophobic resin may further include a repeating unit represented by the following general formula (III).

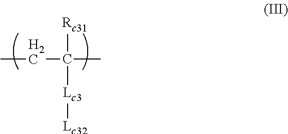

In general formula (III),

R_{C31} represents a hydrogen atom, an alkyl group, an alkyl group that may be substituted with a fluorine atom, a cyano group, or a —CH₂—O-Rac₂ group. In the formula, Rac₂ represents a hydrogen atom, an alkyl group, or a acyl group. Rₑ₃₁ is preferably a hydrogen atom, a methyl group, a hydroxymethyl group, or a trifluoromethyl group, and particularly preferably a hydrogen atom or methyl group.

R_{C32} represents an alkyl group, a cycloalkyl group, an alkenyl group, a cycloalkenyl group, or an aryl group. These groups may be substituted with a group and the like including a fluorine atom or a silicon atom.

L_{c3} represents a single bond or a divalent linking group.

The alkyl group of R_{C32} in general formula (III) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably a phenyl group or a naphthyl group having 6 to 20 carbon atoms, which may have a substituent.

R_{C32} is preferably an unsubstituted alkyl group or an alkyl group substituted with a fluorine atom.

The divalent linking group of L_{c3} is preferably an alkylene group (preferably having 1 to 5 carbon atoms), an oxy group, a phenylene group, or an ester bond (which is a group represented by —COO—).

It is preferable that the hydrophobic resin include a repeating unit represented by the following general formula (BII-AB).

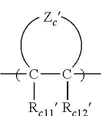

In Formula (BII-AB),

each of R_{C11}′ and R_{C12}′ independently represents a hydrogen atom, a cyano group, a halogen atom, or an alkyl group.

Zc′ represents an atomic group for forming an alicyclic structure with two bound carbon atoms (C—C).

When the respective groups in the repeating units represented by general formulae (III) and (BII-AB) have been substituted with groups having a fluorine atom or a silicon atom, the repeating units correspond to the repeating units having at least one of a fluorine atom and a silicon atom.

Specific examples of the repeating units represented by general formulae (III) and (BII-AB) will be shown below, but the present invention is not limited thereto. In the formulae, Ra represents H, CH₃, CH₂OH, CF₃, or CN. When Ra is CF₃, the repeating unit also corresponds to the repeating unit having at least one of a fluorine atom and a silicon atom. Needless to say, the content of this repeating unit in the hydrophobic resin does not exceed 100 mol % in total.

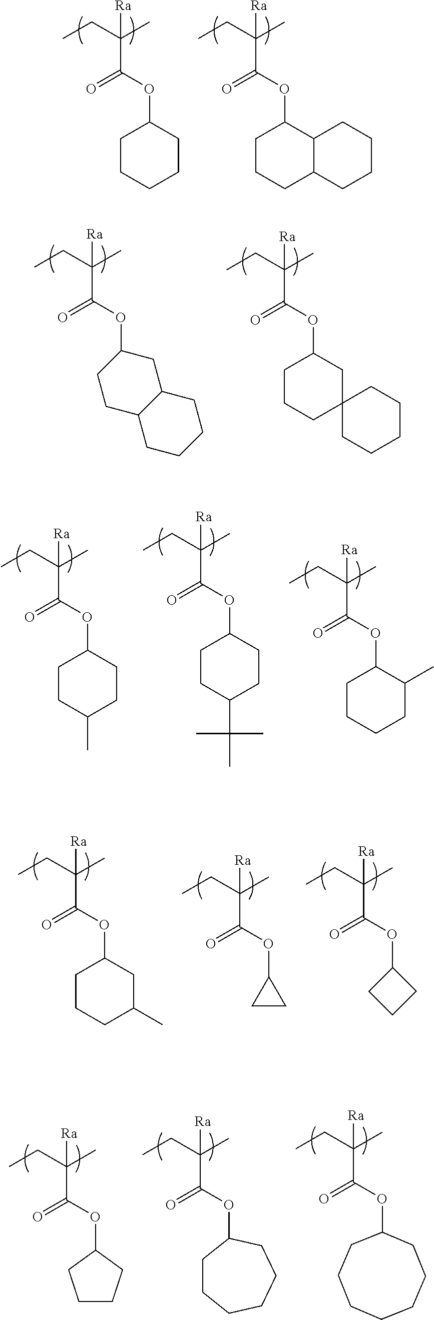

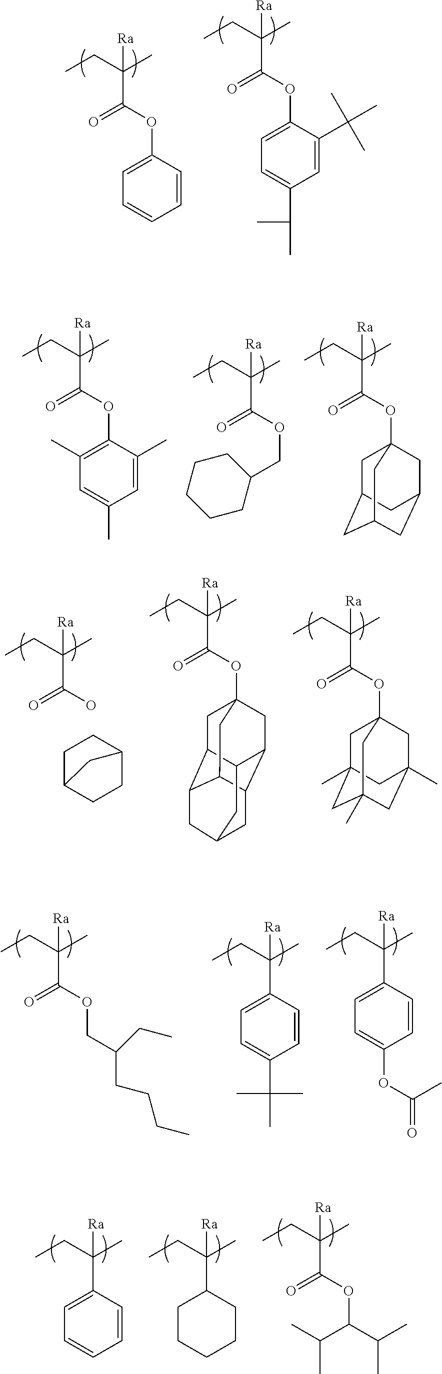

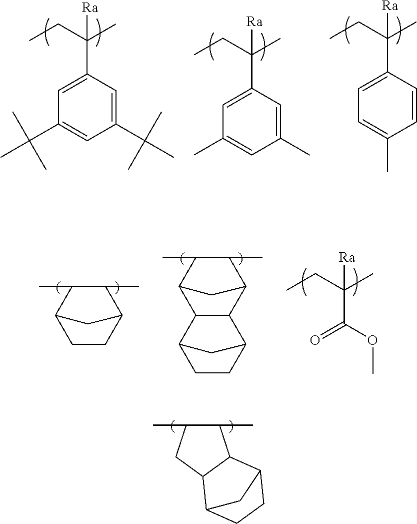

It is natural that the hydrophobic resin contains a small amount of impurities such as metals, similarly to the resin (A). The amount of remaining monomers and oligomer components in the hydrophobic resin is preferably 0% to 10% by mass, more preferably 0% to 5% by mass, and still more preferably 0% to 1% by mass. In this amount, a composition which shows a small degree of change over time of foreign substances in a liquid, sensitivity, and the like can be obtained. The molecular weight distribution (Mw/Mn, which is also referred to as degree of dispersion) is preferably in a range of from 1 to 3, more preferably in a range of from 1 to 2, still more preferably in a range of from 1 to 1.8, and most preferably in a range of from 1 to 1.5, in respect of resolution, the pattern shape, side walls of the pattern, roughness, and the like.

As the hydrophobic resin, various commercially available products can be used, and the hydrophobic resin can also be synthesized by a common method (for example, a radical polymerization). Examples of the general synthesis method include batch polymerization in which polymerization is performed by dissolving polymer materials and initiators in a solvent and heating the resultant, and drop polymerization in which a solution including monomer materials and initiators is added dropwise to a heated solvent for 1 to 10 hours. A preferable method is the drop polymerization.

The reaction solvent, polymerization initiator, reaction conditions (temperature, concentration, and the like), and purification method after the reaction are the same as those that were described for the resin (A).

Specific examples of the hydrophobic resin will be shown below. The molar ratio (listed from left in order for each repeating unit), weight average molecular weight, degree of dispersion of repeating units in the respective resins will be shown in tables inserted below.

TABLE 1

| | Compositional ratio | | |
|---|---|---|---|
| Polymer | (mol %) | Mw | Mw/Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |
| B-56 | 50/50 | 7000 | 1.4 |
| B-57 | 40/60 | 6500 | 1.7 |
| B-58 | 40/60 | 9200 | 1.6 |
| B-59 | 30/70 | 6800 | 1.4 |
| B-60 | 50/50 | 8000 | 1.5 |
| B-61 | 30/50/20 | 12000 | 1.7 |

(B-1) 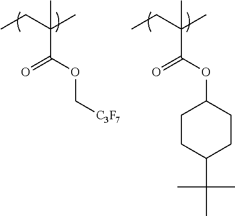
(B-2) 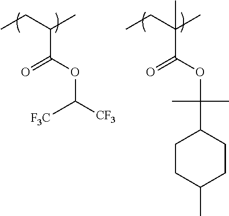
(B-3) 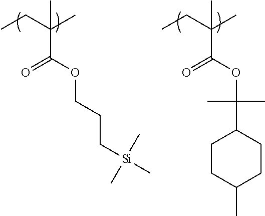
(B-4) 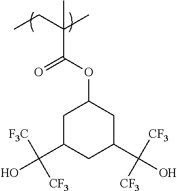
(B-5) 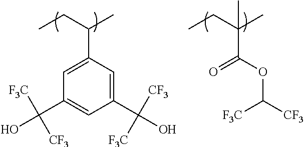
(B-6) 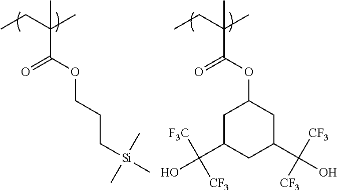
(B-7) 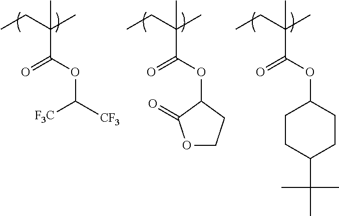
(B-8) 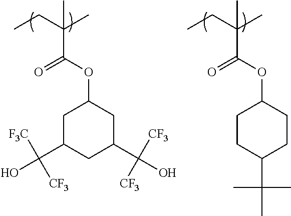
(B-9) 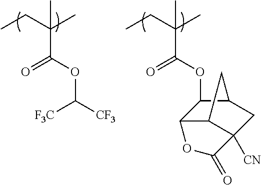
(B-10) 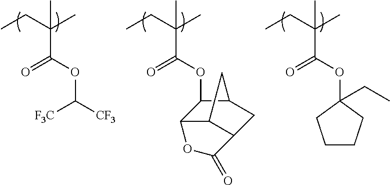
(B-11) 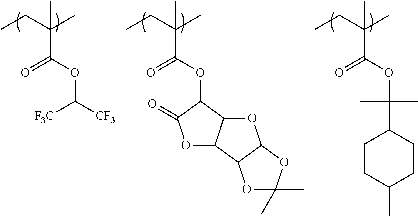
(B-12) 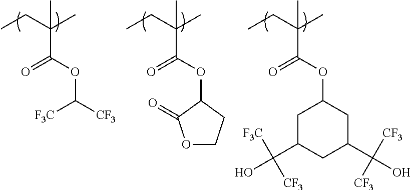
(B-13) 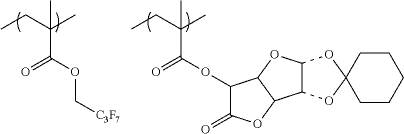
(B-14) 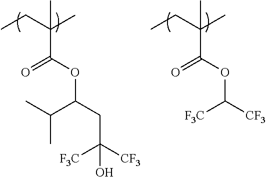
(B-15) 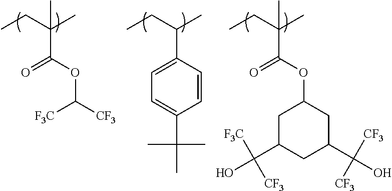
(B-16) 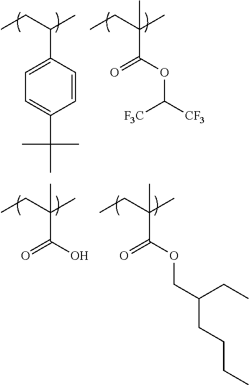
(B-17) 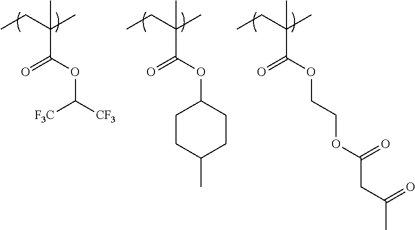
(B-18) 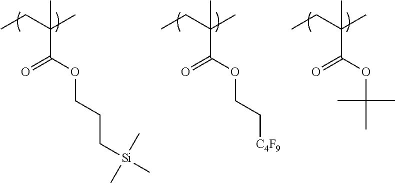
(B-19) 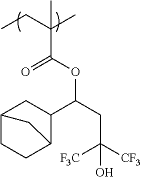
(B-20) 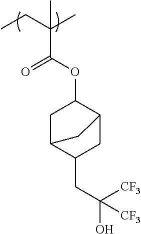
(B-21) 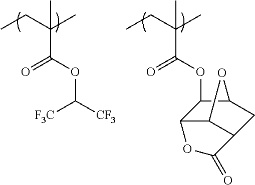
(B-22) 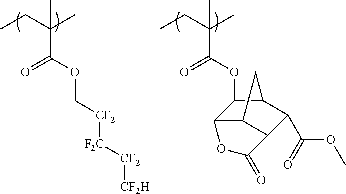
(B-23) 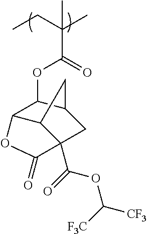
(B-24) 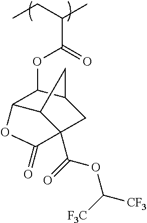
(B-25) 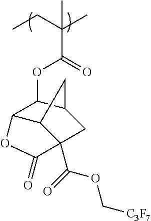
(B-26) 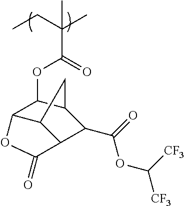
(B-27) 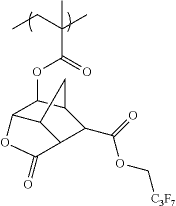
(B-28) 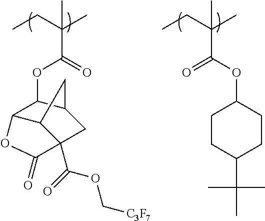
(B-29) 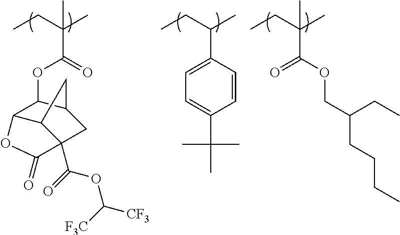
(B-30) 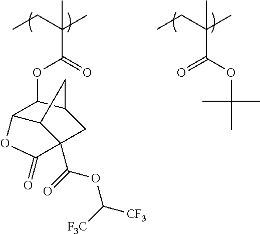
(B-31) 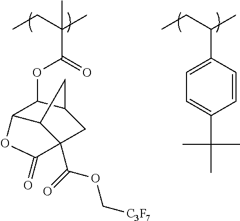
(B-32) 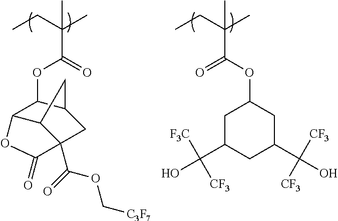
(B-33) 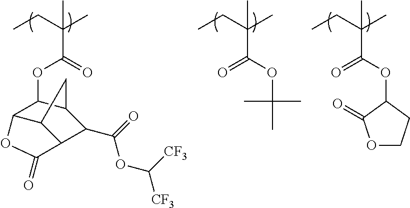
(B-34) 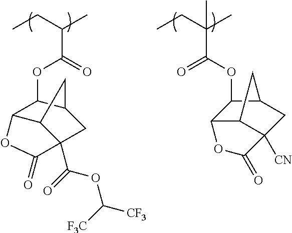
(B-35) 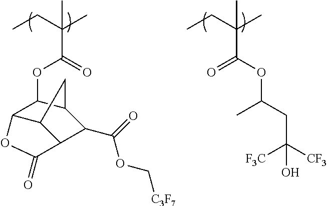
(B-36) 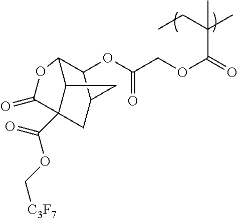
(B-37) 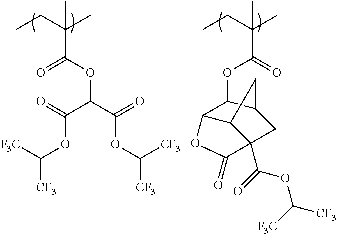
(B-38) 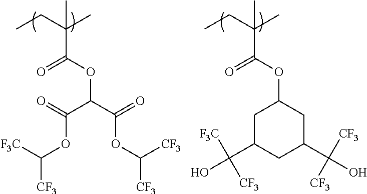
(B-39) 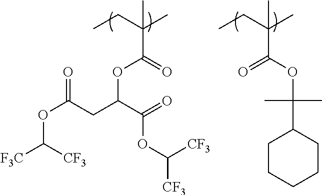
(B-40) 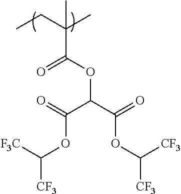
(B-41) 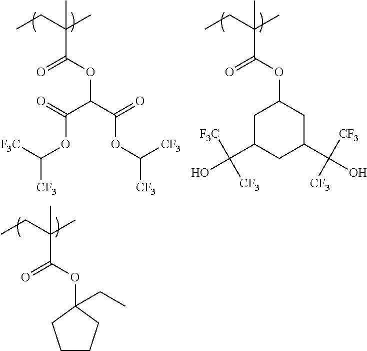
(B-42) 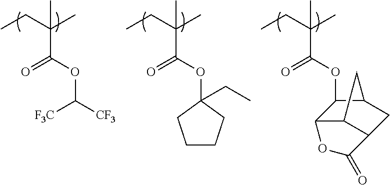
(B-43) 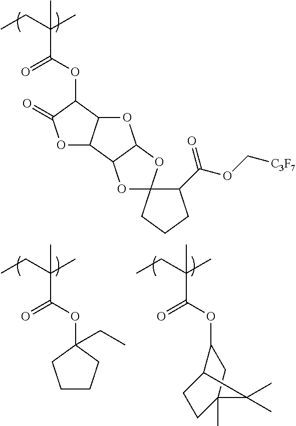
(B-44) 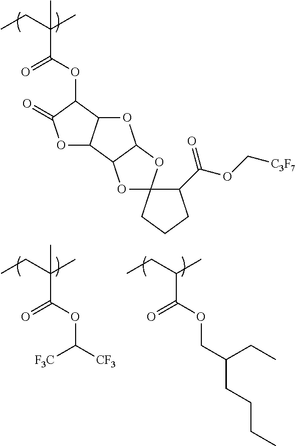
(B-45) 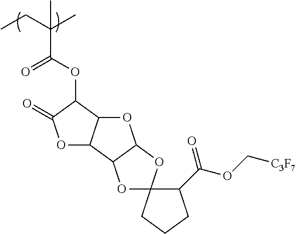
(B-46) 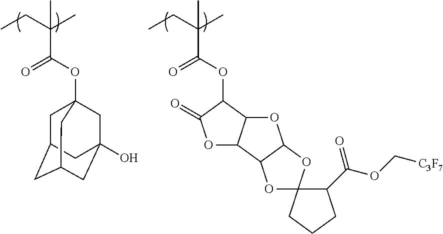
(B-47) 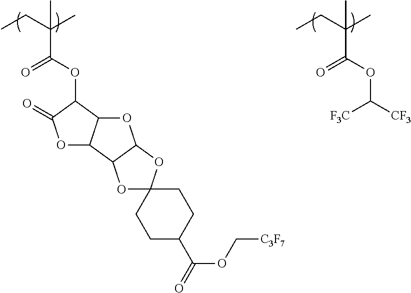
(B-48) 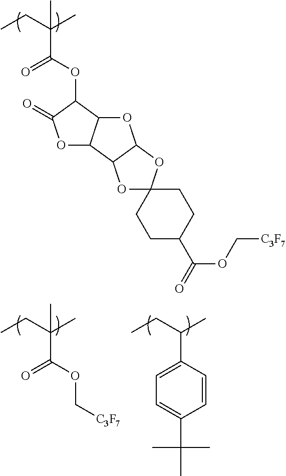
(B-49) 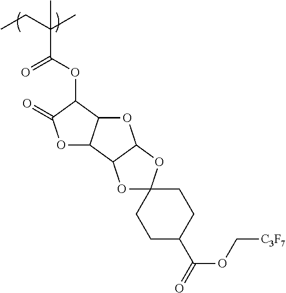
(B-50) 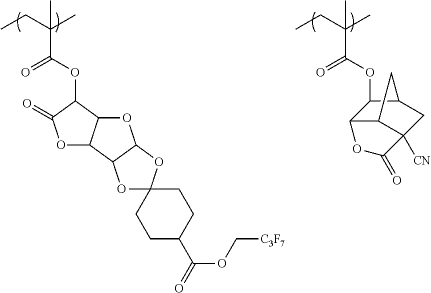
(B-51) 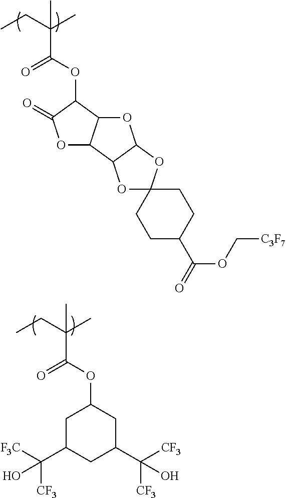
(B-52) 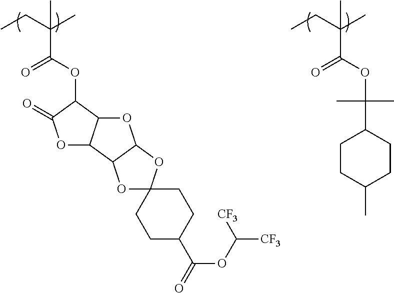
(B-53) 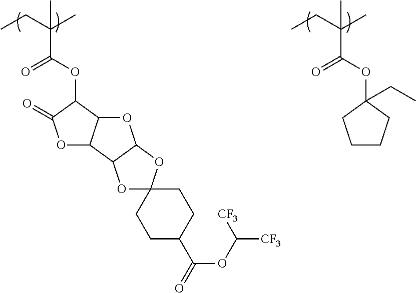
(B-54) 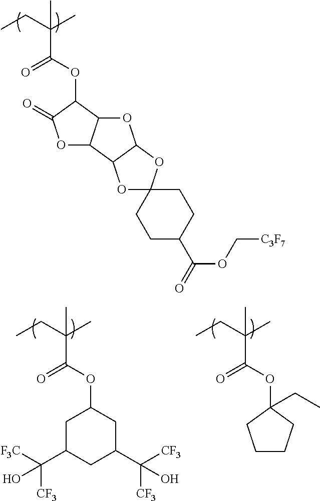
(B-55) 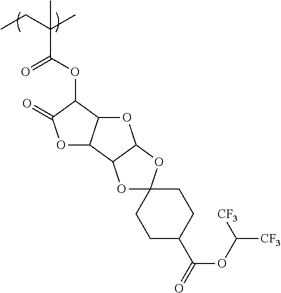
(B-56) 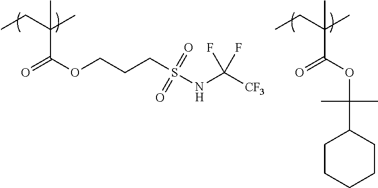
(B-57) 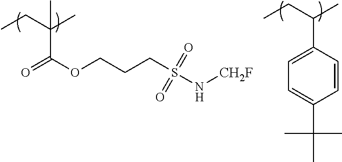
(B-58) 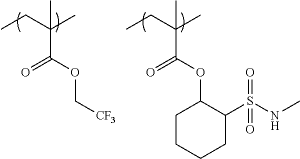
(B-59) 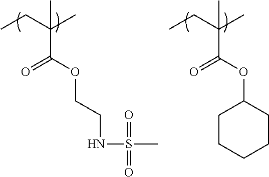
(B-60) 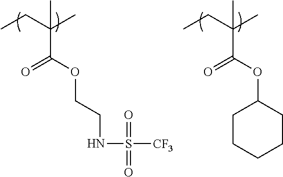
(B-61)

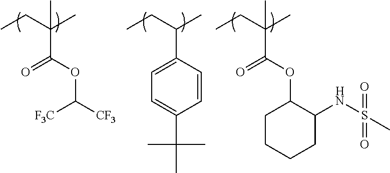

The composition according to the present invention contains the hydrophobic resin containing at least one of a fluorine atom and a silicon atom. Therefore, the hydrophobic resin is localized on a surface layer of a film formed of the composition, and when a medium for liquid immersion is water, the backward contact angle of the film surface with respect to water increases, whereby followability to the water for liquid immersion can be improved.

The backward contact angle of the film which is obtained after baking a coating film formed of the composition of the present invention and has not yet been exposed is preferably 60° to 90°, more preferably 65° C. or more, still more preferably 70° C. or more, and particularly preferably 75° or more, at a temperature at the time of exposure (normally, room temperature of 23±3° C.) and a humidity of 45±5%.

The hydrophobic resin is localized on the interface as described above. However, contrary to a surfactant, the hydrophobic resin does not necessarily have a hydrophilic group in a molecule and may not help a polar substance and a non-polar substance to be evenly mixed.

During the process of liquid immersion exposure, an exposure head needs to scan a wafer at a high speed so as to follow the movement of forming an exposure pattern, and the liquid for liquid immersion needs to move on the wafer. Accordingly, the contact angle of the liquid for liquid immersion with respect to the composition film that is in a dynamic state is important, and there is a demand for a performance that can follow the high-speed scanning of the exposure head without causing droplets to remain.

Due to its hydrophobicity, the hydrophobic resin easily aggravates development residues (scum) and BLOB defects after alkali development. However, if the hydrophobic resin has three or more polymer chains through at least one branched portion, the alkali dissolution rate thereof is improved compared to a linear resin, so the performance causing the development residues (scum) and BLOB defects can be ameliorated.

When the hydrophobic resin has a fluorine atom, the content of the fluorine atom is preferably 5% to 80% by mass, and more preferably 10% to 80% by mass, based on the molecular weight of hydrophobic resin. The content of the repeating unit having a fluorine atom is preferably 10% to 100% by mass, and more preferably 30% to 100% by mass, based on all repeating units in the hydrophobic resin.

When the hydrophobic resin has a silicon atom, the content of the silicon atoms is preferably 2% to 50% by mass, and more preferably 2% to 30% by mass, based on the molecular weight of the hydrophobic resin. The content of the repeating unit having a silicon atom is preferably 10% to 90% by mass, and more preferably 20% to 80% by mass, based on all repeating units in the hydrophobic resin.

The weight average molecular weight of the hydrophobic resin is preferably 1,000 to 100,000, more preferably 2,000 to 50,000, and still more preferably 3,000 to 30,000. Herein, the weight average molecular weight of the resin represents a molecular weight which is measured by GPC (carrier: tetrahydrofuran (THF)) and converted in terms of polystyrene.

The hydrophobic resin may be used alone or in combination of two or more kinds thereof.

The content of the hydrophobic resin in the composition can be appropriately adjusted such that the backward contact angle of the actinic-ray-sensitive or radiation-sensitive resin film falls within the above range. The content is preferably 0.1% to 10% by mass, more preferably 0.5% to 8% by mass, and still more preferably 0.5% to 5% by mass, based on the total solid contents of the composition.

(C) Onium salt which includes nitrogen atom in cation portion and generates an acid by being decomposed upon irradiatikon with actinic-ray or radiation.

The composition according to the present invention contains an onium salt [compound (C)] which includes a nitrogen atom in a cation portion and generates an acid by being decomposed upon irradiatikon with actinic-ray or radiation.

Examples of the onium salt include a diazonium salt, a phosphonium salt, a sulfonium salt, an iodonium salt, imidosulfonate, oxime sulfonate, diazosulfonate, disulfone, and o-nitrobenzyl sulfonate. Among these, a sulfonium salt or an iodonium salt is preferable, and a sulfonium salt is more preferable.

Typically, the onium salt includes a basic moiety containing a nitrogen atom, in a cation portion. The “basic moiety” herein refers to a moiety in which a pKa of a conjugate acid in a cation moiety of the compound (C) is −3 or higher. The pKa is preferably in a range of from −3 to 15, and more preferably in a range of from 0 to 15. In addition, the pKa refers to a value calculated from ACD/ChemSketch (ACD/Labs 8.00 Release Product Version: 8.08).

The basic moiety includes an amino group [a group obtained after removing one hydrogen atom from ammonium or amine (primary and secondary amines, for example): the same definition will be applied hereinbelow] or a nitrogen-containing heterocyclic group. In these structures, it is preferable that all atoms adjacent to the nitrogen atom included in the structure be carbon atoms or hydrogen atoms, from the viewpoint of basicity improvement. Moreover, from the viewpoint of basicity improvement, it is preferable that electron-attracting functional groups (a carbonyl group, a sulfonyl group, a cyano group, a halogen atom, and the like) be not directly linked to the hydrogen atoms.

The basic moiety may include two or more basic groups such as an amino group and a nitrogen-containing heterocyclic group.

When the cation portion of the compound (C) includes an amino group, this cation portion preferably includes a partial structure represented by the following general formula (N-I).

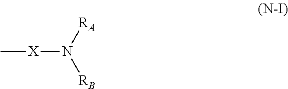

In the formula,

each of R_{A} and R_{B} independently represents a hydrogen atom or an organic group.

X represents single bond or a linking group.

At least two of R_{A}, R_{B}, and X may form a ring by binding to each other.

Examples of the organic group represented by R_{A} or R_{B} include an alkyl group, a cycloalkyl group, an aryl group, a lactone group, and a groups including these groups.

The alkyl group represented by R_{A} or R_{B} may be linear or branched. The number of carbon atoms of this alkyl group is preferably 1 to 50, more preferably 1 to 30, and still more preferably 1 to 20. Examples of such an alkyl group include a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, and a 2-ethylhexyl group.

The cycloalkyl group represented by the R_{A} or R_{B} may be monocyclic or polycyclic. Preferable examples of the cycloalkyl group include a monocyclic cycloalkyl group having 3 to 8 carbon atoms, such as a cyclopropyl group, a cyclopentyl group, and a cyclohexyl group.

The number of carbon atoms of the aryl group represented by R_{A} or R_{B} is preferably 6 to 14. Examples of such an aryl group include a phenyl group and a naphthyl group.

Examples of the lactone group represented by R_{A} or R_{B} include groups having the lactone structure that was exemplified previously for the resin (A).

R_{A} and R_{B} may form a ring by binding to each other. The number of carbon atoms forming the ring is preferably 4 to 20, and the structure thereof may be monocyclic or polycyclic. An oxygen atom, a sulfur atom, a nitrogen atom, an ester bond, an amide bond, or a carbonyl group may be included in the ring.

Examples of the linking group represented by X include a linear or branched alkylene group, a cycloalkylene group, an ether bond, an ester bond, an amide bond, a urethane bond, and a urea bond. X more preferably represents a single bond, an ether bond, or an ester bond. The number of carbon atoms of the linking group represented by X is preferably 20 or less, and more preferably 15 or less. The linear or branched alkylene group and a cycloalkylene group preferably have 8 or less carbon atoms and may have a substituent. The substituent preferably has 8 or less carbon atoms, and examples thereof include an alkyl group (having 1 to 4 carbon atoms), a halogen atom, a hydroxyl group, an alkoxy group (having 1 to 4 carbon atoms), a carboxyl group, an alkoxycarbonyl group (having 2 to 6 carbon atoms), and the like.

When the cation portion of the compound (C) includes a nitrogen-containing heterocyclic group, this nitrogen-containing heterocyclic group may or may not be aromatic. In addition, this nitrogen-containing heterocyclic group may be monocyclic or polycyclic. Preferable examples of the nitrogen-containing heterocyclic group include groups including a piperidine ring, a morpholine ring, a pyridine ring, an imidazole ring, a pyrazine ring, a pyrrole ring or a pyrimidine ring.

There is no particular limitation on the constitution of an anion portion of the compound (C). The anion included in the compound (C) is preferably a non-nucleophilic anion. Herein, the non-nucleophilic anion is an anion with a very low ability of causing a nucleophilic reaction, which is an anion that can inhibit degradation over time caused by an intra-molecular nucleophilic reaction. Due to this property of the anion, the temporal stability of the composition according to the present invention is improved.

Examples of the non-nucleophilic anion include a sulfonic acid anion, a carboxylic acid anion, a sulfonylimide anion, a bis(alkylsulfonyl)imide anion, a tris(alkylsulfonyl)methyl anion, and the like.

Examples of the sulfonic acid anion include an aliphatic sulfonic acid anion, an aromatic sulfonic acid anion, a camphorsulfonic acid anion, and the like.

Examples of the carboxylic acid anion include an aliphatic carboxylic acid anion, an aromatic carboxylic acid anion, an aralkyl carboxylic acid anion, and the like.

The aliphatic moiety in the aliphatic sulfonic acid anion may be an alkyl group or a cycloalkyl group, and is preferably an alkyl group having 1 to 30 carbon atoms and a cycloalkyl group having 3 to 30 carbon atoms. Examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group, and the like.

As the aromatic group in the aromatic sulfonic acid anion, an aryl group having 6 to 14 carbon atoms is preferable. Examples thereof include a phenyl group, a tolyl group, a naphthyl group, and the like.

The alkyl group, cycloalkyl group, and aryl group in the aliphatic sulfonic acid anion and aromatic sulfonic acid anion may have a substituent. Examples of the substituent of the alkyl group, cycloalkyl group, and aryl group in the aliphatic sulfonic acid anion and aromatic sulfonic acid anion include a nitro group, a halogen atom (a fluorine atom, a chlorine atom, a bromine atom, or an iodine atom), a carboxy group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxy sulfonyl group (preferably having 7 to 20 carbon atoms), a cycloalkylaryloxy sulfonyl group (preferably having 10 to 20 carbon atoms), an alkyloxy alkyloxy group (preferably having 5 to 20 carbon atoms), a cycloalkylalkyloxy alkyloxy group (preferably having 8 to 20 carbon atoms), and the like. Regarding the aryl group and the ring structure of the respective groups, an alkyl group (preferably having 1 to 15 carbon atoms) can be further exemplified as a substituent.

Examples of the aliphatic moiety in the aliphatic carboxylic acid anion include the same alkyl group and cycloalkyl group as those in aliphatic sulfonic acid anion.

Examples of the aromatic group in the aromatic carboxylic acid anion include the same aryl group as that in the aromatic sulfonic acid anion.

The aralkyl group in the aralkyl carboxylic acid anion is preferably an aralkyl group having 6 to 12 carbon atoms, and examples thereof include a benzyl group, a phenethyl group, a naphthyl methyl group, a naphthyl ethyl group, a naphthyl butyl group, and the like.

The alkyl group, cycloalkyl group, aryl group, and aralkyl group in the aliphatic carboxylic acid anion, aromatic carboxylic acid anion, and aralkyl carboxylic acid anion may have a substituent. Examples of the substituent of the alkyl group, cycloalkyl group, aryl group, and aralkyl group in the aliphatic carboxylic acid anion, aromatic carboxylic acid anion, and aralkyl carboxylic acid anion include the same halogen atom, alkyl group, cycloalkyl group, alkoxy group, alkylthio group, and the like as those in the aromatic sulfonic acid anion.

Examples of the sulfonylimide anion include a saccharin anion.

The alkyl group in the bis(alkylsulfonyl)imide anion and tris(alkylsulfonyl)methyl anion is preferably an alkyl group having 1 to 5 carbon atoms, and examples thereof include a methyl group, an ethyl group, a propyl group, an isopropyl group, an n-butyl group, an isobutyl group, a sec-butyl group, a pentyl group, a neopentyl group, and the like. Examples of a substituent of these alkyl groups include a halogen atom, an alkyl group substituted with a halogen atom, an alkoxy group, an alkylthio group, an alkyloxysulfonyl group, an aryloxysulfonyl group, a cycloalkylaryloxy sulfonyl group, and the like, and an alkyl group substituted with a fluorine atom is preferable. In addition, an embodiment is also preferable in which two alkyl groups in the bis(alkylsulfonyl)imide anion form a cyclic structure by binding to each other. In this case, the cyclic structure formed is preferably a 5 to 7-membered ring.

Examples of other non-nucleophilic anions include phosphorus fluoride, boron fluoride, antimony fluoride, and the like.

As the non-nucleophilic anion, an aliphatic sulfonic acid anion in which an α position of the sulfonic acid has been substituted with a fluorine atom, an aromatic sulfonic acid anion substituted with a fluorine atom or a group having a fluorine atom, a bis(alkylsulfonyl)imide anion in which the alkyl group has been substituted with a fluorine atom, and a tris(alkylsulfonyl)methide anion in which the alkyl group has been substituted with a fluorine atom are preferable. The non-nucleophilic anion is more preferably a perfluoro aliphatic sulfonic acid anion having 4 to 8 carbon atoms or a benzenesulfonic acid anion having a fluorine atom, and still more preferably a nonafluoro butanesulfonic acid anion, a perfluoro octanesulfonic acid anion, a pentafluoro benzenesulfonic acid anion, or a 3,5-bis(trifluoromethyl)benzenesulfonic acid anion.

The non-nucleophilic anion is preferably represented by the following general formula (LD-1).

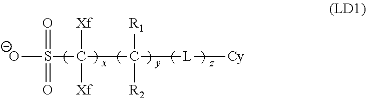

In the formula,

each Xf independently represents a fluorine atom or an alkyl group substituted with at least one fluorine atom.

Each of R₁ and R₂ independently represents a hydrogen atom, a fluorine atom, an alkyl group, and a group selected from an alkyl group substituted with at least one fluorine atom.

Each L independently represents a single bond or a divalent linking group.

Cy represents a group having a cyclic structure.

x represents an integer of 1 to 20.

y represents an integer of 0 to 10.

z represents an integer of 0 to 10.

Xf represents a fluorine atom or an alkyl group substituted with at least one fluorine atom. The number of carbon atoms of the alkyl group is preferably 1 to 10, and more preferably 1 to 4. The alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉.

Each of R₁ and R₂ independently represents a hydrogen atom, a fluorine atom, an alkyl group, and a group selected from an alkyl group substituted with at least one fluorine atom. The alkyl group and alkyl group in the alkyl group substituted with at least one fluorine atom preferably have 1 to 4 carbon atoms, and as these alkyl groups, a perfluoroalkyl group having 1 to 4 carbon atoms is more preferable. Specific examples thereof include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

L represents a single bond or a divalent linking group. Examples of the divalent linking group include —COO—, —OCC—, —CONH—, —CO—, —O—, —S—, —SO—, —SO₂—, an alkylene group, a cycloalkylene group, and an alkenylene group. Among these, —CONH—, —CO—, or —SO₂— is preferable, and —CONH— or —SO₂— is more preferable.

Cy represents a group having a cyclic structure. Examples of the group having a cyclic structure include an alicyclic group, an aryl group, and a group having a heterocyclic structure.

The alicyclic group may be monocyclic or polycyclic. Examples of the monocyclic alicyclic group include a monocyclic cycloalkyl group such as a cyclopentyl group, a cyclohexyl group, and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, and an adamantyl group. Among these, alicyclic groups with a bulky structure having 7 or more carbon atoms, such as norbornyl group, a tricyclodecanyl group, a tetracyclodecanyl group, a tetracyclododecanyl group, and an adamantyl group, are preferable from the viewpoints of inhibiting diffusivity into the film during PEB (Post Exposure Bake) process and improving MEEF (Mask Error Enhancement Factor).

The aryl group may be monocyclic or polycyclic. Examples of the aryl group include a phenyl group, a naphthyl group, a phenanthryl group, and an anthryl group. Among these, a naphthyl group showing relatively low light absorbance at 193 nm is preferable.

The group having a heterocyclic structure may be monocyclic or polycyclic. However, a polycyclic structure can further inhibit the diffusion of acid. Moreover, the group having a heterocyclic structure may or may not be aromatic. Examples of the aromatic heterocycle include a furan ring, a thiophene ring, a benzofuran ring, a benzothiophene ring, a dibenzofuran ring, a dibenzothiophene ring, and a pyridine ring. Examples of the non-aromatic heterocycle include a tetrahydrofuran ring, a lactone ring, and a decahydroisoquinoline ring. As the heterocycle in a group having a heterocyclic structure, a furan ring, a thiophene ring, a pyridine ring, and a decahydroisoquinoline ring are particularly preferable. Examples of the lactone ring include the lactone structure exemplified previously for the resin (A).

The group having the cyclic structure may have a substituent. Examples of the substituent include an alkyl group, a cycloalkyl group, an aryl group, a hydroxy group, an alkoxy group, an ester group, an amide group, a urethane group, a ureido group, a thioether group, a sulfonamide group, and a sulfonic acid ester group. The alkyl group may be linear or branched, and preferably has 1 to 12 carbon atoms. The cycloalkyl group may be monocyclic or polycyclic, and preferably has 3 to 12 carbon atoms. The aryl group preferably has 6 to 14 carbon atoms.

x is preferably 1 to 8, more preferably 1 to 4, and particularly preferably 1. y is preferably 0 to 4, and more preferably 0. z is preferably 0 to 8, and more preferably 0 to 4.

In addition, it is preferable that the non-nucleophilic anion be represented by the following general formula (LD2).

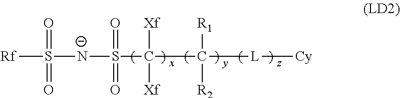

In general formula (LD2), Xf, R₁, R₂, L, Cy, x, y and z have the same definitions as those in the general formula (LD1). Rf is a group including a fluorine atom.

Examples of the group including a fluorine atom, which is represented by Rf, include an alkyl group having at least one fluorine atom, a cycloalkyl group having at least one fluorine atom, and an aryl group having at least one fluorine atom.

These alkyl group, cycloalkyl group, and aryl group may be substituted with a fluorine atom or with another substituent that includes a fluorine atom. When Rf is a cycloalkyl group having at least one fluorine atom or an aryl group having at least one fluorine atom, examples of another substituent that includes a fluorine atom include an alkyl group substituted with at least one fluorine atom.

In addition, these alkyl group, cycloalkyl group, and aryl group may be further substituted with a substituent that does not include a fluorine atom. Examples of this substituent include the substituent that does not include a fluorine atom, among the substituents described previously for Cy.

Examples of the alkyl group having at least one fluorine atom, which is represented by Rf, include the same groups as those described previously as the alkyl group substituted with at least one fluorine atom, which is represented by Xf. Examples of the cycloalkyl group having at least one fluorine atom, which is represented by Rf, include a perfluorocyclopentyl group and a perfluorocyclohexyl group. Examples of the aryl group having at least one fluorine atom, which is represented by Rf, include a perfluorophenyl group.

It is preferable that the compound (C) be represented by the following general formula (N-II).

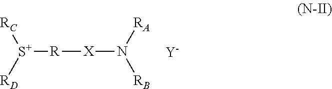

In the formula,

R_{A}, R_{B}, and X have the same definitions as those in general formula (N-I).

R represents an organic group.

Each of R_{C} and R_{D} independently represents a hydrogen atom or an organic group.

At least two of R_{A}, R_{B}, X, R, R_{C}, and R_{D} may form a ring by binding to each other.

Y⁻ represents an anion.

Examples of the organic group represented by R include an alkylene group, a cycloalkylene group, and an arylene group, and among these, an arylene group is preferable. When R is an arylene group, R preferably binds at a p-position (1,4-position) of the arylene group.

Examples of the organic group represented by R_{C} or R_{D} include an alkyl group, an alkenyl group, an aliphatic cyclic group, an aromatic hydrocarbon group, or a heterocyclic hydrocarbon group. R_{C} and R_{D} may form a ring by binding to each other.

The alkyl group represented by R_{C} or R_{D} may be linear or branched. The number of carbon atoms of the alkyl group is preferably 1 to 50, more preferably 1 to 30, and still more preferably 1 to 20. Examples of the alkyl group include a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, and a 2-ethylhexyl group.

The alkenyl group represented by R_{C} or R_{D} may be linear or branched. The number of carbon atoms of the alkenyl group is preferably 2 to 50, more preferably 2 to 30, and still more preferably 3 to 20. Examples of the alkenyl group include a vinyl group, an allyl group, and a styryl group.

The aliphatic cyclic group represented by R_{C} or R_{D} is a cycloalkyl group, for example. The cycloalkyl group may be monocyclic or polycyclic. Preferable examples of the aliphatic cyclic group include a monocyclic cycloalkyl group having 3 to 8 carbon atoms, such as a cyclopropyl group, a cyclopentyl group, and a cyclohexyl group.

The aromatic hydrocarbon group represented by R_{C} or R_{D} preferably has 6 to 14 carbon atoms, and examples of such a group include an aryl group such as a phenyl group and a naphthyl group. The aromatic hydrocarbon group represented by R_{C} or R_{D} is preferably a phenyl group.

The heterocyclic hydrocarbon group represented by R_{C} or R_{D} may or may not be aromatic. This heterocyclic hydrocarbon group is preferably aromatic.

The heterocycle included in the above groups may be monocyclic or polycyclic. Examples of such a heterocycle include an imidazole ring, a pyridine ring, pyrazine ring, a pyrimidine ring, a pyridazine ring, a 2H-pyrrole ring, a 3H-indole ring, a 1H-indazole ring, a purine ring, an isoquinoline ring, a 4H-quinolizine ring, a quinoline ring, a phthalazine ring, a naphthyridine ring, a quinoxaline ring, a quinazoline ring, a cinnoline ring, a pteridine ring, a phenanthridine ring, an acridine ring, a phenanthroline ring, a phenazine ring, a perimidine ring, a triazine ring, a benzisoquinoline ring, a thiazole ring, a thiadiazine ring, an azepine ring, an azocine ring, an isothiazole ring, an isoxazole ring, and a benzothiazole ring.

The ring formed by R_{C} and R_{D} is preferably a 4 to 7-membered ring, more preferably a or 6-membered ring, and particularly preferably a 5-membered ring.

It is preferable that R_{C} and R_{D} be aromatic hydrocarbon groups, or form a ring by binding to each other.

When the group represented by R_{C} or R_{D} or the ring that R_{C} or R_{D} form by binding to each other further includes a substituent, examples of the substituent include the following substituents. That is, the examples of the substituent include a halogen atom (—F, —Br, —Cl, or —I), a hydroxyl group, an alkoxy group, an aryloxy group, a mercapto group, an aralkylthio group, an arylthio group, an amino group, an acyloxy group, a carbamoyloxy group, an alkylsulfoxy group, an arylsulfoxy group, an acylthio group, an acylamino group, an ureido group, an alkoxyarbonyl amino group, an aryloxycarbonyl amino group, an N-alkyl-N-alkoxycarbonyl amino group, an N-alkyl-N-aryloxycarbonyl amino group, an N-aryl-N-alkoxycarbonyl amino group, an N-aryl-N-aryloxycarbonyl amino group, a formyl group, an acyl group, a carboxyl group, a carbamoyl group, an alkylsulfinyl group, an arylsulfinyl group, an alkylsulfonyl group, an arylsulfonyl group, a sulfo group (—SO₃H) and a conjugate basic group thereof (which is referred to as a sulfonato group), an alkoxysulfonyl group, an aryloxysulfonyl group, a sulfinamoyl group, a sulfono group (—PO₃H₂) and a conjugate basic group thereof (which is referred to as a phosphonato group), a phosphonoxy group (—OPO₃H₂) and a conjugate basic group thereof (which is referred to as a phosphonatoxy group), a cyano group, a nitro group, an aryl group, an alkenyl group, an alkynyl group, a heterocyclic group, a silyl group, and an alkyl group.

Among these substituents, a halogen atom, an alkyl group, and an alkoxy group are particularly preferable. Examples of the alkyl group include the same groups as those exemplified previously for R_{C} or R_{D}.

It is preferable that the compound (C) be represented by the following general formula (1-1)

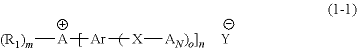

In the formula,

A represents a sulfur atom or an iodine atom.

When m=2, each R₁ independently represents an alkyl group, an alkenyl group, an aliphatic cyclic group, an aromatic hydrocarbon group, or a heterocyclic hydrocarbon group. When m=2, two R₁s may form a ring by binding to each other.

When n≧2, each Ar independently represents an aromatic cyclic group.

When o≧2 and/or n≧2, each X independently represents a single bond or a linking group having a carbon atom as a binding portion to the Ar.

When o≧2 and/or n≧2, each A_{N} independently represents a basic moiety including a nitrogen atom.

When the A is a sulfur atom, n is an integer of 1 to 3, and m is an integer satisfying relationship of m+n=3.

When the A is an iodine atom, n is an integer of 1 or 2, and m is an integer satisfying relationship of m+n=2.

o represents an integer of 1 to 10.

Y⁻ represents an anion.

When m=2, each R₁ independently represents an alkyl group, an alkenyl group, an aliphatic cyclic group, an aromatic hydrocarbon group, or a heterocyclic hydrocarbon group. When m=2, two R₁s may form a ring by binding to each other. These groups and ring may further include a substituent.

The alkyl group represented by R₁ may be linear or branched. The number of carbon atoms of the alkyl group is preferably 1 to 50, more preferably 1 to 30, and still more preferably 1 to 20. Examples of the alkyl group include a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, and a 2-ethylhexyl group.

The alkenyl group represented by R₁ may be linear or branched. The number of carbon atoms of the alkenyl group is preferably 2 to 50, more preferably 2 to 30, and still more preferably 3 to 20. Examples of the alkenyl group include a vinyl group, an allyl group, and a styryl group.

The aliphatic cyclic group represented by R₁ is a cycloalkyl group, for example. The cycloalkyl group may be monocyclic or polycyclic. Preferable examples of the aliphatic cyclic group include a monocyclic cycloalkyl group having 3 to 8 carbon atoms, such as a cyclopropyl group, a cyclopentyl group, and a cyclohexyl group.

The aromatic hydrocarbon group represented by R₁ preferably has 6 to 14 carbon atoms, and examples of such a group include an aryl group such as a phenyl group and a naphthyl group. The aromatic hydrocarbon group represented by R₁ is preferably a phenyl group.

The heterocyclic hydrocarbon group represented by R₁ may or may not be aromatic. This heterocyclic hydrocarbon group is preferably aromatic.

The heterocycle included in the above groups may be monocyclic or polycyclic. Examples of such a heterocycle include an imidazole ring, a pyridine ring, pyrazine ring, a pyrimidine ring, a pyridazine ring, a 2H-pyrrole ring, a 3H-indole ring, a 1H-indazole ring, a purine ring, an isoquinoline ring, a 4H-quinolizine ring, a quinoline ring, a phthalazine ring, a naphthyridine ring, a quinoxaline ring, a quinazoline ring, a cinnoline ring, a pteridine ring, a phenanthridine ring, an acridine ring, a phenanthroline ring, a phenazine ring, a perimidine ring, a triazine ring, a benzisoquinoline ring, a thiazole ring, a thiadiazine ring, an azepine ring, an azocine ring, an isothiazole ring, an isoxazole ring, and a benzothiazole ring.

The ring formed by two R₁s is preferably a 4 to 7-membered ring, more preferably a 5 or 6-membered ring, and particularly preferably a 5-membered ring.

It is preferable that R₁s be aromatic hydrocarbon groups, or form a ring by binding to each other.

When the group represented by R₁ or the ring that two R₁s form by binding to each other further includes a substituent, examples of the substituent include the following substituents. That is, the examples of the substituent include a halogen atom (—F, —Br, —Cl, or —I), a hydroxyl group, an alkoxy group, an aryloxy group, a mercapto group, an alkylthio group, an arylthio group, an amino group, an acyloxy group, a carbamoyloxy group, an alkylsulfoxy group, an arylsulfoxy group, an acylthio group, an acylamino group, an ureido group, an alkoxycarbonyl amino group, an aryloxycarbonyl amino group, an N-alkyl-N-alkoxycarbonyl amino group, an N-alkyl-N-aryloxycarbonyl amino group, an N-aryl-N-alkoxycarbonyl amino group, an N-aryl-N-aryloxycarbonyl amino group, a formyl group, an acyl group, a carboxyl group, a carbamoyl group, an alkylsulfinyl group, an arylsulfinyl group, an alkylsulfonyl group, an arylsulfonyl group, a sulfo group (—SO₃H) and a conjugate basic group thereof (which is referred to as a sulfonato group), an alkoxysulfonyl group, an aryloxysulfonyl group, a sulfinamoyl group, a phosphono group (—PO₃H₂) and a conjugate basic group thereof (which is referred to as a phosphonato group), a phosphonoxy group (—OPO₃H₂) and a conjugate basic group thereof (which is referred to as a phosphonatoxy group), a cyano group, a nitro group, an aryl group, an alkenyl group, an alkynyl group, a heterocyclic group, a silyl group, and an alkyl group.

Among these substituents, a halogen atom, an alkyl group, and an alkoxy group are particularly preferable. Examples of the alkyl group include the same groups as those exemplified previously for R₁.

When n≧2, each Ar independently represents an aromatic cyclic group. This aromatic cyclic group may include a heterocycle as an aromatic ring. In addition, this aromatic ring may be monocyclic or polycyclic.

The aromatic cyclic group preferably has 6 to 14 carbon atoms, and examples thereof include an aryl group such as a phenyl group, a naphthyl group, and an anthryl group. When the aromatic cyclic group includes a heterocycle, examples of the heterocycle include a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring.

The aromatic cyclic group represented by Ar is preferably a phenyl group or a naphthyl group, and particularly preferably a phenyl group.

The aromatic cyclic group represented by Ar may further include a substituent, in addition to a group represented by —(X-A_{N}) described later. As the substituent, substituents exemplified previously as substituents in R₁ can be used.

In the aromatic cyclic group represented by Ar, the group represented by —(X-A_{N}) has been substituted.

When o≧2 and/or n≧2 each X independently represents a single bond or a linking group having a carbon atom as a binding portion to the Ar. At least one X is preferably a linking group having a carbon atom as a binding portion to the Ar. In this case, the basicity of the compound (C) becomes relatively high.

The linking group represented by X is not particularly limited as long as the linking group has a carbon atom as a binding portion to the Ar. This linking group includes, for example, an alkylene group, a cycloalkylene group, an arylene group, —COO—, —CO—, or a combination thereof. This linking group may include a combination of each of these groups and at least one group selected from a group consisting of —O—, —S—, —OCO—, —S(═O)—, —S(═O)₂—, —OS(═O)₂—, and —NR—. Herein, R represents, for example, a hydrogen atom, an alkyl group, a cycloalkyl group, or an aryl group.

The alkylene group that the linking group represented by X can include may be linear or branched. The number of carbon atoms of the alkylene group is preferably 1 to 20, and more preferably 1 to 10. Examples of the alkylene group include a methylene group, an ethylene group, a propylene group, and a butylene group.

The cycloalkylene group that the linking group represented by X can include may be monocyclic or polycyclic. The number of carbon atoms of the cycloalkylene group is preferably 3 to 20, and more preferably 3 to 10. Examples of the cycloalkylene group include a 1,4-cyclohexylene group.

The number of carbon atoms of the arylene group that the linking group represented by X can include is preferably 6 to 20, and more preferably 6 to 10. Example of the arylene group include a phenylene group and a naphthylene group.

It is preferable that at least one X be represented by the following general formula (1-2) or (1-3).

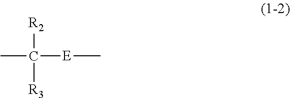

In the formula,

R₂ and R₃ represent a hydrogen atom, an alkyl group, an alkenyl group, an aliphatic cyclic group, an aromatic hydrocarbon group, or a heterocyclic hydrocarbon group. R₂ and R₃ may form a ring by binding to each other. At least one of R₂ and R₃ may form a ring by binding to E.

E represents a linking group or a single bond.

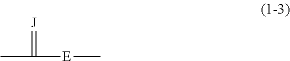

In the formula,

J represents an oxygen atom or a sulfur atom. J is preferably an oxygen atom.

E represents a linking group or a single bond.

Examples of the respective groups represented by R₂ and R₃ and substituents that these groups can further have include the same groups as those described previously for R₁. The ring that R₂ and R₃ can form by binding to each other and the ring that at least one of R₂ and R₃ form by binding to E are preferably 4 to 7-membered rings, and more preferably 5 or 6-membered rings. Each of R₂ and R₃ is preferably a hydrogen atom or an alkyl group independently.

The linking group represented by E includes, for example, an alkylene group, a cycloalkylene group, an arylene group, —COO—, —CO—, —O—, —S—, —OCO—, —S(═O)—, —S(═O)₂—, —OS(═O)₂—, —NR—, or a combination thereof.

The linking group represented by E is preferably at least one group selected from a group consisting of an alkylene bond, an ester bond, an ether bond, a thioether bond,

a urethane bond (a group represented by

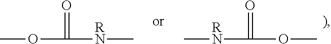

a urea bond (a group represented by

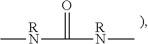

an amide bond, and a sulfonamide bond. Herein, R represents, for example, a hydrogen atom, an alkyl group, a cycloalkyl group, or an aryl group. The linking group represented by E is more preferably an alkylene bond, an ester bond, or an ether bond.

As described above, A_{N} represents a basic moiety including a nitrogen atom. Examples of the basic moiety include those described previously.

o represents an integer of 1 to 10. o is preferably an integer of 1 to 4, and more preferably 1 or 2.

The compound (C) may be a compound having a plurality of moieties including a nitrogen atom. For example, the compound (C) may be a compound in which at least one of R_{C} and R_{D} in general formula (II) has the structure represented by general formula (I).

Specific examples of the compound (C) will be shown below.

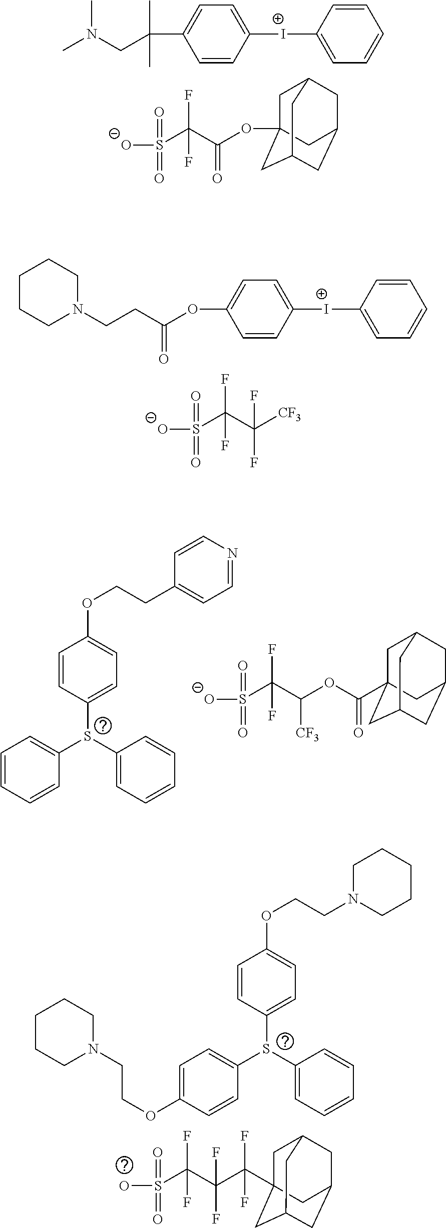

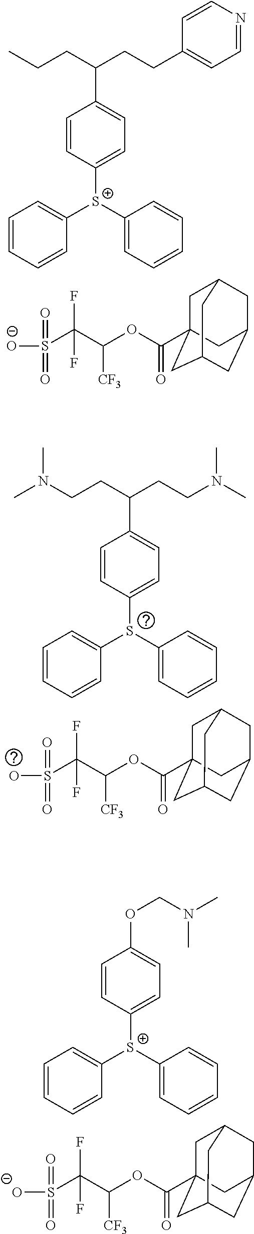

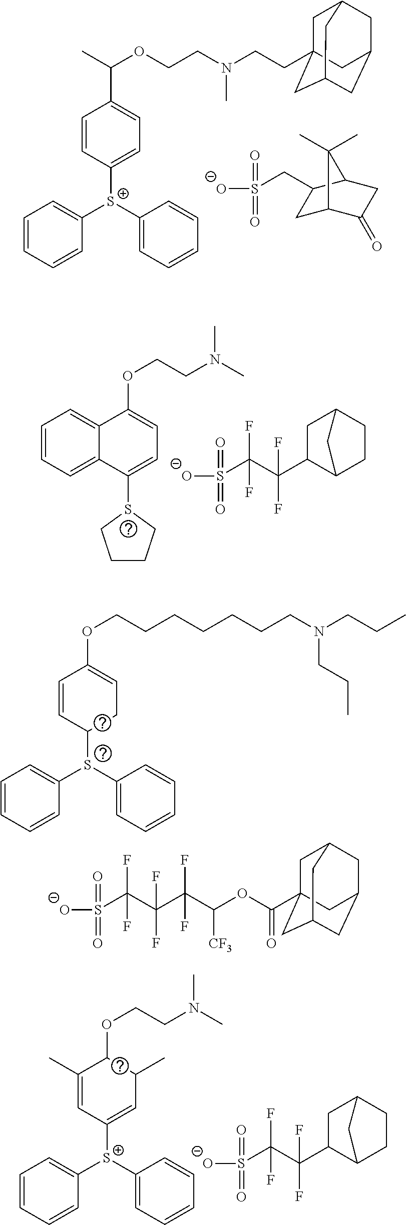

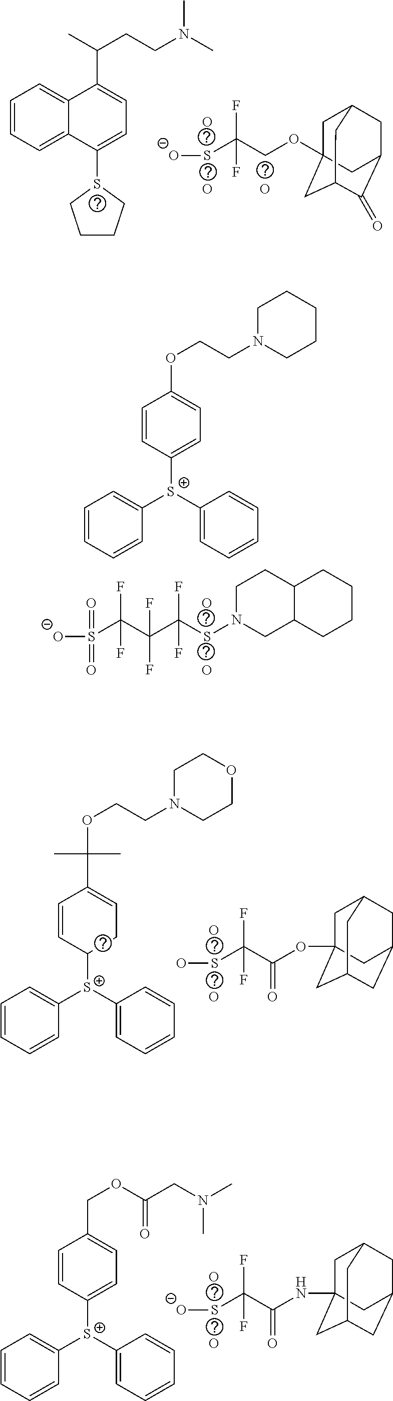

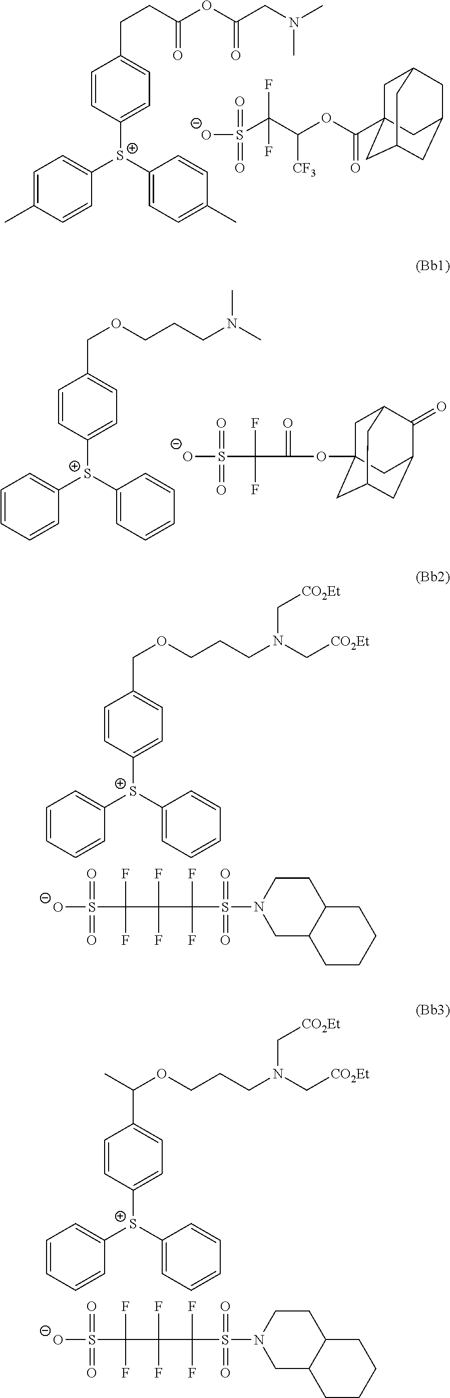

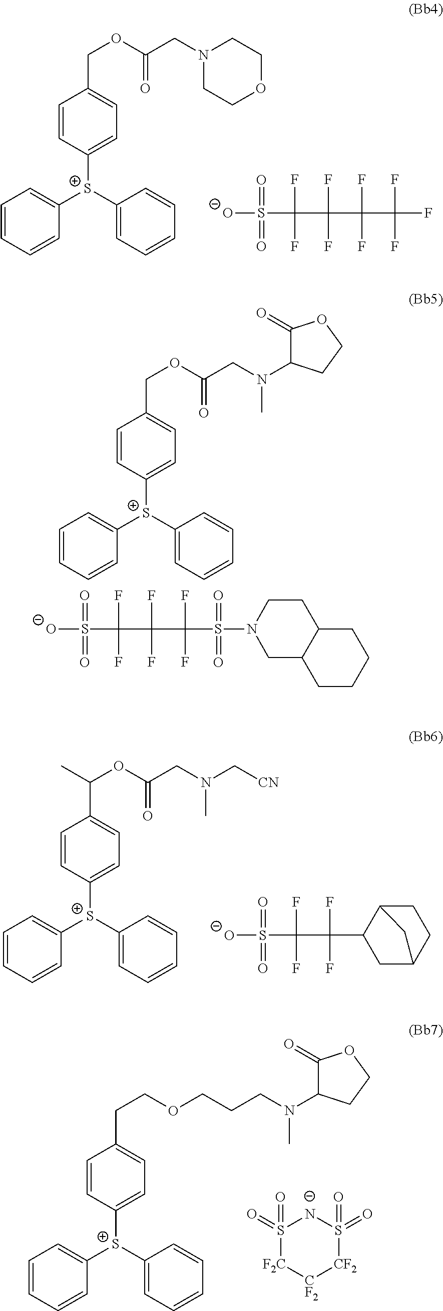

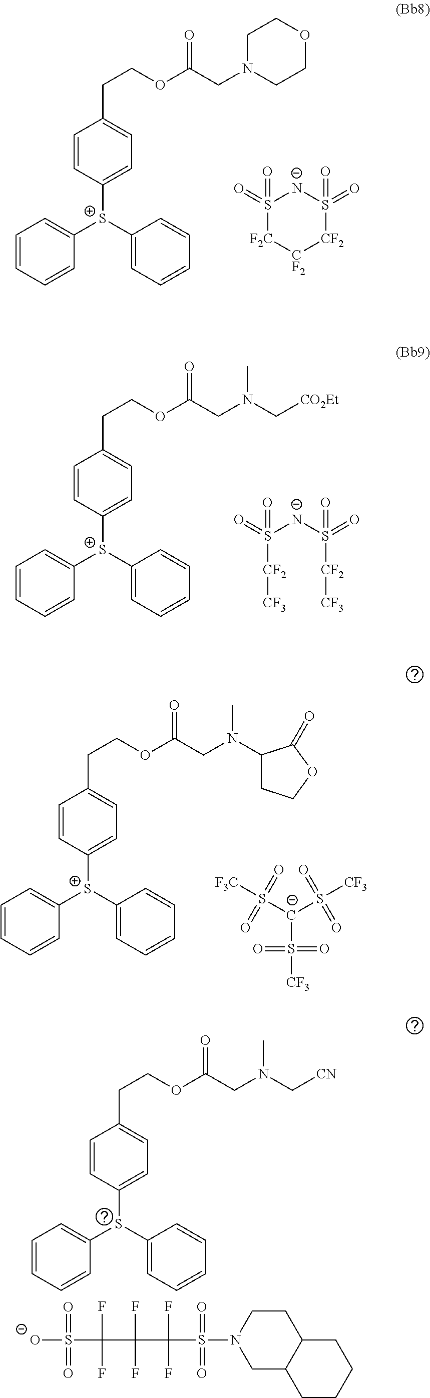

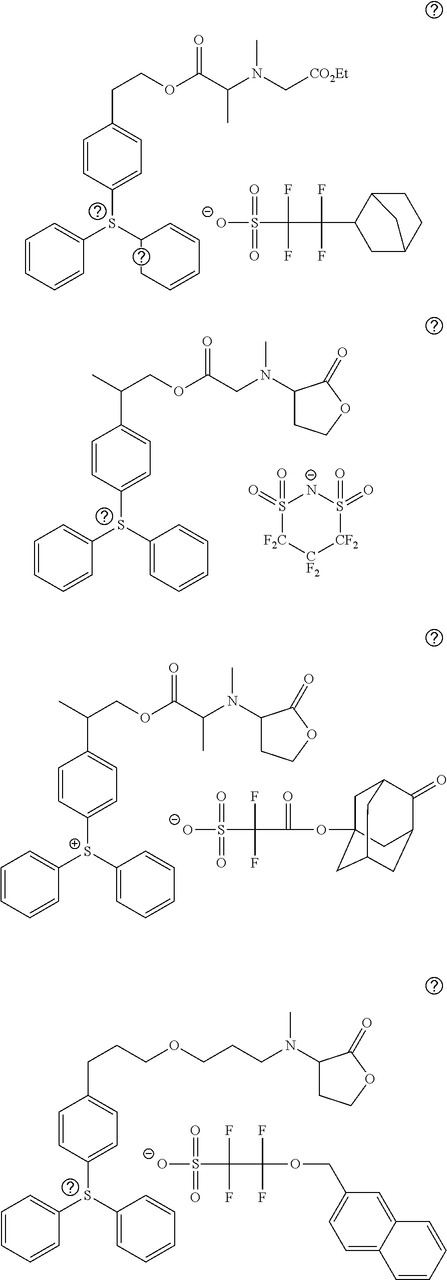

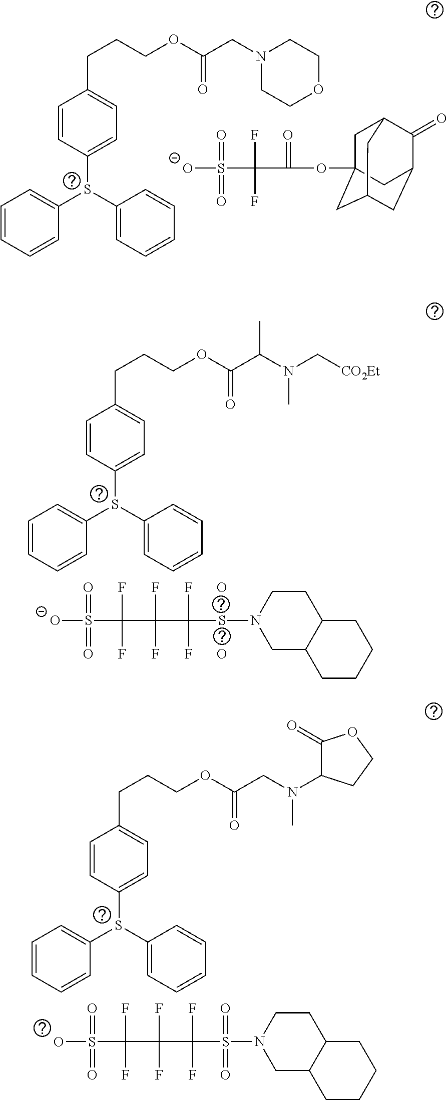

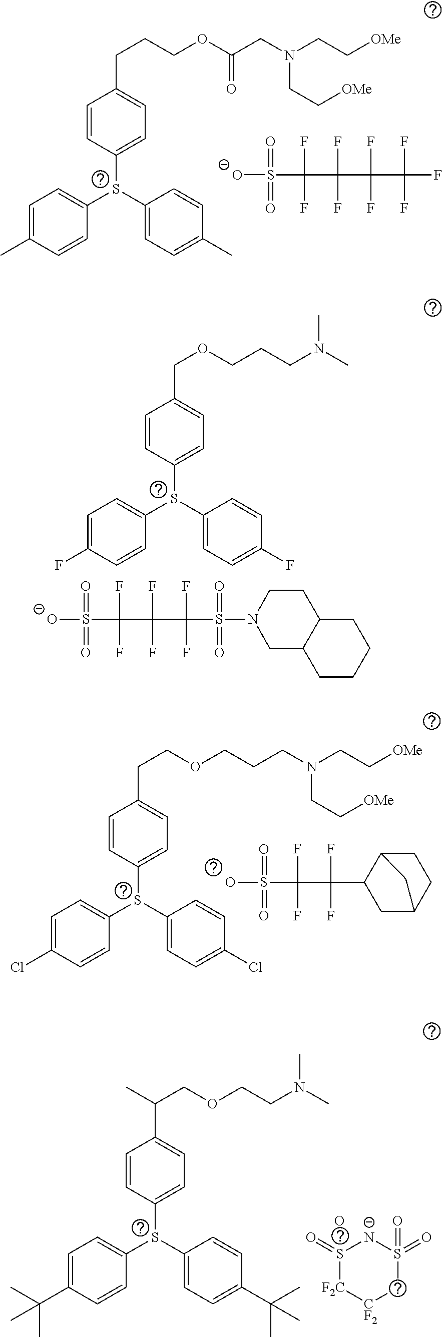

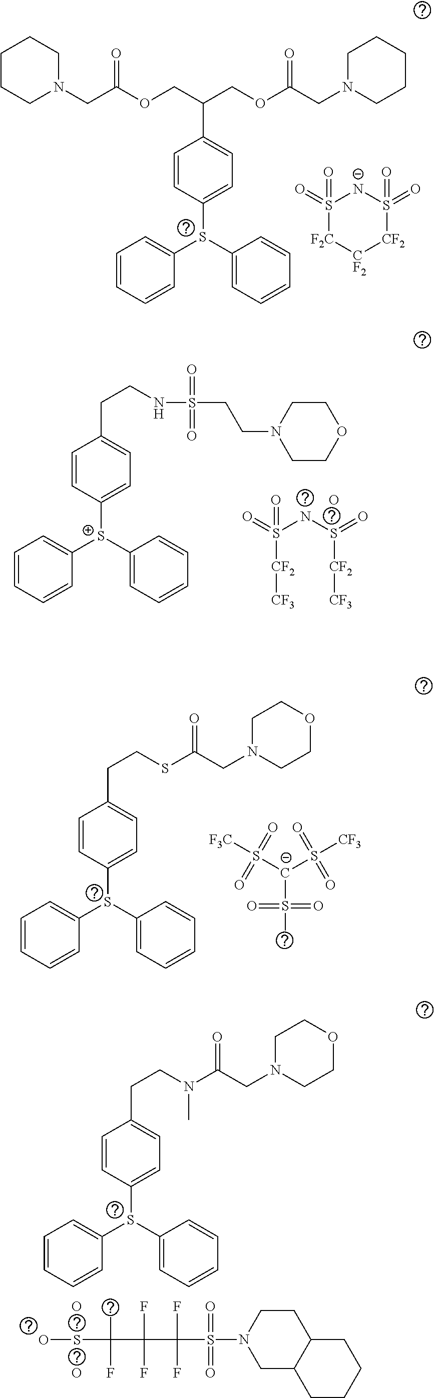

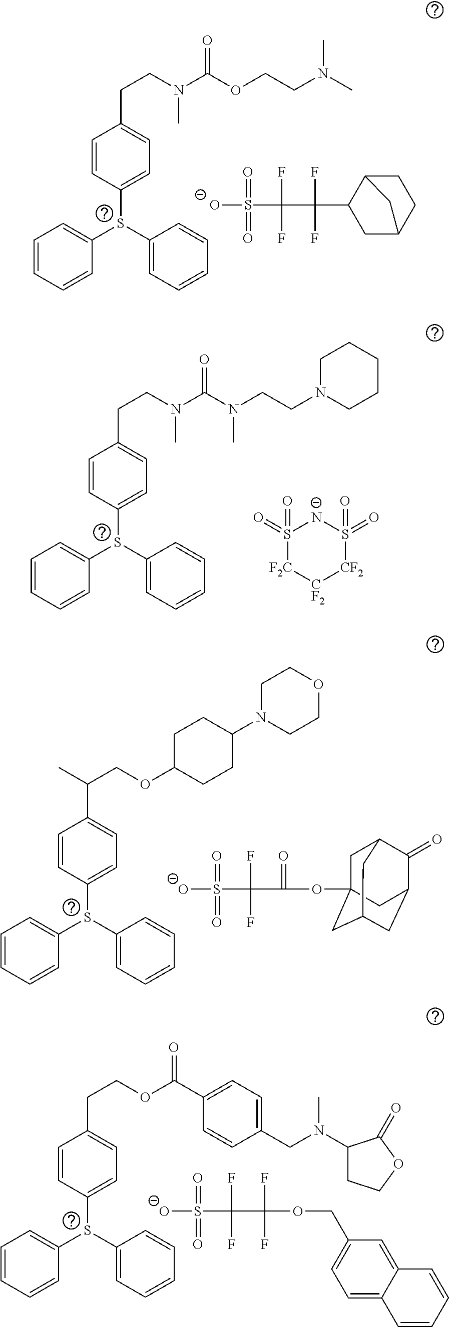

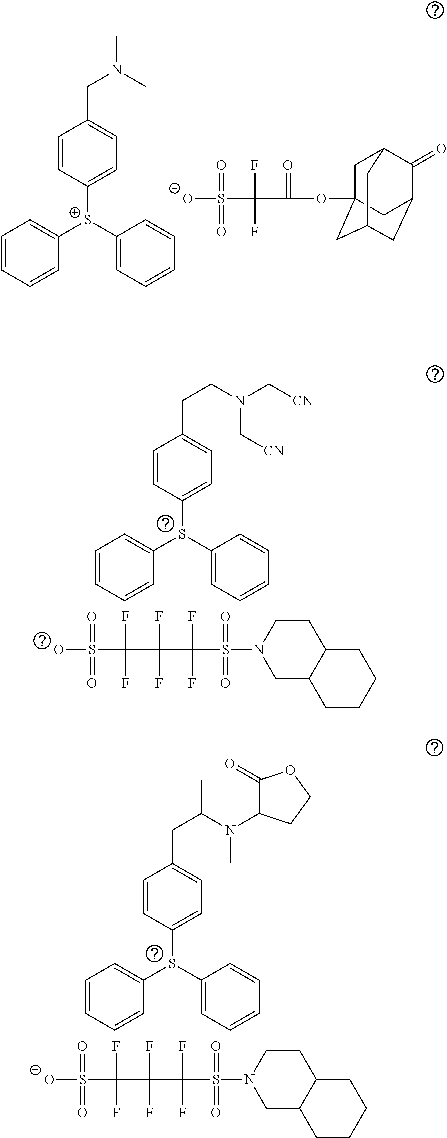

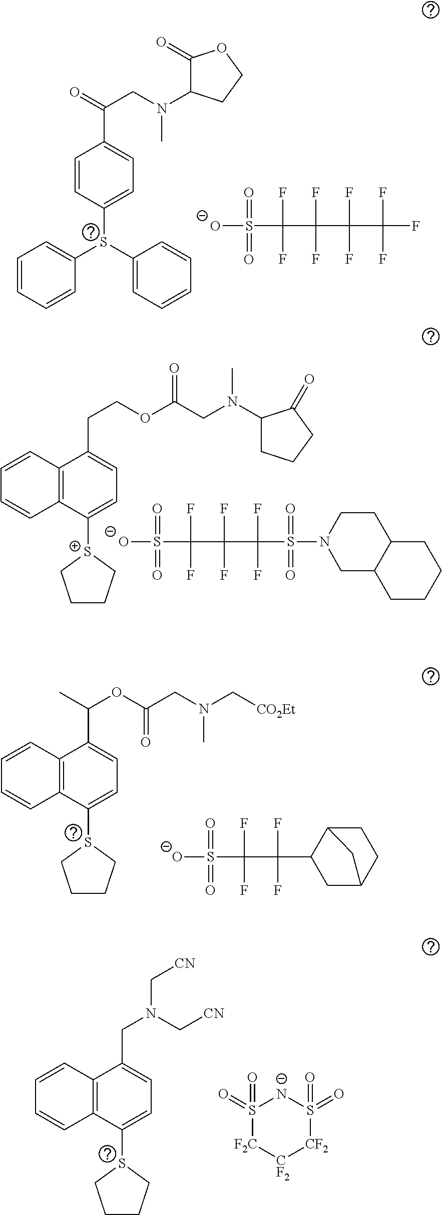

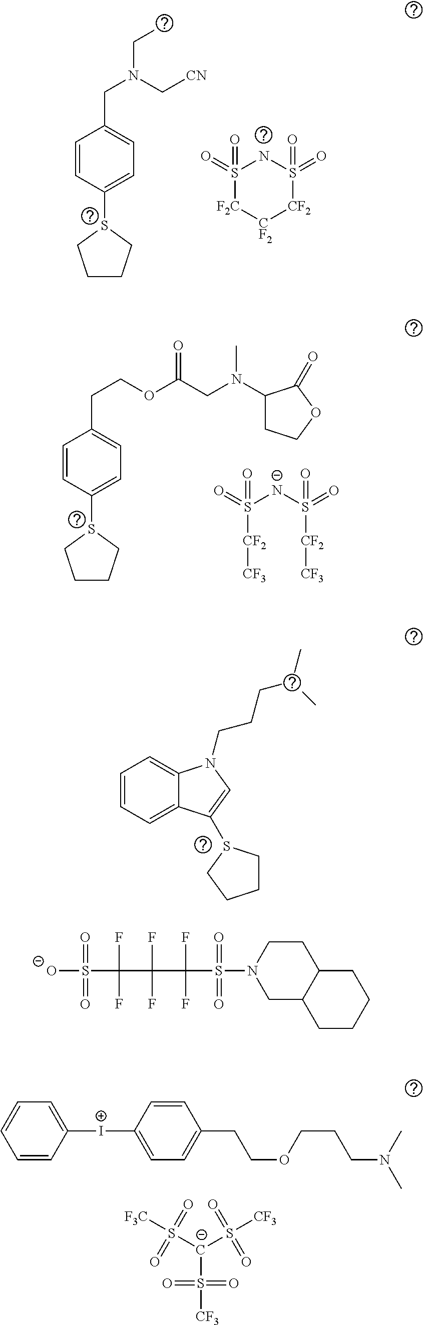

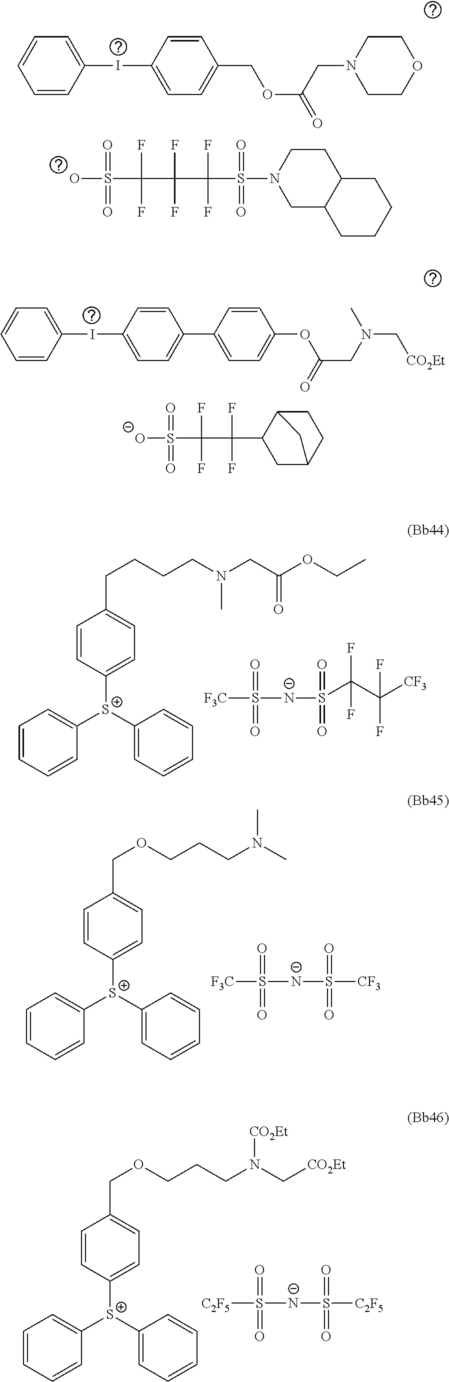

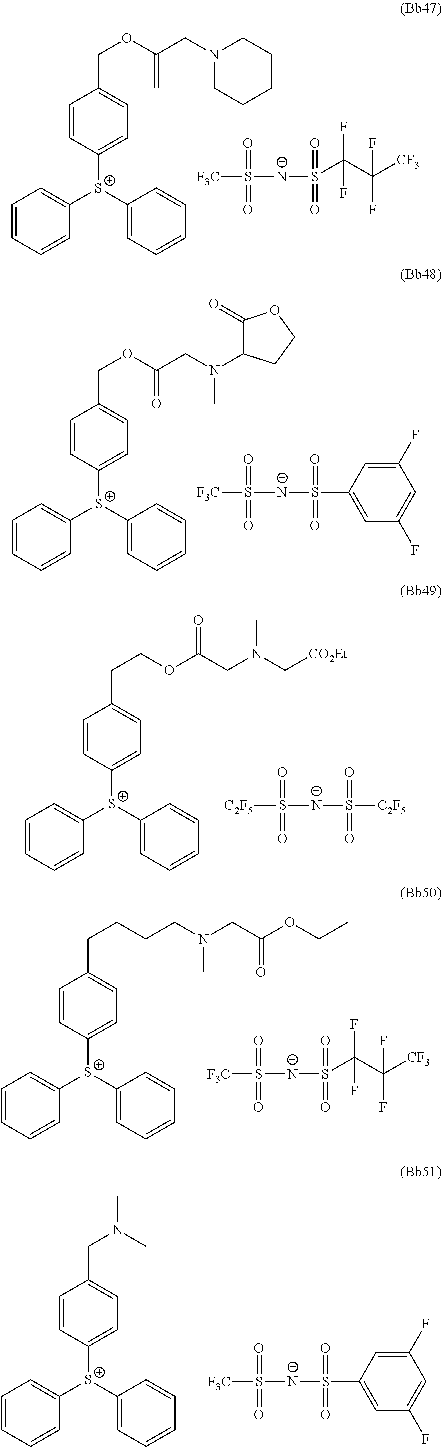

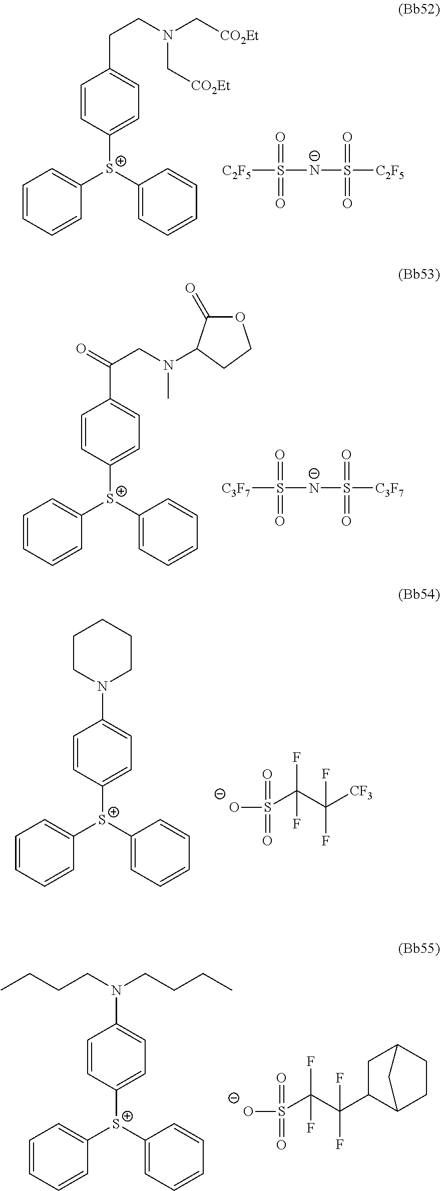

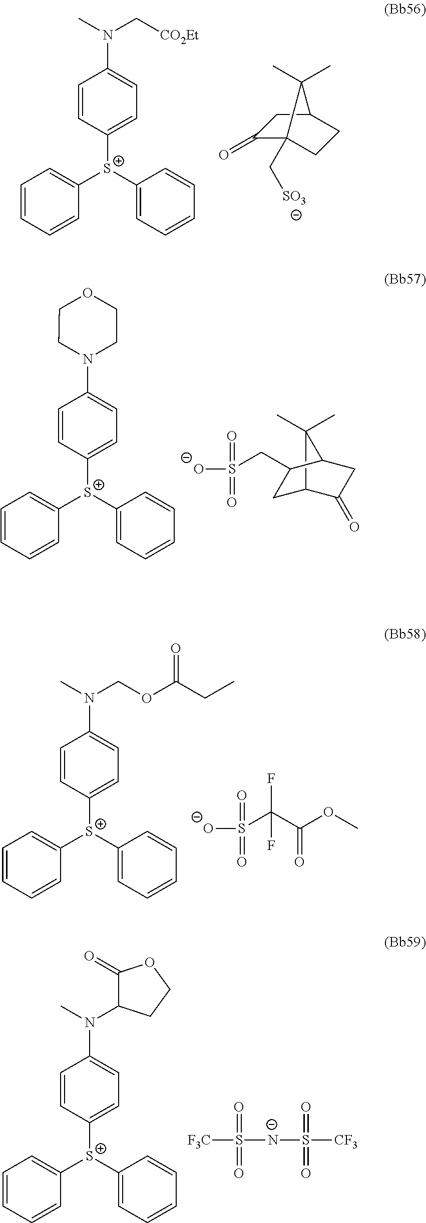

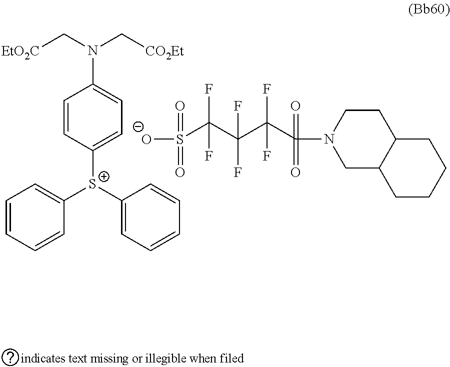

The compound (C) may be used alone or in combination of two or more kinds thereof.

The content of the compound (C) is generally in a range of from 0.001% to 15% by mass, and preferably in a range of from 1% to 10% by mass, based on the total solid contents of the composition.

The composition according to the present invention may further contain other components, in addition to the components (A) to (C) described above. Hereinafter, these arbitrary components will be described. Needless to say, in the composition of the present invention, the content (based on the solid content) of the components (A) to (C) and arbitrary components (for example, components (D) to (J) described later) does not exceed 100% by mass in total.

(D) Acid-Generating Agent Other than Compound (C)

It is preferable that the composition of the present invention further contain an acid-generating agent (which is also referred to as a compound (D) hereinbelow) other than the compound (C).

As the acid-generating agent, a photoinitiator of photo-cation polymerization, a photoinitiator of photo-radical polymerization, a photo-color eraser for pigments, a photo-discoloring agent, or a well-known compound that is used for a micro resist and generates acid by being irradiated with actinic-rays or radiations and a mixture thereof can be appropriately selected and used.

Examples of the acid-generating agent include a diazonium salt, a phosphonium salt, a sulfonium salt, an iodonium salt, imidosulfonate, oxime sulfonate, diazodisulfone, disulfone, and o-nitrobenzyl sulfonate.

In addition, the groups generating acid by being irradiated with actinic-rays or radiations, or compounds in which a compound has been introduced to the main chain or side chain of a polymer, for example, compounds disclosed in U.S. Pat. No. 3,849,137A, DE3914407B, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like can be used.

The compounds generating acid by light, which are disclosed in U.S. Pat. No. 3,779,778A, EP126712B, and the like can also be used.

Examples of preferable compounds among the acid-generating agents include compounds represented by the following general formulae (ZI), (ZII), and (ZIII).

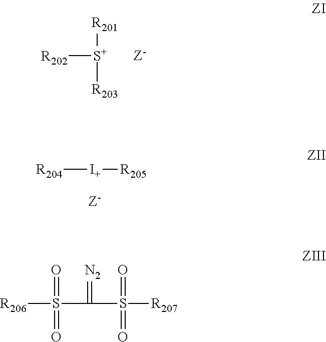

In general formula (ZI),

each of R₂₀₁, R₂₀₂, and R₂₀₃ independently represents an organic group.

The number of carbon atoms of the organic group represented by R₂₀₁, R₂₀₂, and R₂₀₃ is generally 1 to 30, and preferably 1 to 20.

Two of R₂₀₁ to R₂₀₃ may form a ring structure by binding to each other, and the ring may include an oxygen atom, a sulfur atom, an ester bond, an amide bond, or a carbonyl group in the ring. Examples of the group that two of R₂₀₁ to R₂₀₃ form by binding to each other include an alkylene group (for example, a butylene group or a pentylene group).

Z⁻ represents a non-nucleophilic anion.

Examples of Z⁻ include the same anions as those described previously in regard to the anion portion in the compound (C). Z⁻ and the anion portion in the compound (C) may be the same as or different from each other. Here, from the viewpoint of inhibiting a salt-interchange reaction between the compound (C) and compound (D), it is preferable to employ the former constitution.

Examples of the organic group represented by R₂₀₁, R₂₀₂, and R₂₀₃ include groups corresponding to a compound (ZI-1), (ZI-2), (ZI-3), or (ZI-4) described later.

In addition, the organic group may be a compound having a plurality of structures represented by general formula (ZI). For example, the organic group may be a compound having a structure in which at least one of R₂₀₁ to R₂₀₃ of the compound represented by general formula (ZI) binds to at least one of R₂₀₁ to R₂₀₃ of another compound represented by general formula (ZI).

Examples of more preferable (ZI) components include compounds (ZI-1), (ZI-2), (ZI-3), and (ZI-4) described below.

The compound (ZI-1) is an aryl sulfonium compound in which at least one of R₂₀₁ to R₂₀₃ of general formula (ZI) is an aryl group, that is, a compound having aryl sulfonium as a cation.

In the aryl sulfonium compound, all of R₂₀₁ to R₂₀₃ may be aryl groups; alternatively, a portion of R₂₀₁ to R₂₀₃ may be an aryl group, and the remaining group may be an alkyl group or a cycloalkyl group.

Examples of the aryl sulfonium compound include a triaryl sulfonium compound, a diaryl alkyl sulfonium group, an aryl dialkyl sulfonium compound, a diaryl cycloalkyl sulfonium compound, and an aryl dicycloalkyl sulfonium compound.

As the aryl group of the aryl sulfonium compound, a phenyl group and a naphthyl group are preferable, and a phenyl group is more preferable. The aryl group may be an aryl group having a heterocyclic structure including an oxygen atom, a nitrogen atom, a sulfur atom, and the like. Examples of the heterocyclic structure include pyrrole, furan, thiophene, indole, benzofuran, benzothiophene, and the like. When the aryl sulfonium compound has two or more aryl groups, the two or more aryl groups may be the same as or different from each other.

The alkyl group or cycloalkyl group that the aryl sulfonium compound optionally has is preferably a linear or branched alkyl group having 1 to 15 atoms and a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, a cyclohexyl group, and the like.

The aryl group, alkyl group, and cycloalkyl group of R₂₀₁ to R₂₀₃ may have an alkyl group (having 1 to 15 carbon atoms, for example), a cycloalkyl group (having 3 to 15 carbon atoms, for example), an aryl group (having 6 to 14 carbon atoms, for example), an alkoxy group (having 1 to 15 carbon atoms, for example), a halogen atom, a hydroxyl group, or a phenylthio group, as a substituent. The substituent is preferably a linear or branched alkyl group having 1 to 12 carbon atoms, a cycloalkyl group having 3 to 12 carbon atoms, a linear, branched, or cyclic alkoxy group having 1 to 12 carbon atoms, and more preferably an alkyl group having 1 to 4 carbon atoms or an alkoxy group having 1 to 4 carbon atoms. The substituent may be substituted with at least one out of three of R₂₀₁ to R₂₀₃, or may be substituted with all of three. When R₂₀₁ to R₂₀₃ are aryl groups, the substituent is preferably substituted with a p-position of the aryl group.

Next, the compound (ZI-2) will be described.

The compound (ZI-2) is a compound in which each of R₂₀₁ to R₂₀₃ in Formula (ZI) independently represents an organic group not having an aromatic ring. The aromatic ring herein includes an aromatic ring containing a hetero atom.

The organic group not containing an aromatic ring represented by R₂₀₁ to R₂₀₃ has generally 1 to 30 carbon atoms, and preferably 1 to 20 carbon atoms.

Each of R₂₀₁ to R₂₀₃ is independently an alkyl group, a cycloalkyl group, an allyl group, or a vinyl group preferably, and more preferably a linear or branched 2-oxoalkyl group, a 2-oxocycloalkyl group, or an alkoxycarbonyl methyl group, and particularly preferably a linear or branched 2-oxoalkyl group.

Preferable examples of the alkyl group and cycloalkyl group of R₂₀₁ to R₂₀₃ include a linear or branched alkyl group (for example, a methyl group, an ethyl group, a propyl group, a butyl group, or a pentyl group) having 1 to 10 carbon atoms and a cycloalkyl group (a cyclopentyl group, a cyclohexyl group, or a norbornyl group) having 3 to 10 carbon atoms. More preferable examples of the alkyl group include a 2-oxoalkyl group and an alkoxycarbonyl methyl group. More preferable examples of the cycloalkyl group include a 2-oxocycloalkyl group.

The 2-oxoalkyl group may be linear or branched, and more preferable examples thereof include a group having >C═O in the second position of the above alkyl group.

Preferable examples of the 2-oxocycloalkyl group include a group having >C═O in the second position of the above cycloalkyl group.

Preferable examples of the alkoxy group in the alkoxycarbonyl methyl group include an alkoxy group (a methoxy group, an ethoxy group, a propoxy group, a butoxy group, or a pentoxy group) having 1 to 5 carbon atoms.

R₂₀₁ to R₂₀₃ may be further substituted with a halogen atom, an alkoxy group (having 1 to 5 carbon atoms, for example), a hydroxyl group, a cyano group, or a nitro group.

The compound (ZI-3) is a compound represented by the following general formula (ZI-3), which is a compound having a phenacyl sulfonium salt structure.

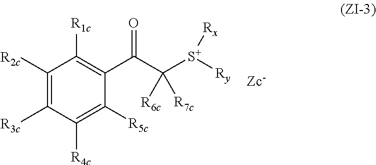

In general formula (ZI-3),

each of R_{1c} to R_{5c} independently represents a hydrogen atom, an alkyl group, a cycloalkyl group, an alkoxy group, a halogen atom or a phenylthio group.

Each of R_{6c} and R_{7c} independently represents a hydrogen atom, an alkyl group, a cycloalkyl group, a halogen atom, a cyano group, or an aryl group.

Each of Rₓ and R_{y} independently represents an alkyl group, a cycloalkyl group, a 2-oxoalkyl group, a 2-oxocycloalkyl group, an alkoxycarbonyl alkyl group, an aryl group, or a vinyl group.

Any two or more of R_{1c} to R_{5c}, R_{6c} and R_{7c}, and Rₓ and R_{y} may form a ring structure by binding to each other respectively, and this ring structure may include an oxygen atom, a sulfur atom an ester bond, or an amide bond. Examples of the group that any two or more of R_{1c} to R_{5c}, R_{6c} and R_{7c}, and Rₓ, and R_{y} form by binding to each other include a butylene group, a pentylene group, and the like.

Zc⁻ represents a non-nucleophilic anion, and examples thereof include the same non-nucleophilic anion represented by Z⁻ in general formula (ZI).

The alkyl group represented by R_{1c} to R_{7c} may be linear or branched. Examples of the alkyl group include an alkyl group having 1 to 20 carbon atoms, and preferably include a linear or branched alkyl group (for example, a methyl group, an ethyl group, a linear or branched propyl group, a linear or branched butyl group, or a linear or branched pentyl group) having 1 to 12 carbon atoms. Examples of the cycloalkyl group include a cycloalkyl group (for example, a cyclopentyl group or a cyclohexyl group) having 3 to 8 carbon atoms.

The alkoxy group represented by R_{1c} to R_{5c} may be linear, branched, or cyclic. Examples of the alkoxy group include an alkoxy group having 1 to 10 carbon atoms, and preferably include a linear or branched alkoxy group (for example, a methoxy group, an ethoxy group, a linear or branched propoxy group, a linear or branched butoxy group, or a linear or branched pentoxy group) having 1 to 5 carbon atoms and a cyclic alkoxy group (for example, a cyclopentyloxy group or a cyclohexyloxy group) having 3 to 8 carbon atoms.

Any one of R_{1c} to R_{5c} is preferably a linear or branched alkyl group, a cycloalkyl group, or a linear, branched, or cyclic alkoxy group. The sum of the number of carbon atoms of R_{1c}, to R_{5c} is more preferably 2 to 15. In this structure, solvent solubility is further improved, and the generation of particles during storage is inhibited.

The aryl group represented by R_{6c} and R_{7c} preferably includes 5 to 15 carbon atoms, and examples thereof include a phenyl group and a naphthyl group.

When R_{6c} and E_{7c} form a ring by binding to each other, the group that R_{6c} and R_{7c} form by binding to each other is preferably an alkylene group having 2 to 10 carbon atoms, and examples thereof include an ethylene group, a propylene group, a butylene group, a pentylene group, a hexylene group, and the like. The ring that R_{6c} and R_{7c} form by binding to each other may include a hetero atom of oxygen atoms and the like in the ring.

Examples of the alkyl group and cycloalkyl group represented by Rₓ and R_{y} include the same alkyl group and cycloalkyl group as those in R_{1c} to R_{7c}.

Examples of the 2-oxoalkyl group and 2-oxocycloalkyl group include a group having >C═O in the second position of the alkyl group and cycloalkyl group represented by R_{1c}, to R_{7c}.

Examples of the alkoxy group in the alkoxycarbonyl alkyl group include the same alkoxy group as that in R_{1c} to R_{5c}, and examples of the alkyl group include an alkyl group having 1 to 12 carbon atoms, and preferably include a linear alkyl group (for example, a methyl group or an ethyl group) having 1 to 5 carbon atoms.

There is no particular limitation on the aryl group, but the aryl group is preferably unsubstituted or substituted with a monocyclic or polycyclic cycloalkyl group.

There is no particular limitation on the vinyl group, but the vinyl group is preferably unsubstituted or substituted with a monocyclic or polycyclic cycloalkyl group.

Examples of the ring structure that Rₓ and R_{y} may form by binding to each other include 5 or 6-membered ring that divalent Rₓ and R_{y} (for example, a methylene group, an ethylene group, a propylene group, or the like) form along with a sulfur atom in general formula (ZI-3), and particularly preferably include a 5-membered ring (that is, a tetrahydrothiophene ring).

Rₓ and R_{y} are preferably an alkyl group or a cycloalkyl group having 4 or more carbon atoms, more preferably an alkyl group or a cycloalkyl group having 6 or more carbon atoms, and still more preferably an alkyl group or a cycloalkyl group having 8 or more carbon atoms.

Specific examples of a cation portion of the compound (ZI-3) will be shown below.

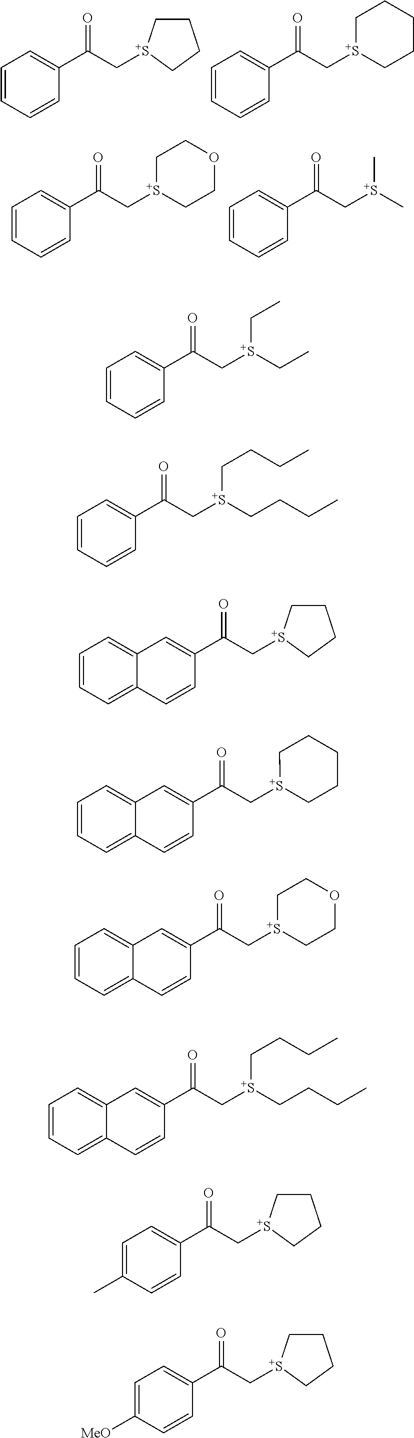

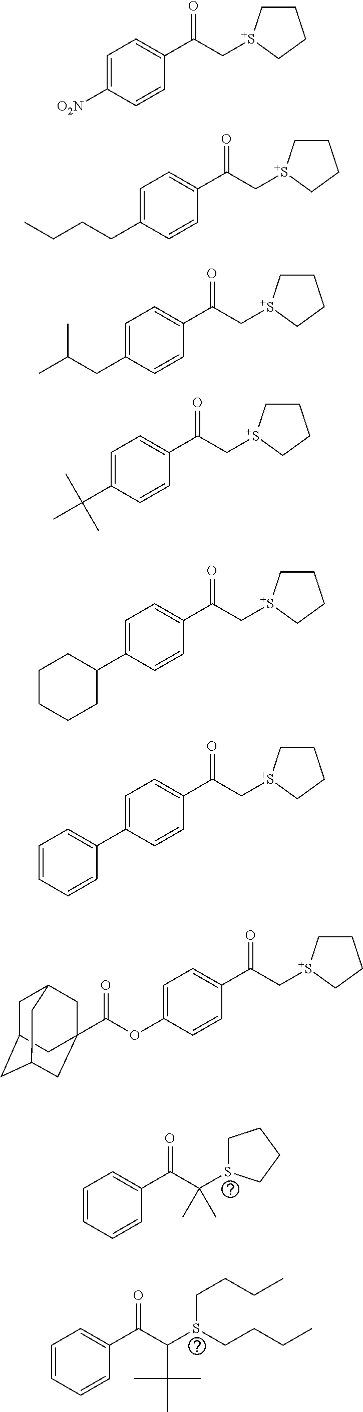

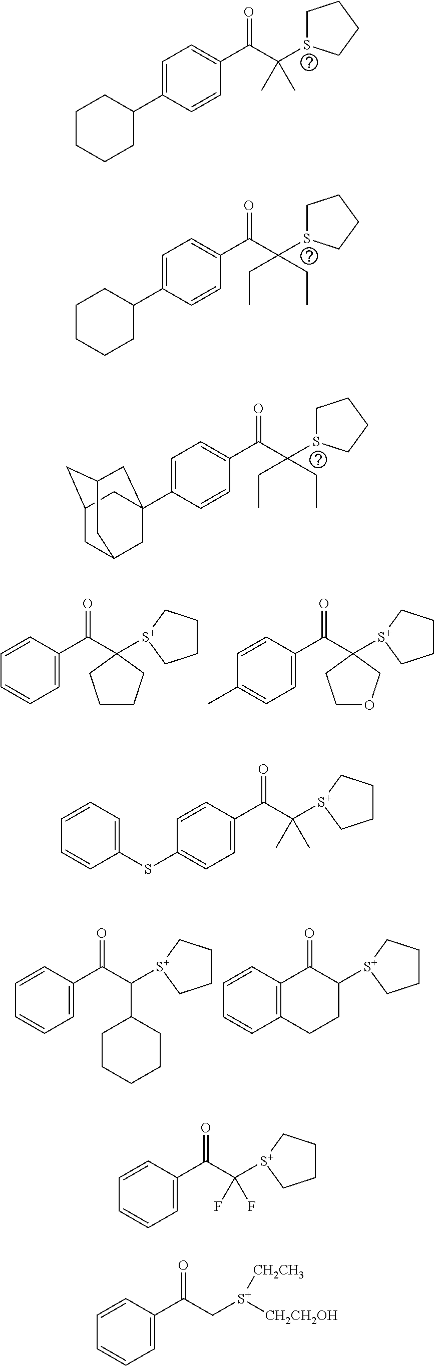

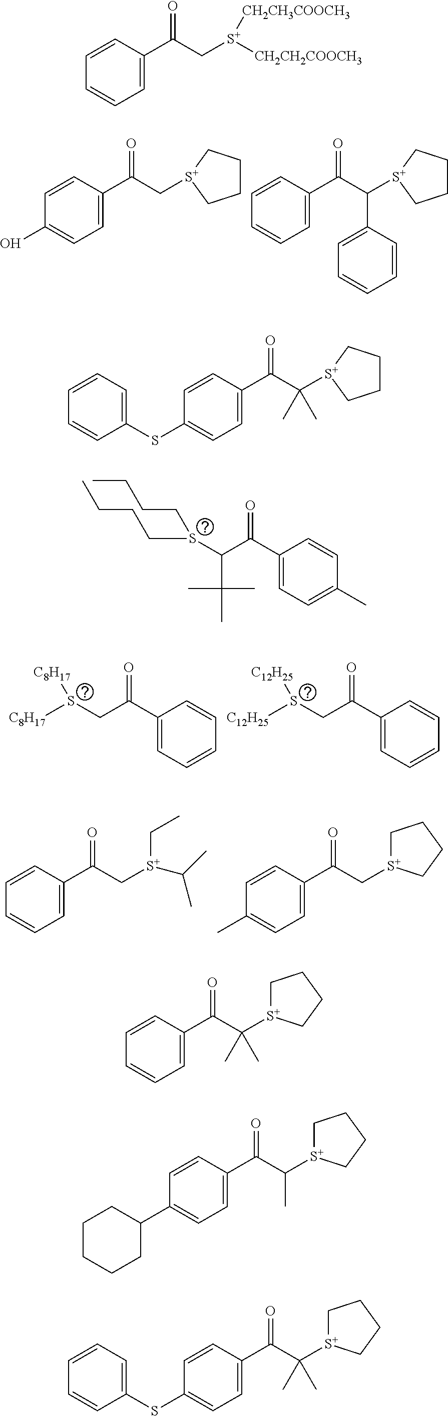

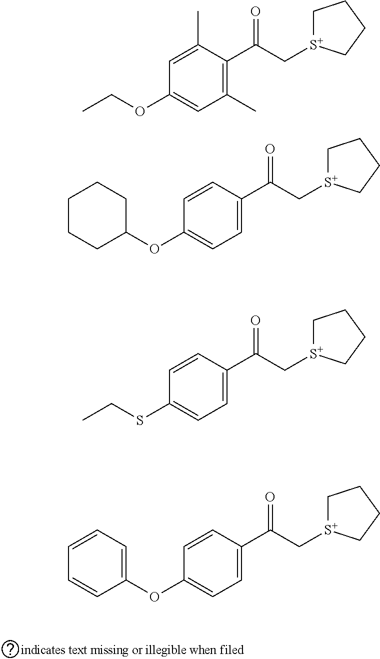

The compound (ZI-4) is a compound represented by the following general formula (ZI-4).

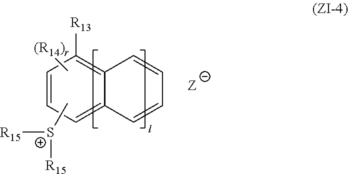

In general formula (ZI-4),

R₁₃ represents a hydrogen atom, a fluorine atom, a hydroxyl group, an alkyl group, a cycloalkyl group, an alkoxy group, an alkoxycarbonyl group, or a group having a monocyclic or polycyclic cycloalkyl skeleton. These groups may have a substituent.

When there is a plurality of R₁₄s, each R₁₄ independently represents an alkyl group, a cycloalkyl group, an alkoxy group, an alkoxycarbonyl group, an alkylcarbonyl group, an alkylsulfonyl group, a cycloalkylsulfonyl group, or a group having a monocyclic or polycyclic cycloalkyl skeleton. These groups may have a substituent.

Each R₁₅ independently represents an alkyl group, a cycloalkyl group, or a naphthyl group. Two R₁₅s may form a ring by binding to each other. These groups may have a substituent.

1 represents an integer of 0 to 2.

r represents an integer of 0 to 8.

Z⁻ represents a non-nucleophilic anion, and examples thereof include the same non-nucleophilic anion represented by Z⁻ in general formula (ZI).

In general formula (Z-14), the alkyl group of R₁₃, R₁₄, and R₁₅ may be linear or branched, and the number of carbon atoms thereof is preferably 1 to 10. Examples of the alkyl group include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group, and the like. Among these alkyl groups, a methyl group, an ethyl group, an n-butyl group, a t-butyl group, and the like are preferable.

Examples of the cycloalkyl group of R₁₃, R₁₄, and R₁₅ include cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclodecanyl, adamantyl, and the like. Particularly, cyclopropyl, cyclopentyl, cyclohexyl, and cyclooctyl are preferable.

The alkoxy group of R₁₃ and R₁₄ is linear or branched, and the number of carbon atoms thereof is preferably 1 to 10. Examples of the alkoxy group include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like. Among these alkoxy groups, a methoxy group, an ethoxy group, an n-propoxy group, an n-butoxy group, and the like are preferable.

The alkoxycarbonyl group of R₁₃ and R₁₄ is linear or branched, and the number of carbon atoms thereof is preferably 2 to 11. Examples of the alkoxycarbonyl group include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group, and the like. Among these alkoxycarbonyl groups, a methoxycarbonyl group, an ethoxycarbonyl group, an n-butoxycarbonyl group, and the like are preferable.

Examples of the group of R₁₃ and R₁₄, which have a monocyclic or polycyclic cycloalkyl skeleton, include a monocyclic or polycyclic cycloalkyloxy group and an alkoxy group having a monocyclic or polycyclic cycloalkyl group. These groups may further include a substituent.

The monocyclic or polycyclic cycloalkyloxy group of R₁₃ and R₁₄ preferably includes 7 or more carbon atoms in total, and more preferably includes 7 to 15 carbon atoms in total. In addition, the cycloalkyloxy group preferably includes a monocyclic cycloalkyl skeleton. Examples of the cycloalkyloxy group having 7 or more carbon atoms in total include a monocyclic cycloalkyloxy group such as a cyclopropyloxy group, a cyclobutyloxy group, a cyclopentyloxy group, a cyclohexyloxy group, a cycloheptyloxy group, a cyclooctyl group, a cyclododecanyloxy group, or the like which arbitrarily includes a substituent including an alkyl group such as a methyl group, an ethyl group, a propyl group, a butyl group, a pentyl group, a hexyl group, a heptyl group, an octyl group, a dodecy group, a 2-ethylhexyl group, an isopropyl group, a sec-butyl group, a t-butyl group, an iso-amyl group or the like; a hydroxyl group; a halogen atom (fluorine, chlorine, bromine, or iodine); a nitro group; an amino group; an amide group; a sulfonamide group; an alkoxy group such as a methoxy group, an ethoxy group, a hydroxyethoxy group, a propoxy group, a hydroxypropoxy group, a butoxy group, or the like; an alkoxycarbonyl group such as a methoxycarbonyl group, an ethoxycarbonyl group, or the like; an acyl group such as a formyl group, an acetyl group, a benzoyl group, or the like; an acyloxy group such as an acetoxy group, a butyryloxy group, or the like; and a carboxy group. Such a cycloalkyloxy group represents a cycloalkyloxy group having 7 or more carbon atoms in total obtained by adding the arbitrary substituent on the cycloalkyl group.

Examples of the polycyclic cycloalkyloxy group having 7 or more carbon atoms in total include a norbornyloxy group, a tricyclodecanyloxy group, a tetracyclodecanyloxy group, an adamantyloxy group, and the like.

The alkoxy group of R₁₃ and R₁₄, which have a monocyclic or polycyclic cycloalkyl skeleton, preferably has 7 or more carbon atoms in total, and more preferably has 7 to 15 carbon atoms in total. In addition, this alkoxy group is preferably an alkoxy group having a monocyclic cycloalkyl skeleton. The alkoxy group that has 7 or more carbon atoms in total and a monocyclic cycloalkyl skeleton is a group that is obtained in a manner in which a monocyclic cycloalkyl group which may have the substituent described above has been substituted with an alkoxy group such as methoxy, ethoxy, propoxy, butoxy, pentyloxy, hexyloxy, heptyloxy, octyloxy, dodecyloxy, 2-ethyl hexyl oxy, isopropoxy, sec-butoxy, t-butoxy, iso-amyloxy, or the like. This alkoxy group represents the alkoxy group having 7 or more carbon atoms in total which also includes the substituent. Examples of this alkoxy group include a cyclohexyl methoxy group, a cyclopentyl methoxy group, a cyclohexyl methoxy group, and the like, and among these, a cyclohexyl methoxy group is preferable.

Examples of the alkoxy group that has 7 or more carbon atoms in total and a polycyclic cycloalkyl skeleton, include a norbornyl methoxy group, a norbornyl ethoxy group, a tricyclodecanyl methoxy group, a tricyclodecanyl ethoxy group, a tetracyclodecanyl methoxy group, a tetracyclodecanyl ethoxy group, an adamantyl methoxy group, an adamantyl ethoxy group, and the like. Among these, a norbornyl methoxy group, a norbornyl ethoxy group, and the like are preferable.

Examples of the alkyl group of the alkylcarbonyl group of R₁₄ include the same specific examples as the alkyl group represented by R₁₃ to R₁₅ described above.

The alkylsolfonyl group and cycloalkylsulfonyl group of R₁₄ are preferably linear, branched, or cyclic, and preferably have 1 to 10 carbon atoms in total. Examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group, and the like. Among these alkylsulfonyl and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group, and the like are preferable.

Examples of the substituent that the above respective groups may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group, and the like.

Examples of the alkoxy group include a linear, branched, or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, a cyclohexyloxy group, and the like.

Examples of the alkoxyalkyl group include a linear, branched, or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, a 2-ethoxyethyl group, and the like.

Examples of the alkoxycarbonyl group include a linear, branched, or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, a cyclohexyloxycarbonyl group, and the like.

Examples of the alkoxycarbonyloxy group include a linear, branched, or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, a cyclohexyloxycarbonyloxy group, and the like.

Examples of the ring structure that two R₁₅ may form by binding to each other include a 5 or 6-membered ring that two divalent R₁₅ form along with a sulfur atom in general formula (ZI-4), and particularly, a 5-membered ring (that is, a tetrahydrothiophene ring) is preferable. This ring may be condensed with an aryl group or a cycloalkyl group. The divalent R₁₅ may have a substituent, and examples of the substituent include a hydroxyl group, a carboxy group, a cyano group, a nitro group, an alkoxy group, an alkoxyalkyl group, an alkoxycarbonyl group, an alkoxycarbonyloxy group, and the like. As R₁₅ in general formula (ZI-4), a methyl group, an ethyl group, a naphthyl group, a divalent group in which two R₁₅ₛ form a tetrahydrothiophene ring structure along with a sulfur atom by binding to each other, and the like are preferable.

As the substituent that R₁₃ and R₁₄ can have, a hydroxyl group, an alkoxy group, an alkoxycarbonyl group, and a halogen atom (particularly, a fluorine atom) are preferable.

1 is preferably 0 or 1, and more preferably 1.

r is preferably 0 to 2.

Specific examples of a cation portion of the compound (ZI-4) will be shown below.

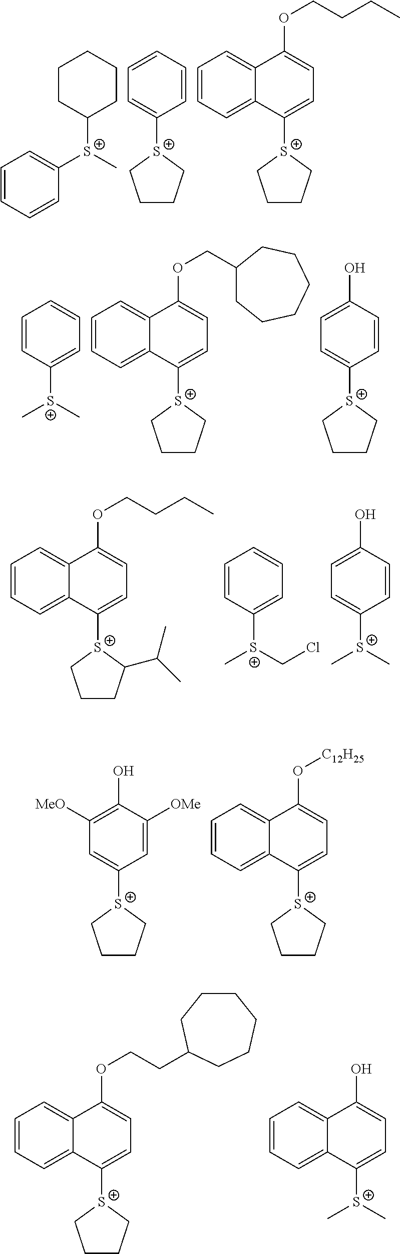

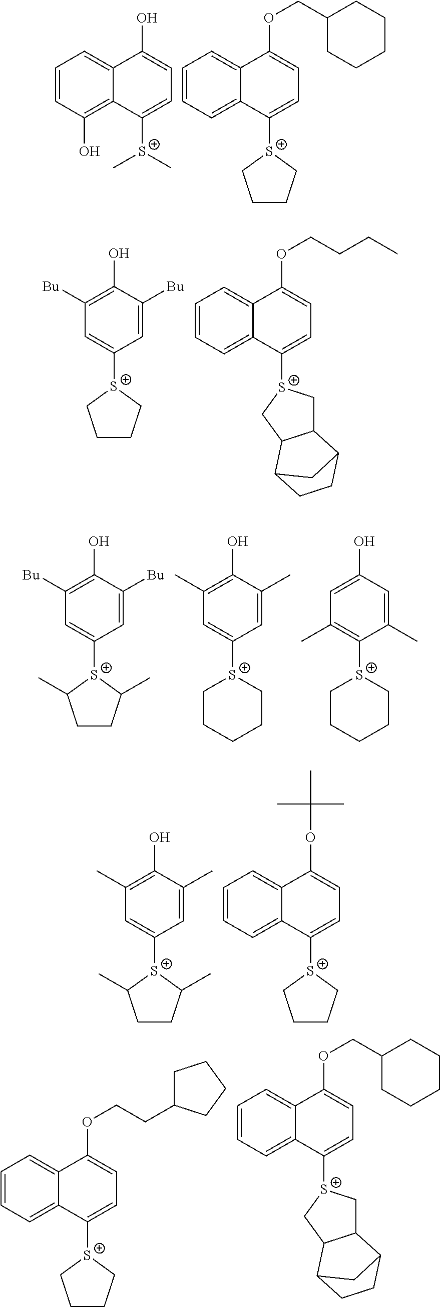

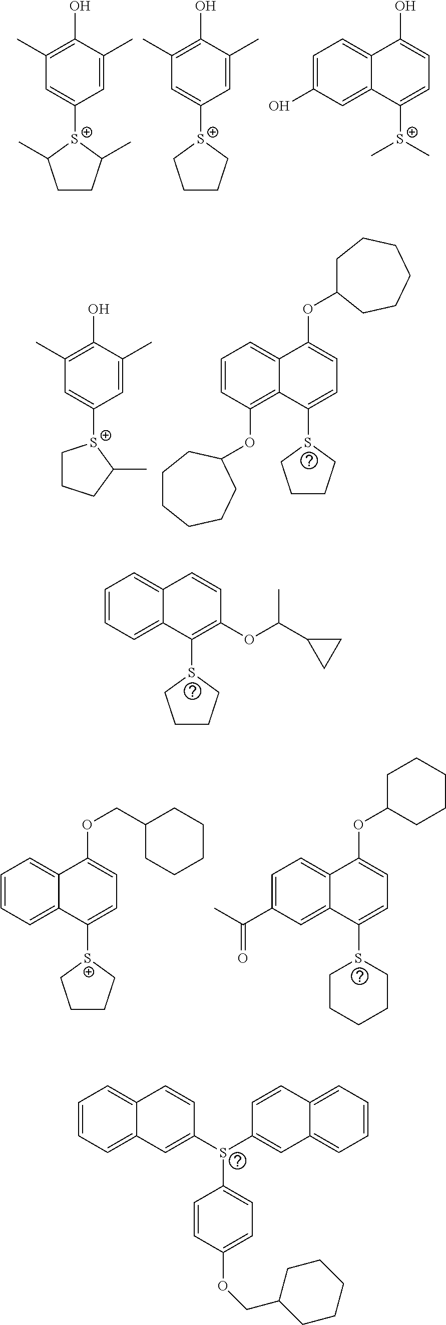

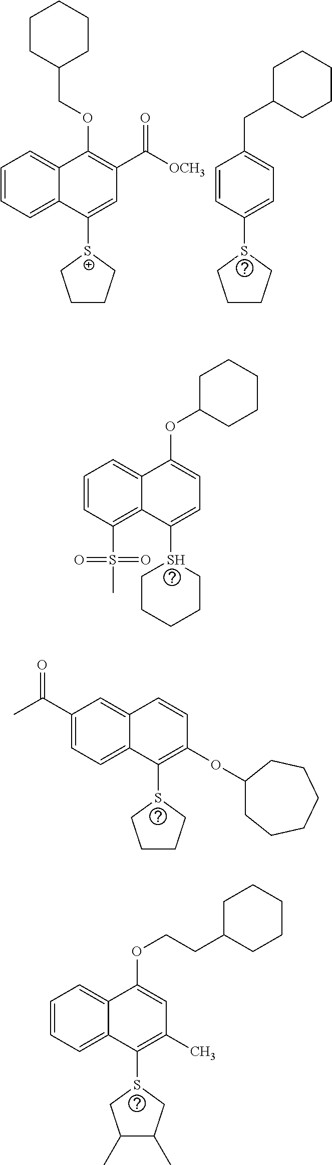

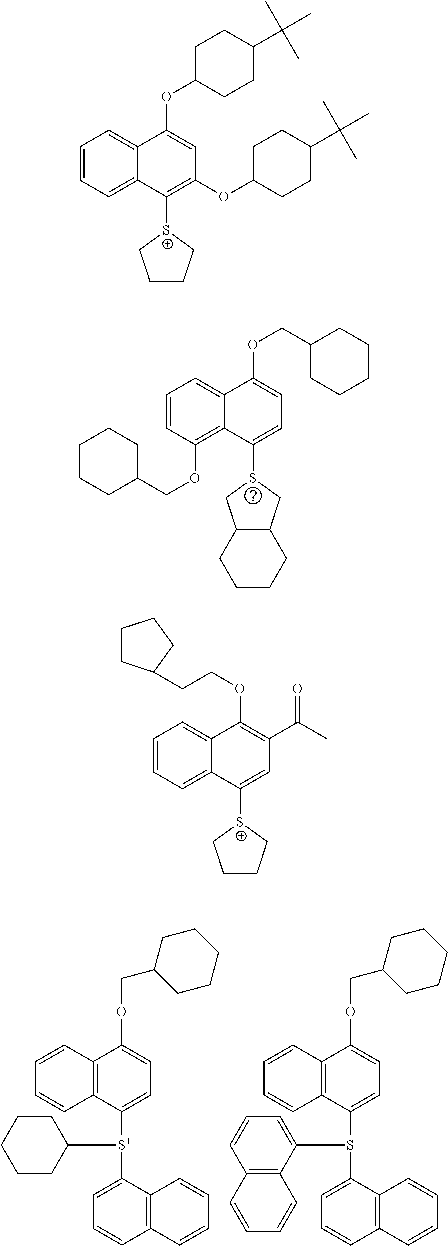

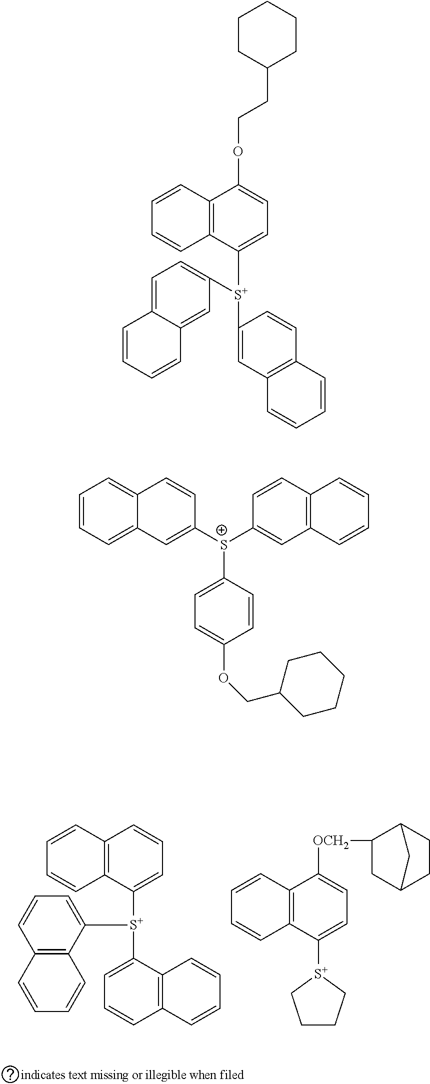

Next, the general formulae (ZII) and (ZIII) will be described.

In general formulae (ZII) and (ZIII), each of R₂₀₄ to R₂₀₇ independently represents an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure having an oxygen atom, a nitrogen atom, a sulfur atom, and the like. Examples of the heterocyclic structure include pyrrole, furan, thiophene, indole, benzofuran, benzothiophene, and the like.

Preferable examples of the alkyl group and cycloalkyl group in R₂₀₄ to R₂₀₇ include a linear or branched alkyl group (for example, a methyl group, an ethyl group, a propyl group, a butyl group, or a pentyl group) having 1 to 10 carbon atoms, and a cycloalkyl group (cyclopentyl group, cyclohexyl group, or norbornyl group) having 3 to 10 carbon atoms.

The aryl group, alkyl group, and cycloalkyl group of R₂₀₄ to R₂₀₇ may have a substituent. Examples of the substituent that the aryl group, alkyl group, and cycloalkyl group of R₂₀₄ to R₂₀₇ may have include an alkyl group (having 1 to 15 carbon atoms, for example), a cycloalkyl group (having 3 to 15 carbon atoms, for example), an aryl group (having 6 to 15 carbon atoms, for example), an alkoxy group (having 1 to 15 carbon atoms, for example), a halogen atom, a hydroxyl group, a phenylthio group, and the like.

Z⁻ represents a non-nucleophilic anion, and examples thereof include the same anion as the non-nucleophilic anion of Z⁻ in general formula (ZI).

Examples of the acid-generating agent further include compounds represented by the following general formulae (ZIV), (ZV), and (ZVI).

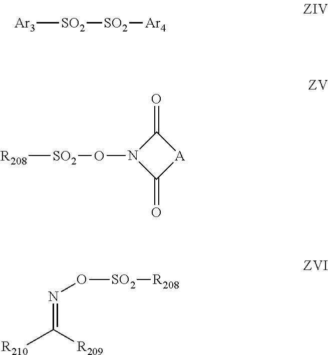

In general formulae (ZIV) to (ZVI),

each of Ar₃ and Ar₄ independently represents an aryl group.

Each of R₂₀₈, R₂₀₉, and R₂₁₀ independently represents an alkyl group, a cycloalkyl group, or an aryl group.

A represents an alkylene group, an alkenylene group, or an arylene group.

Among the acid-generating agents, the compounds represented by general formulae (ZI) to (ZIII) are preferable.

Moreover, the acid-generating agent is preferably a compound generating acid having one sulfonic acid group or imide group, more preferably a compound generating monovalent perfluoroalkane sulfonic acid, a compound generating aromatic sulfonic acid substituted with a monovalent fluorine atom or a group containing a fluorine atom, or a compound generating imidic acid substituted with a monovalent fluorine atom or a group containing a fluorine atom, and still more preferably a sulfonium salt of fluorinated alkanesulfonic acid, fluorine-substituted benzenesulfonic acid, fluorine-substituted imidic acid, or fluorine-substituted methidic acid. The usable acid-generating agent is particularly preferably fluorinated alkanesulfonic acid generating acid of pKa=−1 or less, fluorinated benzenesulfonic acid, or fluorinated imidic acid, and this acid-generating agent improves sensitivity.

Among the acid-generating agents, particularly preferable examples will be shown below.

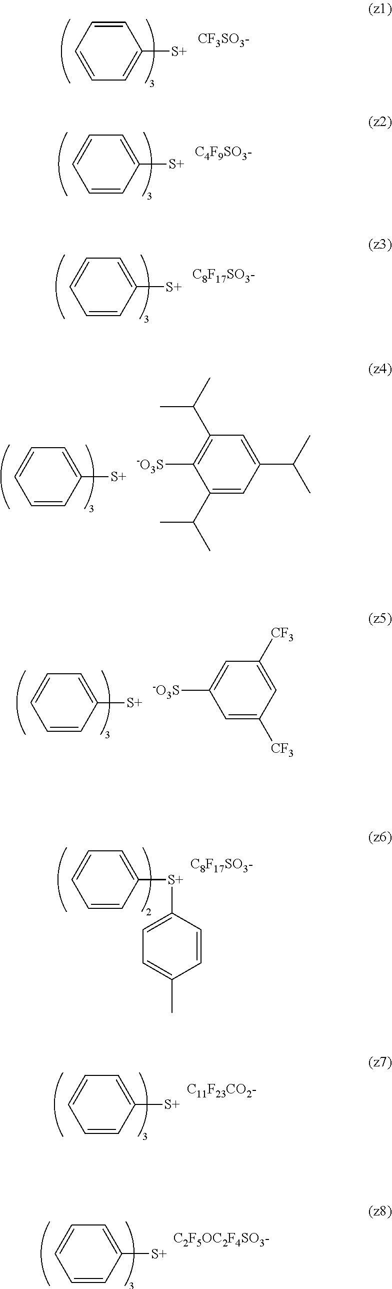

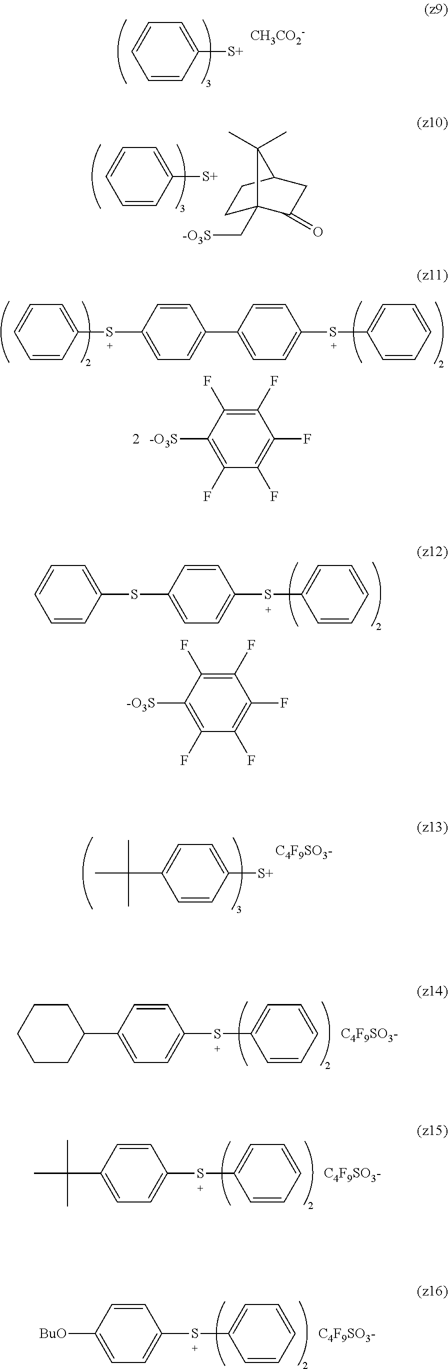

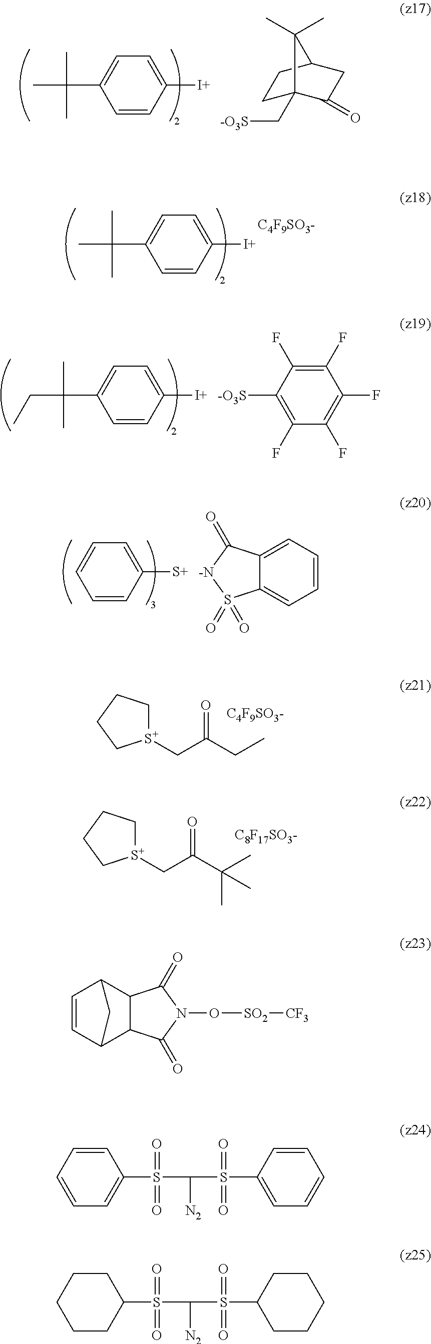

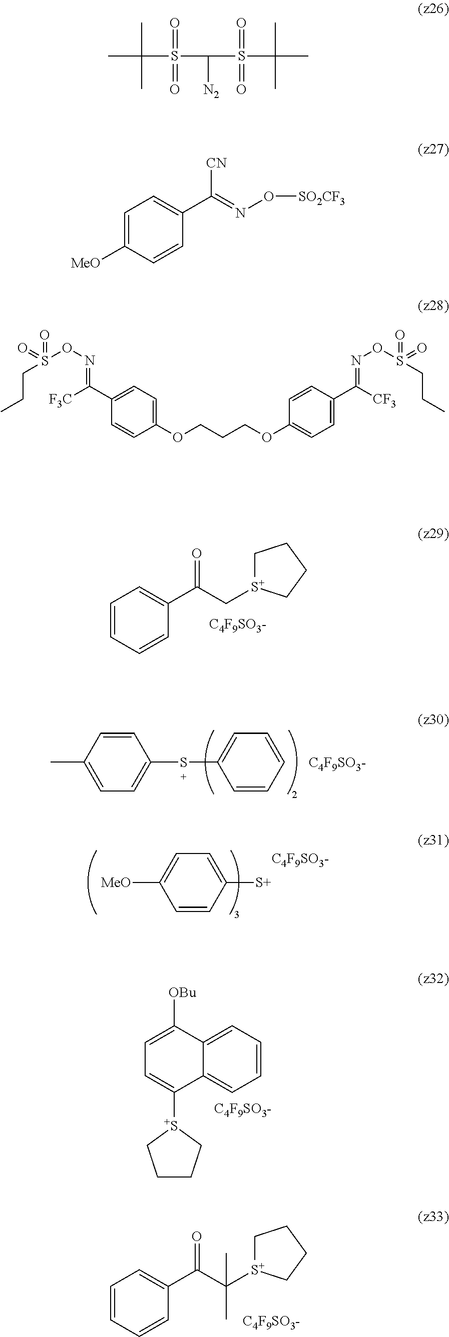

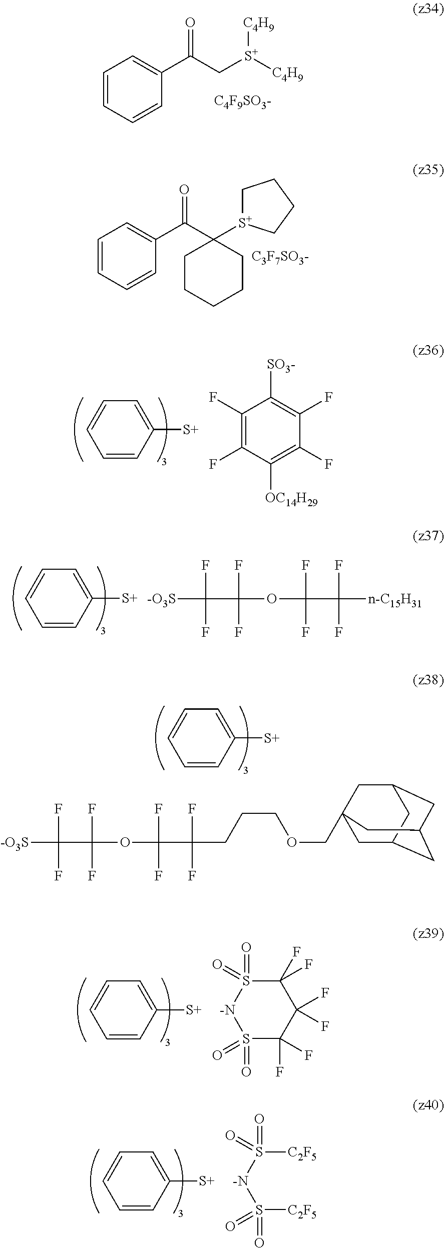

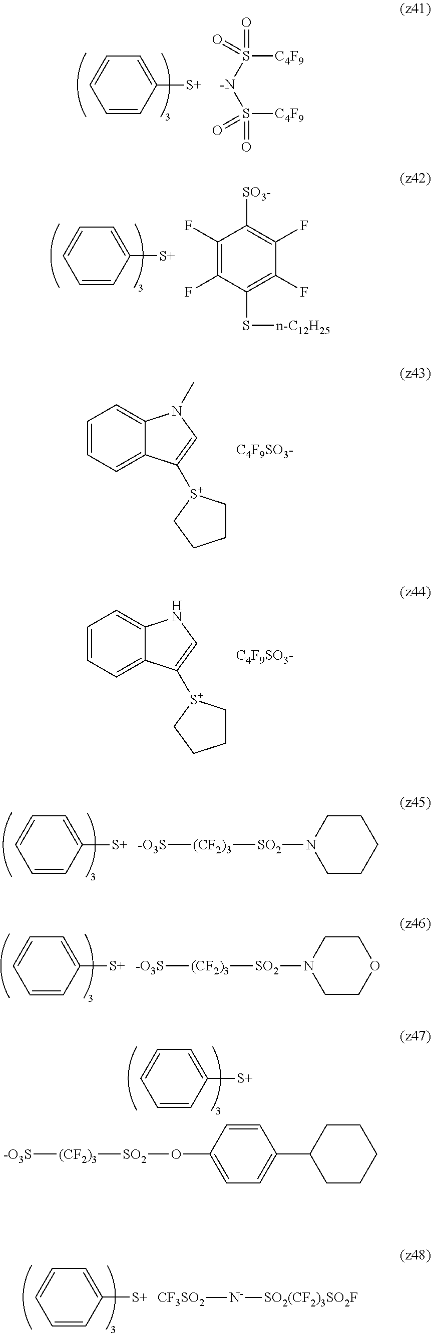

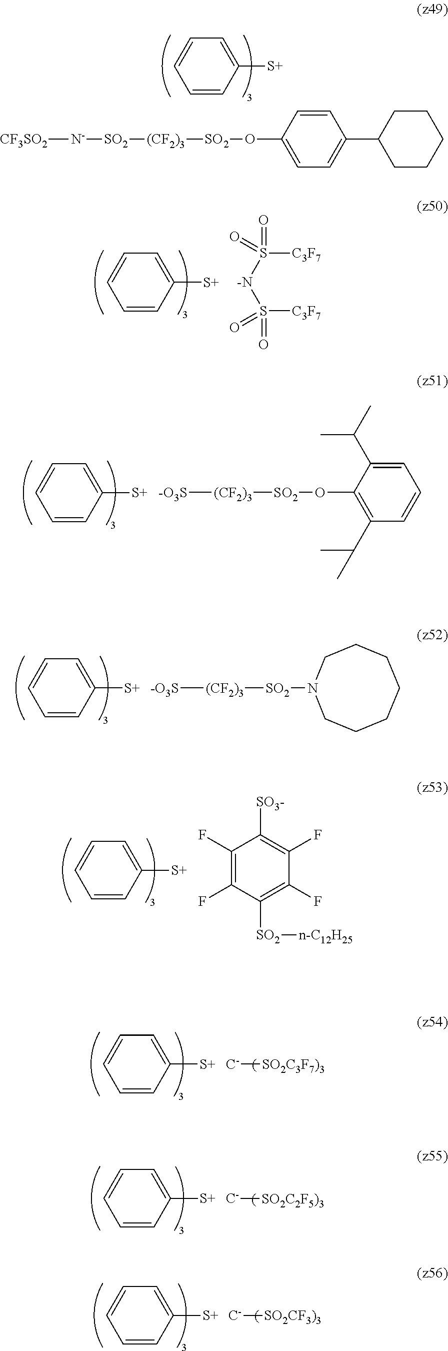

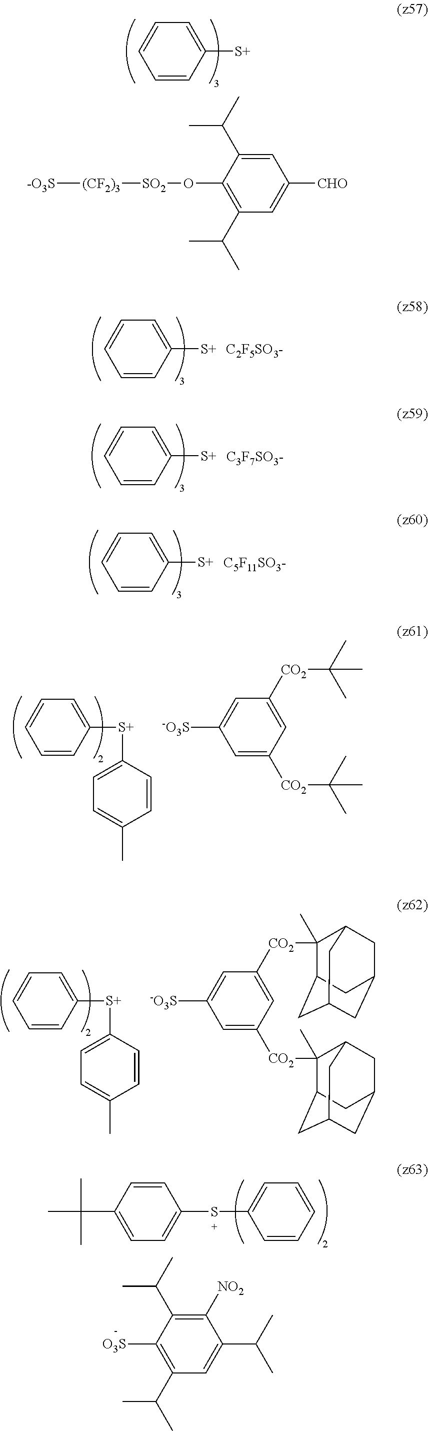

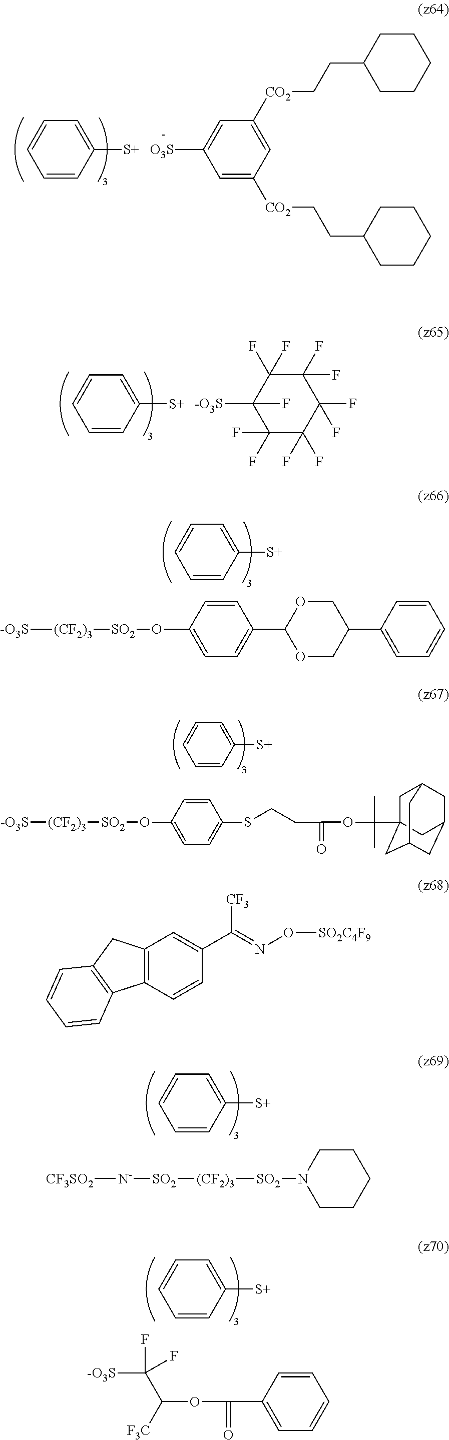

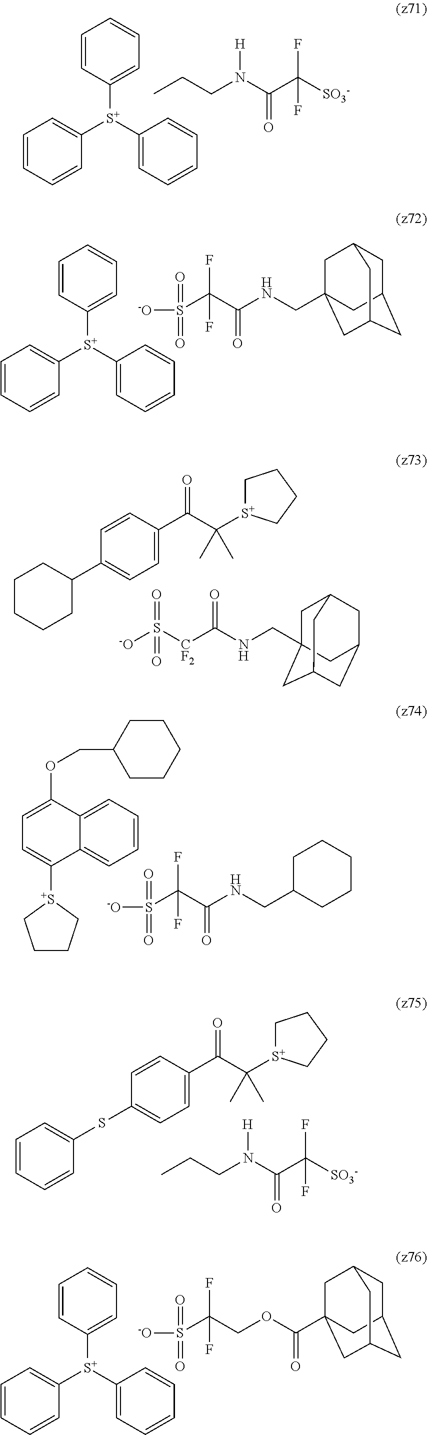

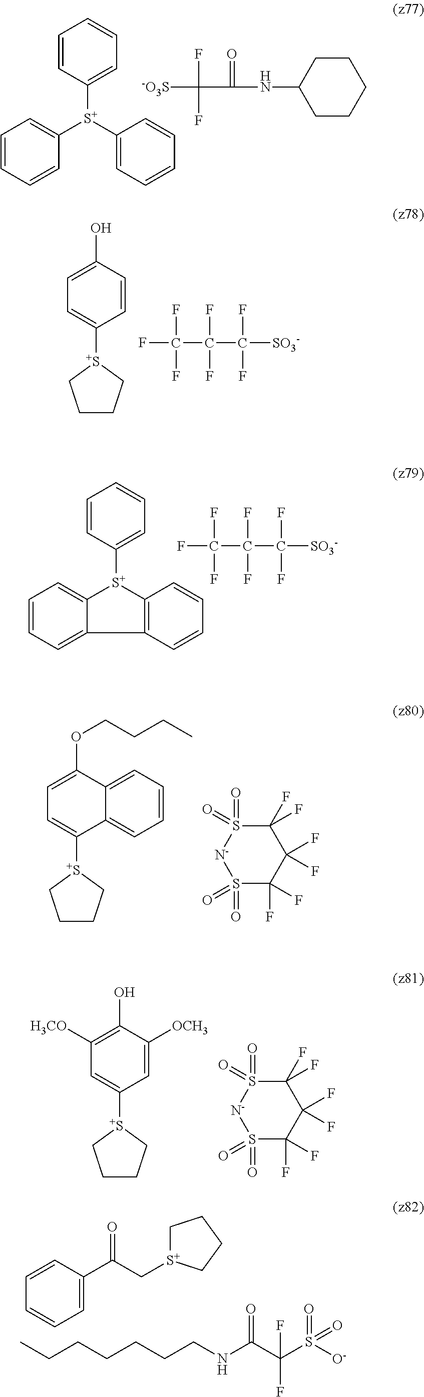

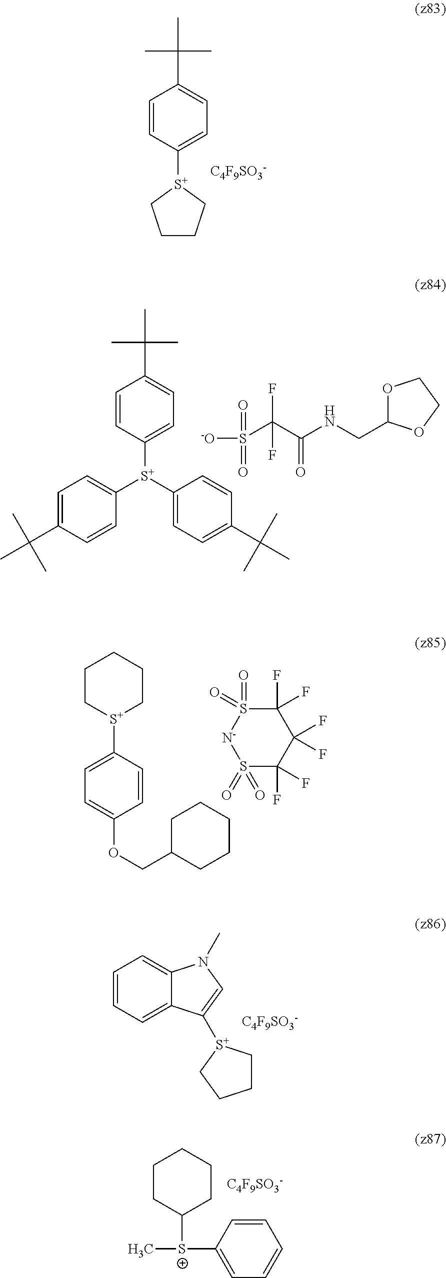

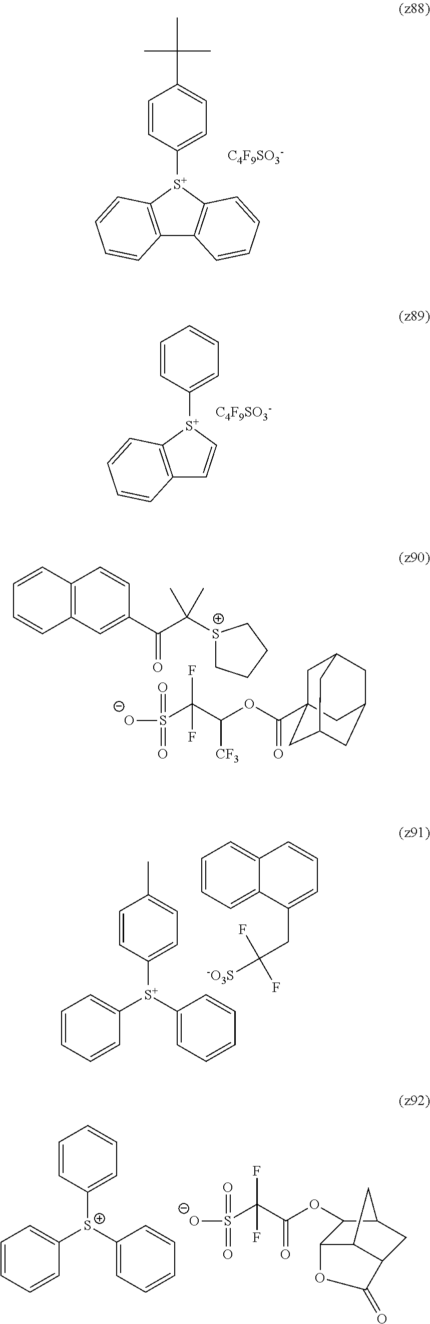

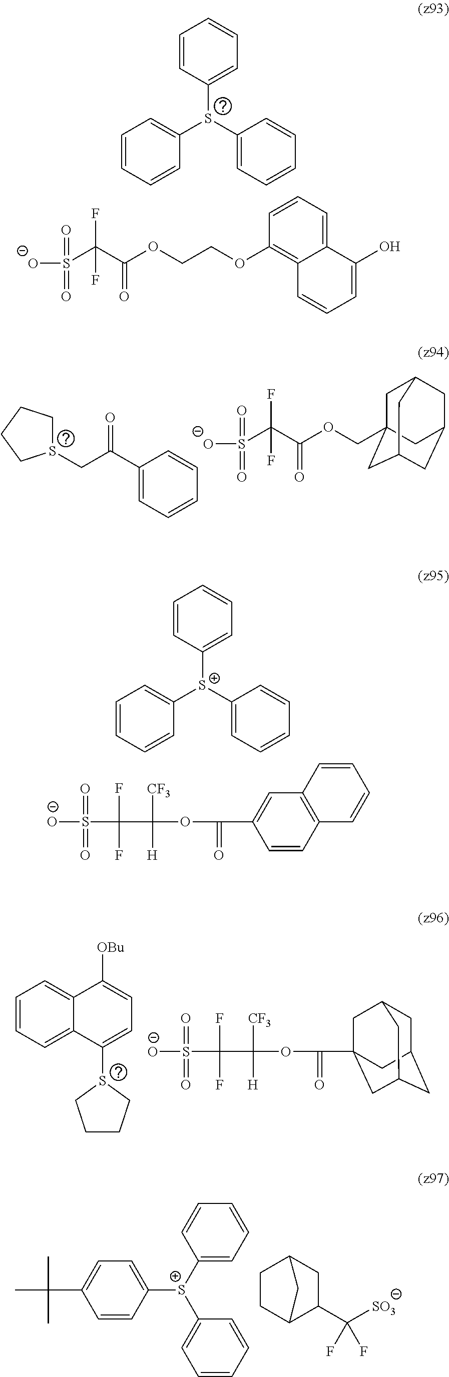

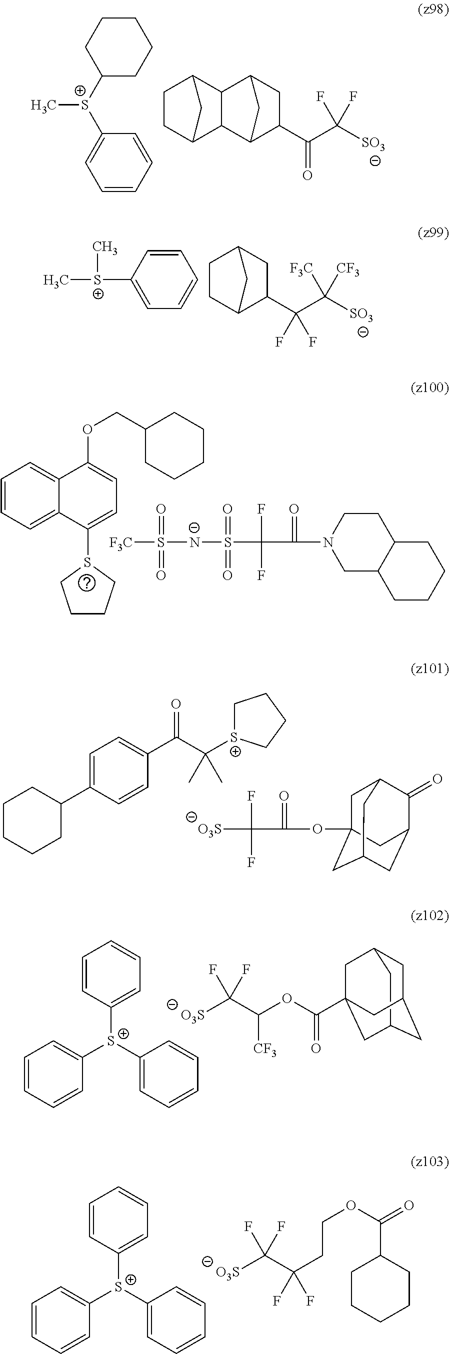

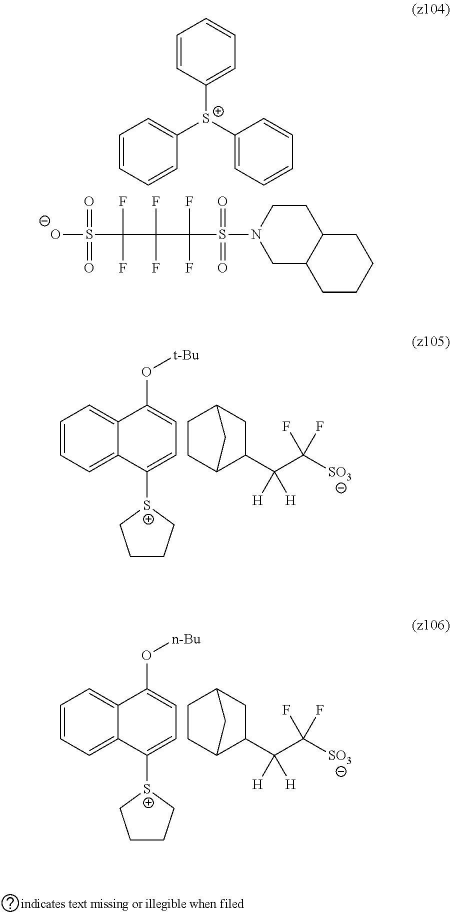

The compound (D) can be used alone or in combination of two or more kinds thereof.

When the composition according to the present invention contains the compound (D), the content of the compound (D) is preferably 0.1% to 30% by mass, more preferably 0.5% to 25% by mass, still more preferably 3% to 20% by mass, and particularly preferably 5% to 20% by mass, based on the total solid contents of the composition.

When the compound (D) is represented by the general formula (ZI-3) or (ZI-4), the content of the compound (D) is preferably 5% to 20% by mass, more preferably 8% to 20% by mass, still more preferably 10% to 20% by mass, and particularly preferably 15% to 20% by mass, based on the total solid contents of the composition.

The mass ratio of the compound (D) with respect to the compound (C) is preferably 1:10 to 10:1, and more preferably 1:5 to 3:1.

(E) Solvent

The composition according to the present invention may further contain a solvent.

Example of the solvent include alkylene glycol monoalkyl ether carboxylate, alkylene glycol monoalkyl ether, alkyl lactate ester, alkyl alkoxy propionate, cyclic lactone (preferably having 4 to 10 carbon atoms), a monoketone compound (preferably having 4 to 10 carbon atoms) that may have a ring, alkylene carbonate, alkyl alkoxy acetate, alkyl pyruvate, and the like.

Examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferable examples of the alkyl lactate ester include methyl lactate, ethyl lactate, propyl lactate, and butyl lactate.

Preferable examples of the alkyl alkoxy propionate include ethyl 3-ethoxypropionate, methyl 3-methoxypropionate, methyl 3-ethoxypropionate, and ethyl 3-methoxypropionate.

Preferable examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoiclactone, and α-hydroxy-γ-butyrolactone.

Examples of the monoketone compound that may contain a ring include 2-butanone, 3-methylbutanone, pinacol one, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4,-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-hepten-2-one, cyclopentanone, 2-methylcyclopentanone, 3-methyl cyclopentanone, 2,2-dimethylcyclopentanone, 2,4,4-trimethylcyclopentanone, cyclohexanone, 3-methylcyclohexanone, 4-methyl cyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methyl cycloheptanone.

Preferable examples of the alkylene carbonate include propylene carbonate, vinyl carbonate, ethylene carbonate, and butylene carbonate.

Preferable examples of the alkyl alkoxy acetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferable examples of the alkyl propionate include methyl pyruvate, ethyl pyruvate, and propyl pyruvate.

Examples of preferably usable solvents include solvents having a boiling point of 130° C. or higher at normal temperature and normal pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid-2-ethoxyethyl, acetic acid-2-(2-ethoxyethoxy)ethyl, and propylene carbonate.

In the present invention, the above solvents may be used alone or in combination of two or more kinds thereof.

In the present invention, a mixed solvent that is obtained by mixing a solvent as an organic solvent containing a hydroxyl group in the structure and a solvent not containing a hydroxyl group can be used.

The solvent containing a hydroxyl group and solvent not containing a hydroxyl group can be appropriately selected from the example compounds described above. The solvent containing a hydroxyl group is preferably alkylene glycol monoalkyl ether, alkyl lactate, or the like, and more preferably propylene glycol monomethyl ethyl or ethyl lactate. The solvent not containing a hydroxyl group is preferably alkylene glycol monoalkyl ether acetate, alkyl alkoxy propionate, a monoketone compound that may contain a ring, cyclic lactone, alkyl acetate, or the like. Among these, propylene glycol monomethyl ether acetate, ethyl ethoxy propionate, 2-heptanone, γ-butyrolactone, cyclohexanone, and butyl acetate are particularly preferable, and propylene glycol monomethyl ether acetate, ethyl ethoxy propionate, and 2-heptanone are most preferable.

The mixing ratio (mass) between the solvent containing a hydroxyl group and the solvent not containing a hydroxyl group is 1/99 to 99/1, preferably 10/90 to 90/10, and more preferably 20/80 to 60/40. A mixed solvent that contains 50% by mass or more of the solvent not containing a hydroxyl group is particularly preferable in respect of coating uniformity.

It is preferable that the solvent be two or more kinds of mixed solvents containing propylene glycol monomethyl ether acetate.

(F) Basic Compound Other than Compound (C).

The composition according to the present invention may further contain a basic compound (which will be also referred to as an (F) component hereinbelow) other than the compound (C) so as to reduce the change in performances with time from exposure to heating.

Preferable examples of the basic compound include compounds having structures represented by the following Formulae (A) to (E).

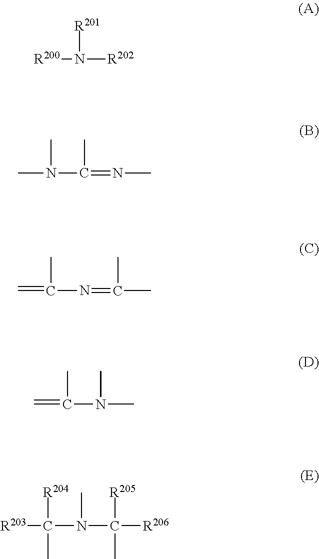

In general formula (A) and (E),

R²⁰⁰, R²⁰¹, and R²⁰² may be the same as or different from each other, and represent a hydrogen atom, an alkyl group (preferably having 1 to 20 carbon atoms), a cycloalkyl group (preferably having 3 to 20 carbon atoms), or an aryl group (having 6 to 20 carbon atoms). Herein, R²⁰¹ and R²⁰² may form a ring by binding to each other. R²⁰³, R²⁰⁴, R²⁰⁵, and R²⁰⁶ may be the same as or different from each other, and represent an alkyl group having 1 to 20 carbon atoms.

Regarding the alkyl group described above, as an alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

It is preferable that the alkyl group in the general formulae (A) and (E) be a substituent.

Preferable examples of the compound include guanidine, aminopyrrolidine, pyrazole, pyrazoline, piperazine, aminomorpholine, aminoalkyl morpholine, piperidine, and the like. More preferable examples of the compound include compounds having an imidazole structure, a diazabicyclo structure, an onium hydroxide structure, an onium carboxylate structure, a trialkylamine structure, an aniline structure, or a pyridine structure, alkylamino derivatives having a hydroxyl group and/or an ether bond, aniline derivatives having a hydroxyl group and/or an ether bond, and the like.

Examples of the compound having an imidazole structure include imidazole, 2,4,5-triphenylimidazole, benzimidazole, 2-phenylbenzimidazole, and the like. Examples of the compound having a diazabicyclo structure include 1,4-diazabicyclo[2,2,2]octane, 1,5-diazabicyclo[4,3,0]nona-5-ene, 1,8-diazabicyclo[5,4,0]undeca-7-ene, and the like. Examples of the compound having an onium hydroxide structure include tetrabutyl ammonium hydroxide, triaryl sulfonium hydroxide, phenacyl sulfonium hydroxide, sulfonium hydroxide having a 2-oxoalkyl group, and specifically, triphenyl sulfonium hydroxide, tris(t-butylphenyl) sulfonium hydroxide, bis(t-butylphenyl)iodonium hydroxide, phenacyl thiophenium hydroxide, 2-oxopropyl thiophenium hydroxide, and the like are exemplified. The compound having an onium carboxylate structure is a compound having an onium hydroxide structure, wherein the anion portion thereof has been carboxylated. Examples of the compound having an onium carboxylate structure include acetate, adamantane-1-carboxylate, perfluoroalkyl carboxylate, and the like. Examples of the compound having a trialkylamine structure include tri(n-butyl)amine, tri(n-octyl)amine, and the like. Examples of the aniline compound include 2,6-diisopropylaniline, N,N-dimethylaniline, N,N-dibutylaniline, N,N-dihexylaniline, and the like. Examples of the alkylamino derivative having a hydroxyl group and/or an ether bond include ethanolamine, diethanolamine, triethanolamine, N-phenyldiethanoleamine, tris(methoxyethoxy)amine, and the like. Examples of the aniline derivative having a hydroxyl group and/or an ether bond include N,N-bis(hydroxyethyl)aniline and the like.

Preferable examples of the basic compound further include an amine compound having a phenoxy group, an ammonium salt compound having a phenoxy group, an amine compound having a sulfonic acid ester group, and an ammonium salt compound having a sulfonic acid ester group.

It is preferable that at least one alkyl group bind to a nitrogen atom in the amine compound having a phenoxy group, the ammonium salt compound having a phenoxy group, the amine compound having a sulfonic acid ester group, and the ammonium salt compound having a sulfonic acid ester group. It is also preferable that these compounds have an oxygen atom in the alkyl chain described above and form an oxyalkylene group. The number of the oxyalkylene group in a molecule is 1 or more, preferably 3 to 9, and more preferably 4 to 6. Among the oxyalkylene groups, a structure of —CH₂CH₂O—, —CH(CH₃)CH₂O—, or —CH₂CH₂CH₂O— is preferable.

Specific examples of the amine compound having a phenoxy group, the ammonium salt compound having a phenoxy group, the amine compound having a sulfonic acid ester group, and the ammonium salt compound having a sulfonic acid ester group include compounds (C1-1) to (C3-3) exemplified in [0066] of the specification of US2007/0224539A, but the present invention is not limited thereto.

These basic compounds may be used alone or in combination of two or more kinds thereof.

When the composition according to the present invention includes the (F) component, the content of the (F) compound is normally 0.001% to 10% by mass, and preferably 0.01% to 5% by mass, based on the total solid contents of the composition of the present invention.

The content ratio between the acid-generating agent and the (F) component in the composition is preferably acid-generating agent/(F) component (molar ratio)=2.5 to 300. That is, the molar ratio is preferably 2.5 or higher in respect of sensitivity and resolution, and preferably 300 or lower in respect of inhibiting the reduction in resolution resulting from thickening of a resist pattern caused with time elapsing to heating treatment after exposure. The acid-generating agent/(F) component (molar ratio) is more preferably 3.5 to 200, and still more preferably 3.5 to 150.

(G) Low-molecular-weight compound that has group eliminated by action of an acid and basicity increasing by the elimination.

The composition according to the present invention preferably contains a low-molecular-weight compound (which will be referred to as a “low-molecular-weight compound (G)” hereinbelow) that has a group eliminated by the action of an acid and basicity increasing by the elimination.

Though not particularly limited, the group eliminated by the action of an acid is preferably an acetal group, a carbonate group, a carbamate group, a tertiary ester group, a tertiary hydroxyl group, or a hemiaminal ether group, and particularly preferably a carbamate group or a hemiaminal ether group.

The molecular weight of the low-molecular-weight compound (G) having a group eliminated by the action of an acid is preferably 100 to 1000, more preferably 100 to 700, and particularly preferably 100 to 500.

As the compound (G), amine derivatives having a group eliminated by the action of an acid on a nitrogen atom is preferable.

The compound (G) may have a carbamate group having a protective group on a nitrogen group. The protective group constituting the carbamate group is represented by the following general formula (d-1).

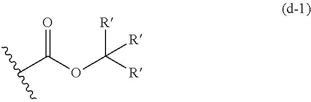

In general formula (d-1),

each R′ independently represents a hydrogen atom, a linear or branched alkyl group, a cycloalkyl group, an aryl group, an aralkyl group, or an alkoxyalkyl group. R's may form a ring by binding to each other.

R′ is more preferably a linear or branched alkyl group, a cycloalkyl group, or an aryl group, and still more preferably a linear or branched alkyl group or a cycloalkyl group.

The low-molecular-weight compound (G) can be constituted by arbitrarily combining the basic compound described above and the structure represented by general formula (d-1).

The low-molecular-weight compound (G) particularly preferably includes a structure represented by the following general formula (A).

In addition, the low-molecular-weight compound (G) may correspond to the basic compound as long as the low-molecular-weight compound (G) is a low-molecular-weight compound having a group eliminated by the action of an acid.

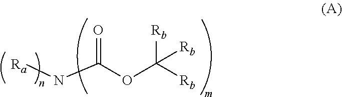

In general formula (A), Ra represents a hydrogen atom, an alkyl group, a cycloalkyl group, an aryl group, or an aralkyl group. When n=2, two Ras may be the same as or different from each other. Two Ras may form a divalent heterocyclic hydrocarbon group (preferably having 20 or less carbon atoms) or a derivative thereof by binding to each other.

Each of Rb independently represents a hydrogen atom, an alkyl group, a cycloalkyl group, an aryl group, an aralkyl group, or an alkoxyalkyl group. Here, in —C(Rb)(Rb)(Rb), when one or more Rb are hydrogen atoms, at least one of the remaining Rb is a cyclopropyl group, a 1-alkoxyalkyl group, or an aryl group.

At least two Rbs may form an alicyclic hydrocarbon group, an aromatic hydrocarbon group, a heterocyclic hydrocarbon group, or a derivative thereof by binding to each other.

n represents an integer of 0 to 2, m represents an integer of 1 to 3, and n+m=3.

In general formula (A), the alkyl group, cycloalkyl group, aryl group, and aralkyl group represented by Ra and Rb may be substituted with a functional group such as a hydroxyl group, a cyano group, an amino group, a pyrrolidine group, a piperidine group, a morpholino group, or an oxo group, an alkoxy group, and a halogen atom, and this structure is applied to the alkoxyalkyl group represented by Rb in the same manner.

Examples of the alkyl group, cycloalkyl group, aryl group, and aralkyl group (these alkyl group, cycloalkyl group, aryl group, and aralkyl group may have been substituted with the above functional group, alkoxy group, and halogen atom) of the Ra and/or Rb include a group derived from a linear or branched alkane such as methane, ethane, propane, butane, pentane, hexane, heptane, octane, nonane, decane, undecane, dodecane; and a group derived from the linear or branched alkane substituted with one or more kinds or one or more of a cycloalkyl group such as a cyclobutyl group, a cyclopentyl group, or a cyclohexyl group;

a group derived from cycloalkane such as cyclobutane, cyclopentane, cyclohexane, cycloheptane, cyclooctane, norbornane, adamantane, or noradamantane; and a group derived from the cycloalkane substituted with one or more kinds or one or more of a linear or branched alkyl group such as a methyl group, an ethyl group, an n-propyl group, an i-propyl group, an n-butyl group, a 2-methylpropyl group, a 1-methylpropyl group, or a t-butyl group;

a group derived from aromatic compounds such as benzene, naphthalene, and anthracene; and a group derived from the aromatic compounds substituted with one or more kinds or one or more of a linear or branched alkyl group such as a methyl group, an ethyl group, an n-propyl group, an i-propyl group, an n-butyl group, a 2-methylpropyl group, a 1-methylpropyl group, or a t-butyl group;

a group derived from heterocyclic compounds such as pyrrolidine, piperidine, morpholine, tetrahydrofuran, tetrahydropyran, indole, indoline, quinoline, perhydroquinoline, indazole, and benzimidazole; and a group derived from the heterocyclic compounds substituted with one or more kinds or one or more of a group derived from a linear or branched alkyl group or a group derived from aromatic compounds; a group derived from a linear or branched alkane and a group derived form cycloalkane wherein the groups is substituted with one or more kinds or one or more groups derived from aromatic compounds such as a phenyl group, a naphthyl group, and an anthracenyl group; or a group wherein the above-described substituent is substituted with a functional group such as a hydroxyl group, a cyano group, an amino group, a pyrrolidine group, a piperidine group, a morpholino group, or an oxo group.

Examples of the divalent heterocyclic hydrocarbon group (preferably having 1 to 20 carbon atoms) or the derivative thereof that the Ra's form by binding to each other include a group derived from heterocyclic compounds such as pyrrolidine, piperidine, morpholine, 1,4,5,6-tetrahydropyfimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, and 1,5,9-triazacyclododecane; and a group derived from the heterocyclic compounds substituted with one or more kinds or one or more of a group derived from a linear or branched alkane, a group derived from a cycloalkane, a group derived from aromatic compounds, a group derived from heterocyclic compounds, or a functional group such as a hydroxyl group, a cyano group, an amino group, a pyrrolidino group, a piperazino group, a morpholino group, or an oxo group.

Specific examples of the particularly preferable low-molecular-weight compound (G) in the present invention will be shown, but the present invention is not limited thereto.

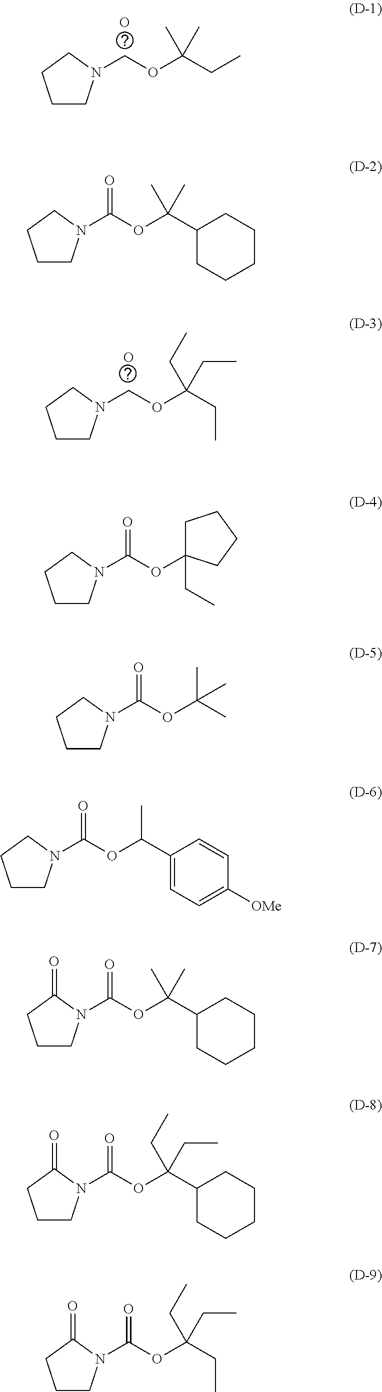

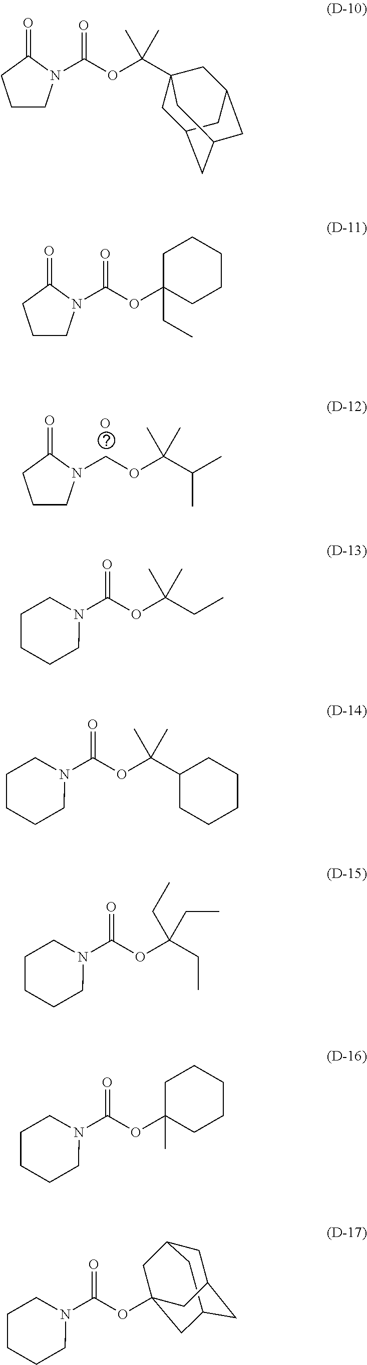

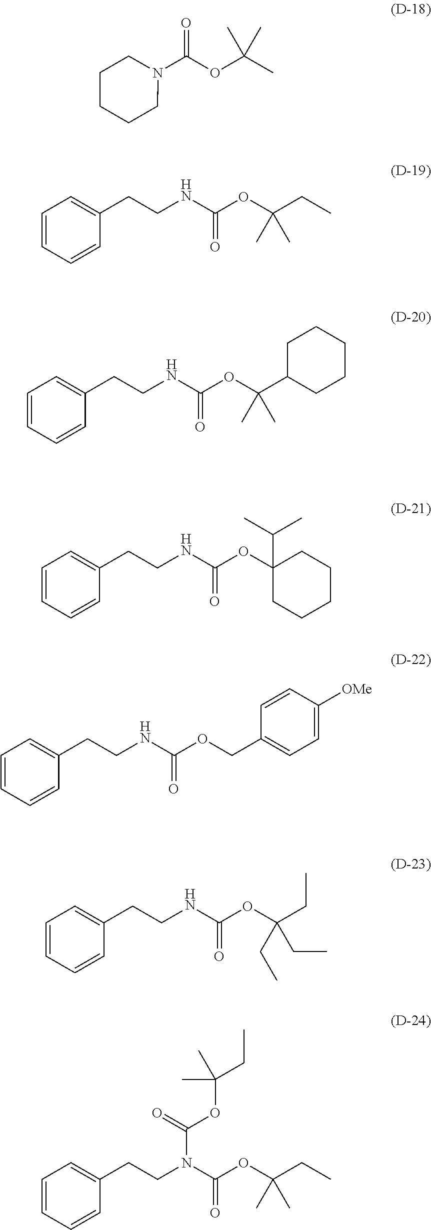

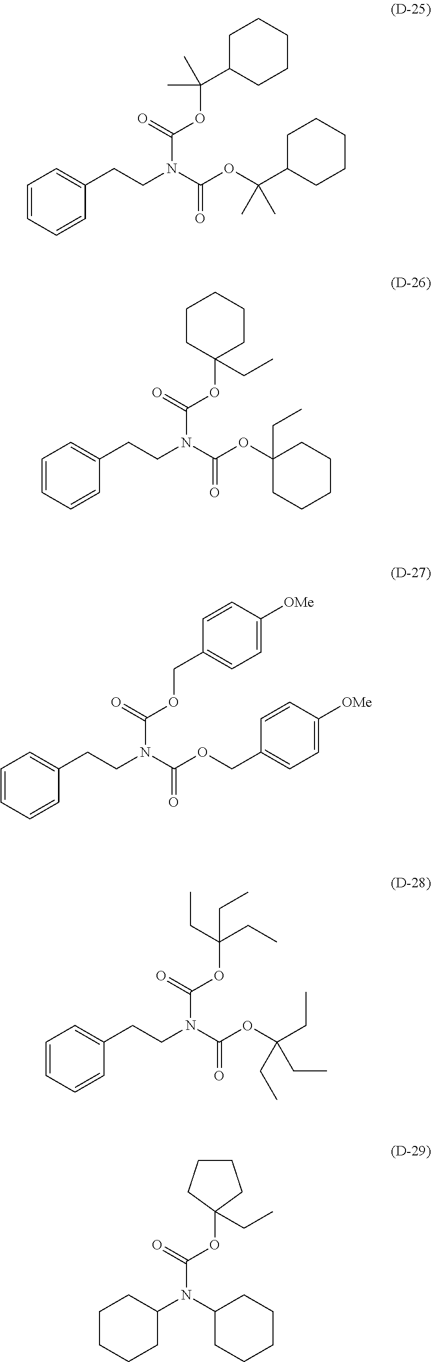

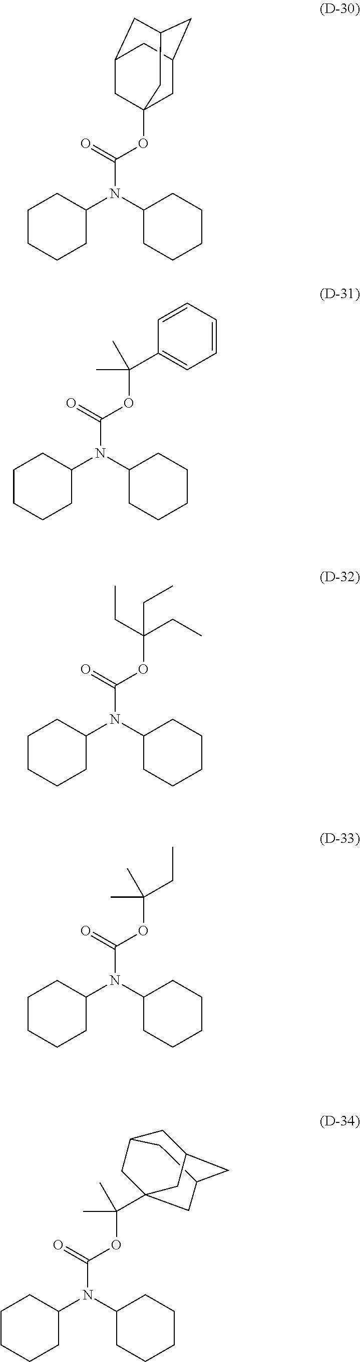

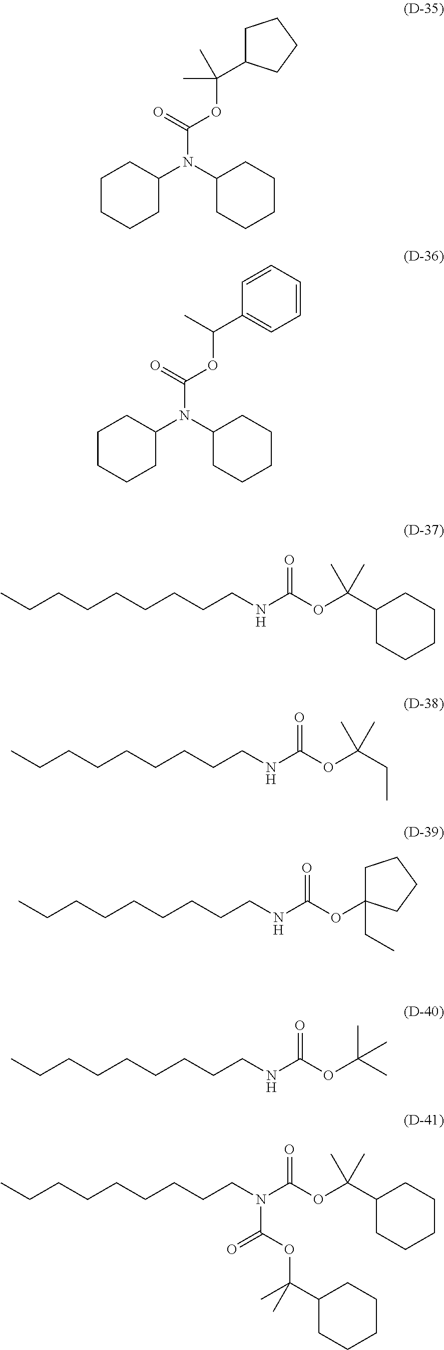

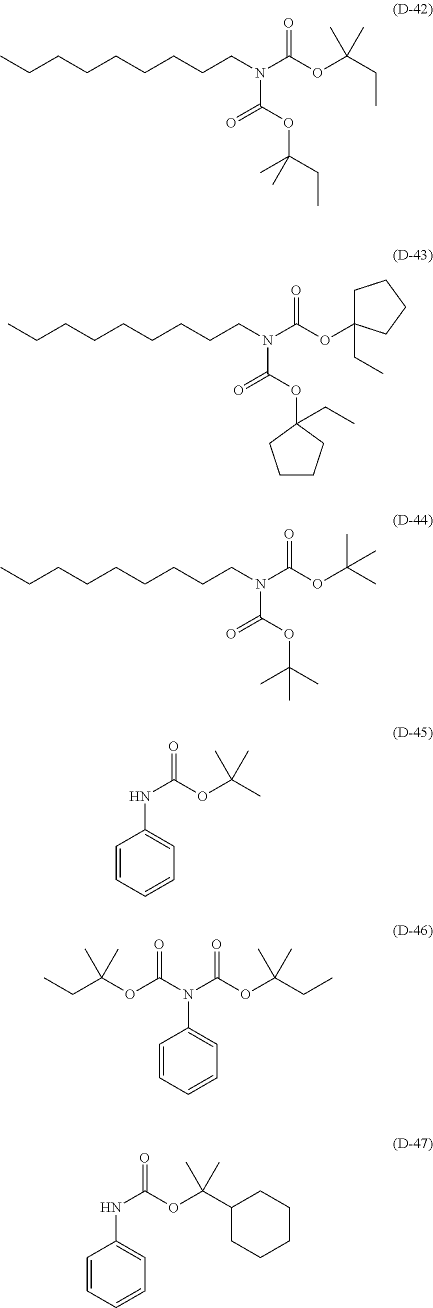

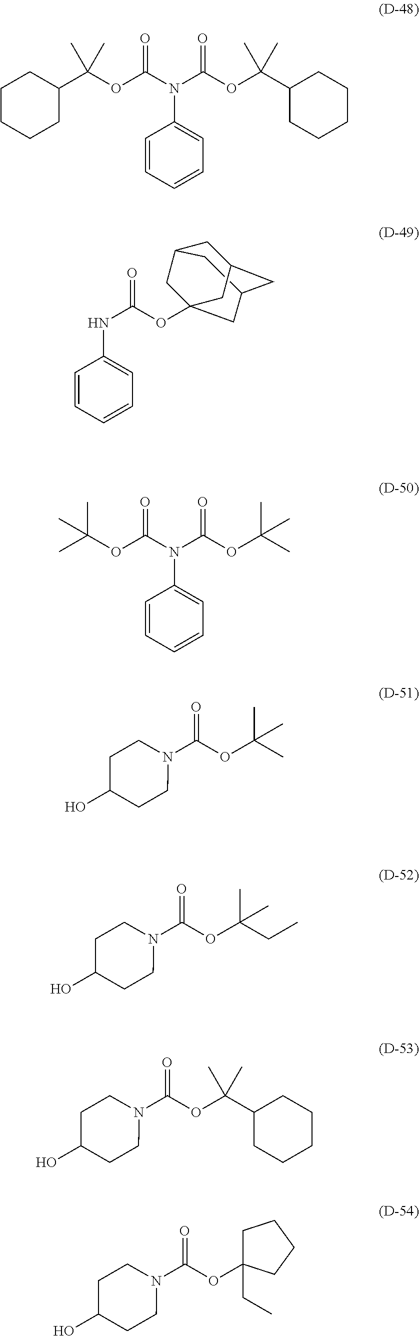

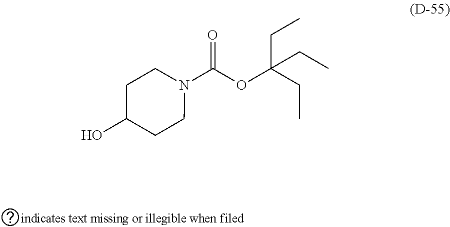

The compound represented by general formula (A) can be synthesized by the method disclosed in JP2009-199021A, for example.

The low-molecular-weight compound (G) can be used alone or in combination of two or more kinds thereof.

In the present invention, the content of the low-molecular-weight compound (G) is generally 0.001% to 20% by mass, preferably 0.001% to 10% by mass, and more preferably 0.01% to 5% by mass, based on the total solid contents of the composition to which the above-described basic compound has been added.

The proportion of the acid-generating agent and the low-molecular-weight compound (G) that are used in the composition is preferably acid-generating agent/[low-molecular-weight compound (G)+(F) component] (molar ratio)=2.5 to 300. That is, the molar ratio is preferably 2.5 or higher in respect of sensitivity and resolution, and preferably 300 or lower in respect of inhibiting the reduction in resolution resulting from thickening of a resist pattern caused with time elapsing to heating treatment after exposure. The acid-generating agent/[low-molecular-weight compound (G)+(F) component] (molar ratio) is more preferably 3.5 to 200, and still more preferably 3.5 to 150.

(H) Surfactant

The composition of the present invention may further contain a surfactant. When the composition contains a surfactant, the composition preferably contains any one of a fluorine-based surfactant and/or a silicon-based surfactant (a fluorine-based surfactant, a silicon-based surfactant, and a surfactant including both a fluorine atom and a silicon atom) or two or more kinds of these surfactants.

If the composition of the present invention contains the surfactant, a resist pattern having small adhesion and development defects can be provided with excellent sensitivity and resolution, when an exposure light source of 250 nm or less, particularly, an exposure light source of 220 nm or less is used.

Examples of the fluorine-based surfactant and/or silicon-based surfactant include surfactants disclosed in [0276] of US2008/0248425A, which are, for example, EFtop EF301 and EF303 (available from Shin-Akita Kasei Co., Ltd.); Fluorad FC430, 431, and 4430 (manufacture by Sumitomo 3M Limited); Magafac F171, F173, F176, F189, F113, F110, F177, F120, and R08 (available from Dainippon Ink & Chemicals, Inc.); Surflon S-382, SC101, 102, 103, 104, 105, and 106 (available from ASAHI GLASS CO., LTD.); Troysol S-366 (available from Troy Chemical Co., Ltd.); GF-300 and GF-150 (available from TOAGOSEI, CO., LTD.); Surflon S-393 (available from SEIMI CHEMICAL CO., LTD.); EFtope EF121, EF122A, EF122B, RF122C, EF125M, EF135M, EF351, EF352, EF801, EF802, and EF601 (available from JEMCO Inc.); PF636, PF656, PF6320, and PF6520 (available from OMNOVA solution Inc.); and FTX-204G, 208E 218G, 230G, 204D, 208D, 212D, 218D, and 222D (available from NEOS Co., Ltd.). In addition, polysiloxane polymer KP-341 (available from Shin-Etsu Chemical Co., Ltd.) can also be used as the silicon-based surfactant.

As the surfactant, surfactants that use a polymer having a fluoroaliphatic group derived from fluoroaliphatic compounds which are produced by a telomerization method (which is also called a telomer method) or an oligomerization method (which is also called an oligomer method) can also be used, in addition to the well-known surfactants described above. The fluoroaliphatic compound can be synthesized by the method disclosed in JP2002-90991A.

The polymer having the fluoroaliphatic group is preferably a copolymer of a monomer having a fluoroaliphatic group and (poly(oxyalkylene))acrylate and/or (poly(oxyalkylene))methacrylate, and may be irregularly distributed or may be block-copolymerized. Examples of the poly(oxyalkylene) group include a poly(oxyethylene) group, a poly(oxypropylene) group, a poly(oxybutylene) group, and the like. The poly(oxyalkylene) group may be a unit that may have alkylene having different lengths of alkylene in the same chain length, such as a poly(oxyethylene-oxypropylene-oxyethylene block linked body) and a poly(oxyethylene-oxypropylene block linked body). In addition, the copolymer of a monomer having a fluoroaliphatic group and (poly(oxyalkylene))acrylate (or methacrylate) may be not only a binary copolymer, but also a ternary or higher copolymer obtained by simultaneously copolymerizing a monomer having two or more kinds of different fluoroaliphatic groups, two or more kinds of different (poly(oxyalkylene))acrylate (or methacrylate), and the like.

Examples of commercially available surfactants include Megafac F178, F-470, F-473, F-475, F-476, and F-472 (available from Dainippon Ink & Chemicals, Inc.), a copolymer of acrylate (or methacrylate) having a C₆F₁₃ group and (poly(oxyalkylene))acrylate (or methacrylate), a copolymer of acrylate (or methacrylate) having a C₃F₇ group, (poly(oxyethyl ene))acrylate (or methacrylate), and (poly(oxypropyl ene))acrylate (or methacrylate), and the like.

In the present invention, surfactants other than the fluorine-based surfactant and/or silicon-based surfactant, which are described in [0280] of US2008/0248425A, can also be used.

These surfactants may be used alone or in combination of several kinds thereof.

When the composition according to the present invention contains the surfactant, the content of the surfactant is preferably 0.1% to 2% by mass, more preferably 0.1% to 1.5% by mass, and particularly preferably 0.1% to 1% by mass, based on the total solid contents of the composition.

(I) Carboxylic Acid Onium Salt

The composition of the present invention may contain a carboxylic acid onium salt. As the carboxylic acid onium salt, an iodonium salt and a sulfonium salt are preferable. As the anion portion, a linear, branched, monocyclic, or polycyclic alkylcarboxylic acid anion having 1 to 30 carbon atoms is preferable, and an anion of carboxylic acid in which a portion or all of these alkyl groups have been substituted with fluorine is more preferable. The alkyl chain may include an oxygen atom. In this structure, transparency with respect to light of 220 nm or less is secured, sensitivity and resolution are improved, and density distribution dependency and exposure margin are ameliorated.

Examples of the anion of carboxylic acid substituted with fluorine include anions of fluoroacetic acid, difluoroacetic acid, trifluoroacetic acid, pentafluoropropionic acid, pentafluorobutyric acid, heptafluorobutyric acid, nonafluoropentanoic acid, perfluorododecanoic acid, perfluorotridecanoic acid, perfluorocyclohexane carboxylic acid, and 2,2-bistrifluoromethyl propionic acid, and the like.

The content of the carboxylic acid onium salt in the composition is generally 0.1% to 20% by mass, preferably 0.5% to 10% by mass, and more preferably 1% to 7% by mass, based on the total solid contents of the composition.

(J) Dissolution-Inhibiting Compound

The composition of the present invention may contain a dissolution-inhibiting compound having a molecular weight of 3000 or less, which has solubility that increases in an alkaline developer by being decomposed by the action of an acid. As the dissolution-inhibiting compound, an alicyclic or aliphatic compound containing an acid-decomposable group such as a cholic acid derivative containing the acid-decomposable group disclosed in Proceeding of SPIE, 2724, 355 (1996) is preferable since this dissolution-inhibiting compound does not reduce transparency at 220 nm or less. Examples of the acid-decomposable group and alicyclic structure include the same group and structure as those described for the resin (A).

When the composition of the present invention is exposed by a KrF excimer laser or irradiated with an electron beam, it is preferable that the dissolution-inhibiting compound contain a structure in which a phenolic hydroxyl group of a phenol compound has been substituted with the acid-decomposable group. The phenol compound contains preferably 1 to 9 phenol skeletons, and more preferably 2 to 6 phenol skeletons.

The amount of the dissolution-inhibiting compound added is preferably 3% to 50% by mass, and more preferably 5% to 40% by mass, based on the total solid contents of the actinic-ray-sensitive or radiation-sensitive resin composition.

Specific examples of the dissolution-inhibiting compound will be shown below, but the present invention is not limited thereto.

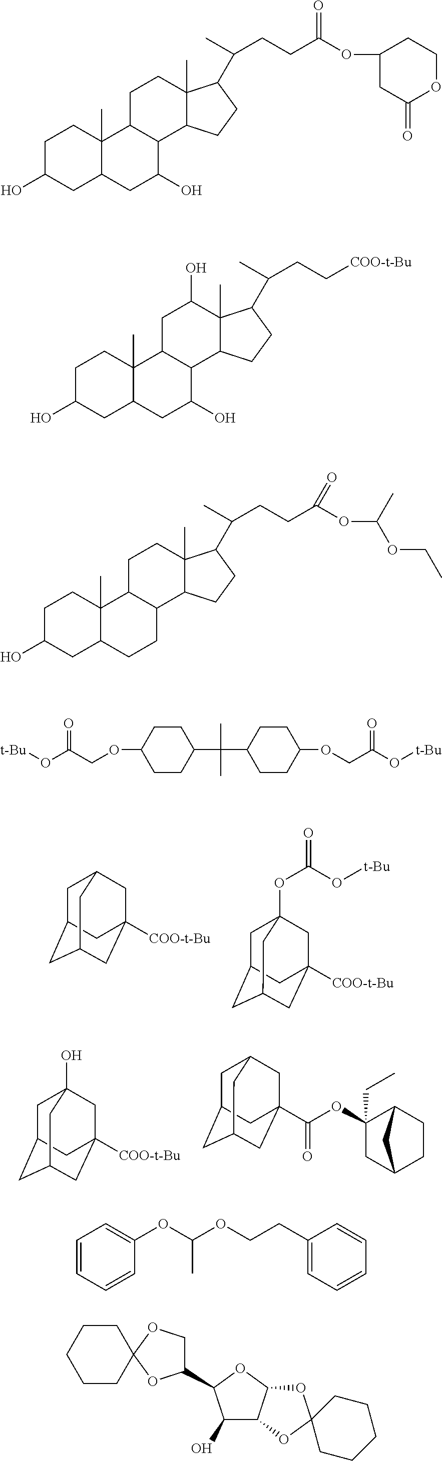

(K) Other Additives

The composition of the present invention can optionally further contain a dye, a plasticizer, a photosensitizer, a light absorber, a compound (for example, a phenol compound having a molecular weight of 1000 or less, or an alicyclic or aliphatic compound having a carboxyl group) promoting solubility with respect to a developer, and the like.

A person skilled in the art can easily synthesize the phenol compound having a molecular weight of 1000 or less with reference to methods disclosed in JP1992-122938A (JP-H4-122938A), JP1990-28531A (JP-H2-28531A), U.S. Pat. No. 4,916,210A, EP219294B, and the like.

Specific examples of the alicyclic or aliphatic compound having a carboxyl group include carboxylic acid derivatives having a steroid structure such as cholic acid, deoxycholic acid, and lithocholic acid, adamantane carboxylic acid derivatives, adamantane dicarboxylic acid, cyclohexane carboxylic acid, cyclohexane dicarboxylic acid, and the like, but the present invention is not limited thereto.

### <Pattern Forming Method>

The composition of the present invention is used preferably in a film thickness of 30 nm to 250 nm, and more preferably in a film thickness of 30 nm to 200 nm, from the viewpoint of resolution improvement. This film thickness can be adjusted by setting the concentration of the solid content in the actinic-ray-sensitive or radiation-sensitive resin composition within an appropriate range to give proper viscosity, thereby improving coating property and film formability.

The concentration of the total solid contents in the composition of the present invention is generally 1% to 10% by mass, more preferably 1% to 8.0% by mass, and still more preferably 1.0% to 7.0% by mass.

To use the composition of the present invention, the above-described components are dissolved in a predetermined organic solvent, preferably in the above-described mixed solvent, followed by filtering through a filter, and coated on a predetermined support as described below. The pore size of the filter used for the filtering is 0.1 μm or less, more preferably 0.05 μm or less, and still more preferably 0.03 μm or less, and the filter is preferably made of polytetrafluoroethylene, polyethylene, or nylon. Moreover, a plurality of filters may be used by being connected in series or in parallel, and the composition may be filtered a plurality of times. In addition, the composition may be subjected to deaeration treatment before and after the filtering.

For example, the actinic-ray-sensitive or radiation-sensitive resin composition is coated on a substrate (example: silicon/silicon dioxide coating) that may be used for producing a precision integrated circuit element by an appropriate coating method using a spinner, coater, and the like, followed by drying, thereby forming a film.

The film is irradiated with actinic-rays or radiations through a predetermined mask and baked (heated) preferably, followed by development and rinsing. In this manner, an excellent pattern can be obtained.

Examples of the actinic-ray or radiation include infrared light, visible light, ultraviolet light, far-ultraviolet light, extreme ultraviolet light, X-rays, electron beams, and the like. Among these, far-ultraviolet light preferably having a wavelength of 250 nm or less, more preferably having a wavelength of 220 nm or less, particularly preferably having a wavelength of 1 nm to 200 nm is preferable. Specific examples thereof include a KrF excimer laser (248 nm), an ArF excimer laser (193 nm), an F₂ excimer laser (157 nm), X-rays, electron beams, and the like, and an ArF excimer laser, an F₂ excimer laser, EUV (13 nm), and electron beam are preferable.

An antireflection film may be coated on the substrate in advance before the film is formed.

As the antireflection film, any of inorganic film types such as titanium, titanium dioxide, titanium nitride, chromium oxide, carbon, amorphous silicon, and the like, and organic film types formed of light absorber and polymer materials can be used. As the organic antireflection film, commercially available organic antireflection films such as a DUV30 series and DUV-40 series available from Brewer Science Inc., AR-2, AR-3, and AR-5 available from Shipley Company, L.L.C. can be used.

As the alkaline developer used for development process, a quaternary ammonium salt represented by tetramethyl ammonium hydroxide is generally used, but in addition to this, an aqueous alkaline solution of inorganic alkali, primary amine, secondary amine, tertiary amine, alcohol amine, cyclic amine, and the like can also be used.

In addition, alcohols and surfactants can be added to the alkaline developer in an appropriate amount for use.

An alkali concentration of the alkaline developer is generally 0.1% to 20% by mass.

A pH of the alkaline developer is generally 10.0 to 15.0.

Moreover, alcohols and surfactants can be added to the aqueous alkaline solution in an appropriate amount for use.

As a rinsing liquid, pure water is used, and a surfactant can be added thereto in an appropriate amount for use.

After development treatment or rinsing treatment, a treatment can be performed which removes the developer or rinsing liquid attached onto the pattern by using supercritical fluid.

The film that is formed using the composition according to the present invention can be subjected to liquid immersion exposure. That is, while liquid having a refractive index higher than that of air is filled between the film and a lens, actinic-ray or radiation irradiation may be performed. In this manner, resolution could be further improved.

The liquid for liquid immersion used for liquid immersion exposure will be described below.

As the liquid for liquid immersion, a liquid is preferable which is transparent to the exposure wavelength and has a temperature coefficient of refractive index as small as possible so as to minimize the distortion of an optical image projected onto a resist film. Particularly, when the exposure light source is an ArF excimer laser (wavelength; 193 nm), water is preferably used in respect that the water is easily obtained and handled, in addition to the above-described viewpoints.

Moreover, in order to further shorten the wavelength, a medium having a refractive index of 1.5 or higher can also be used. This medium may be an aqueous solution or an organic solvent.

When water is used as the liquid for liquid immersion, in order to reduce surface tension of water and to increase surfactant potency, the resist layer on a wafer may not be dissolved, and an additive (liquid) that negligibly affects optical coat of the lower surface of a lens element may be added in a slight proportion.

As the additive, aliphatic alcohol that has almost the same refractive index as that of water is preferable, and specific examples thereof include methyl alcohol, ethyl alcohol, isopropyl alcohol, and the like. By adding the alcohol having almost the same refractive index as that of water, change in refractive index caused in overall liquid can be minimized, even if the concentration of the alcohol contained in the water changes due to evaporation of the alcohol. When a substance that is opaque to light having a wavelength of 193 nm and impurities that have a refractive index greatly differing from that of water are mixed in, since the optical image projected onto the resist is distorted, distilled water is preferable as water to be used. In addition, pure water filtered through an ion exchange filter or the like may be used.

The electrical resistance of water used as the liquid for liquid immersion is desirably 18.3 MQ cm or more, the TOC (organic matter concentration) thereof is desirably 20 ppb or less, and it is desirable that the water have undergone deaeration treatment.

By increasing the refractive index of the liquid for liquid immersion, a lithography performance can be improved. From such a viewpoint, an additive for improving refractive index may be added to water, or heavy water (D₂O) may be used instead of water.

As the alkaline developer in the development process, a quaternary ammonium salt represented by tetramethyl ammonium hydroxide is generally used, but in addition to this, an aqueous alkaline solution of inorganic alkali, primary amine, secondary amine, tertiary amine, alcoholamine, cyclic amine, and the like can also be used. Alcohols and/or surfactants may be added to the alkaline developer in an appropriate amount.

An alkali concentration of the alkaline developer is generally 0.1% to 20% by mass.

A pH of the alkaline developer is generally 10.0 to 15.0.

As a rinsing liquid, pure water is used, and a surfactant can be added thereto in an appropriate amount for use. In addition, after development treatment or rinsing treatment, a treatment can be performed which removes the developer or rinsing liquid attached onto the pattern by using supercritical fluid.

### EXAMPLE

The embodiment of the present invention will be described in more detail by using examples, but the scope of the present invention is not limited to the following examples.

### <Resin (A)>

As the resin(A), resins (A1) to (A6) shown below were prepared.

| | | |
|---|---|---|
| A1 | 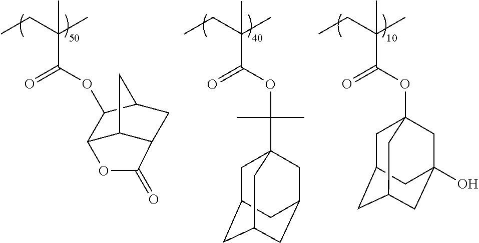 | Mw = 8800 Mw/Mn = 1.82 |
| A2 | 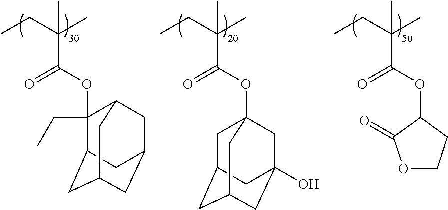 | Mw = 8100 Mw/Mn = 1.78 |
| A3 | 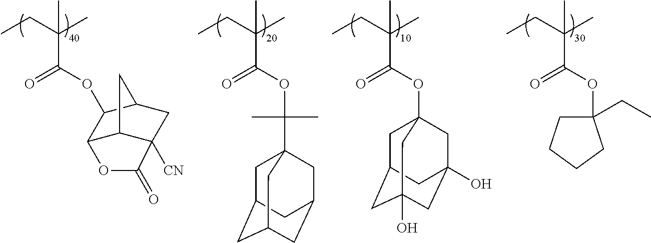 | Mw = 9800 Mw/Mn = 1.68 |
| A4 | 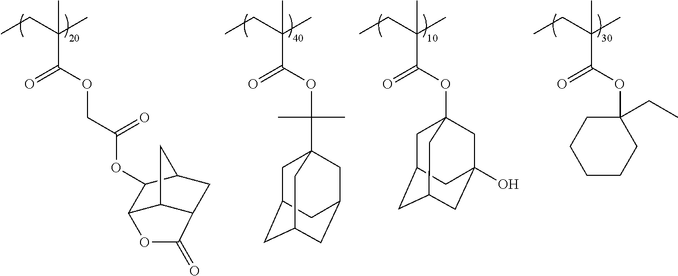 | Mw = 7500 Mw/Mn = 1.72 |
| A5 | 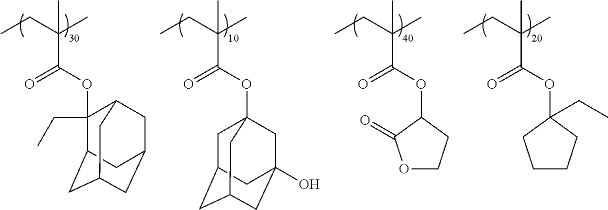 | Mw = 5500 Mw/Mn = 1.77 |
| A6 | 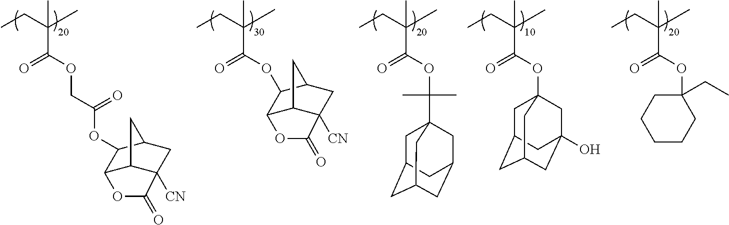 | Mw = 7500 Mw/Mn = 1.72 |

### <Resin (B)>

As the resin (B), resins (B1) to (B11) shown below were prepared.

| | | |
|---|---|---|
| B1 | 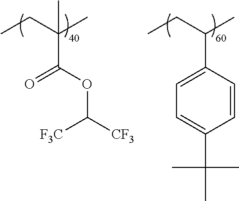 | Mw = 4500 Mw/Mn = 1.62 |
| B2 | 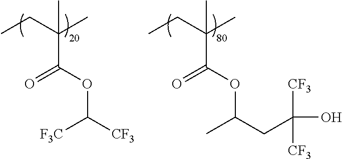 | Mw = 8100 Mw/Mn = 1.78 |
| B3 | 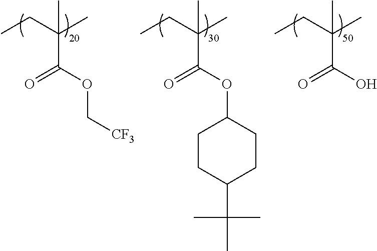 | Mw = 6000 Mw/Mn = 1.56 |
| B4 | 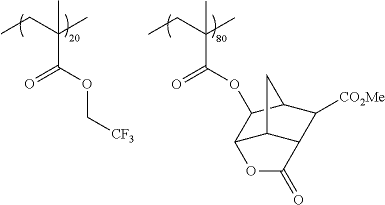 | Mw = 10800 Mw/Mn = 1.81 |
| B5 | 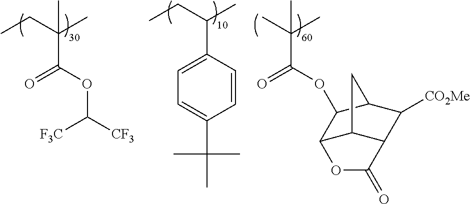 | Mw = 7500 Mw/Mn = 1.77 |
| B6 | 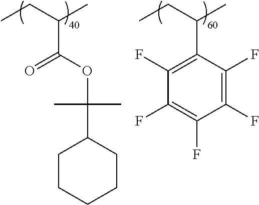 | Mw = 5700 Mw/Mn = 1.69 |
| B7 | 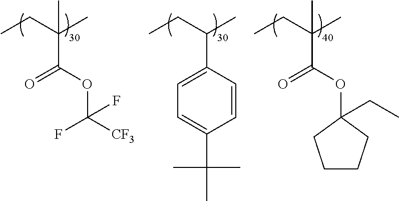 | Mw = 5800 Mw/Mn = 1.62 |
| B8 | 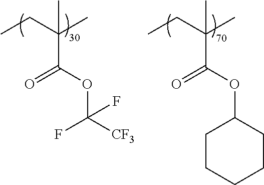 | Mw = 8300 Mw/Mn = 1.84 |
| B9 | 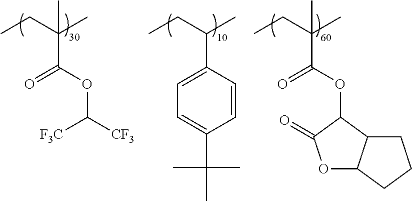 | Mw = 7500 Mw/Mn = 1.77 |
| B10 | 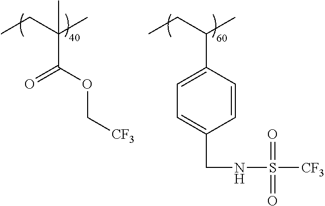 | Mw = 6600 Mw/Mn = 1.59 |
| B11 | 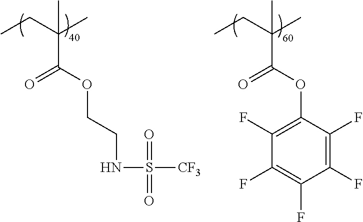 | Mw = 8500 Mw/Mn = 1.75 |

### <Compound (C)>

As the compound (C), the following compounds (C1) to (C5), and (C10) were synthesized. In addition, the following compounds (C6) to (C9) were prepared for reference.

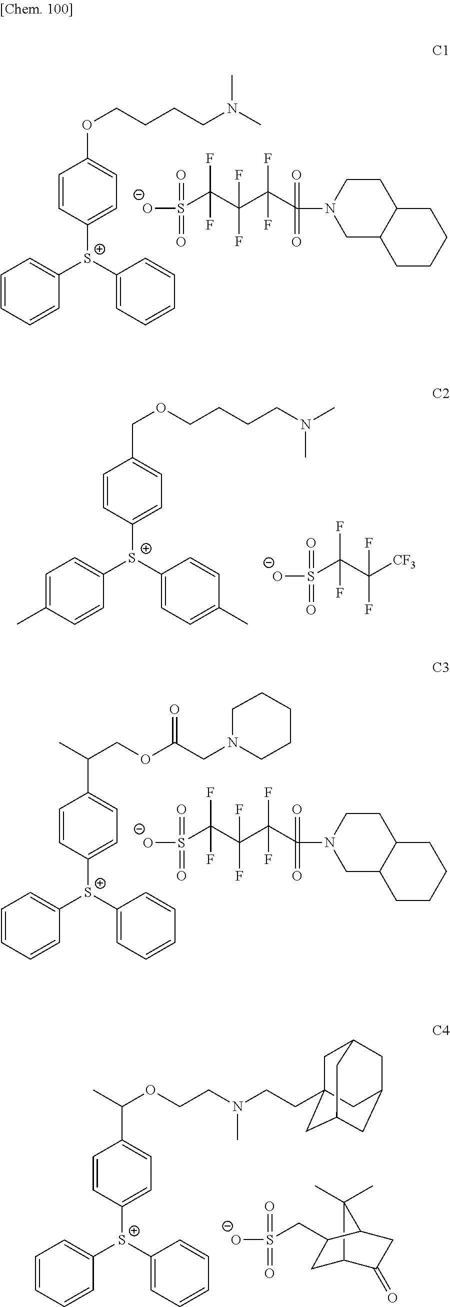

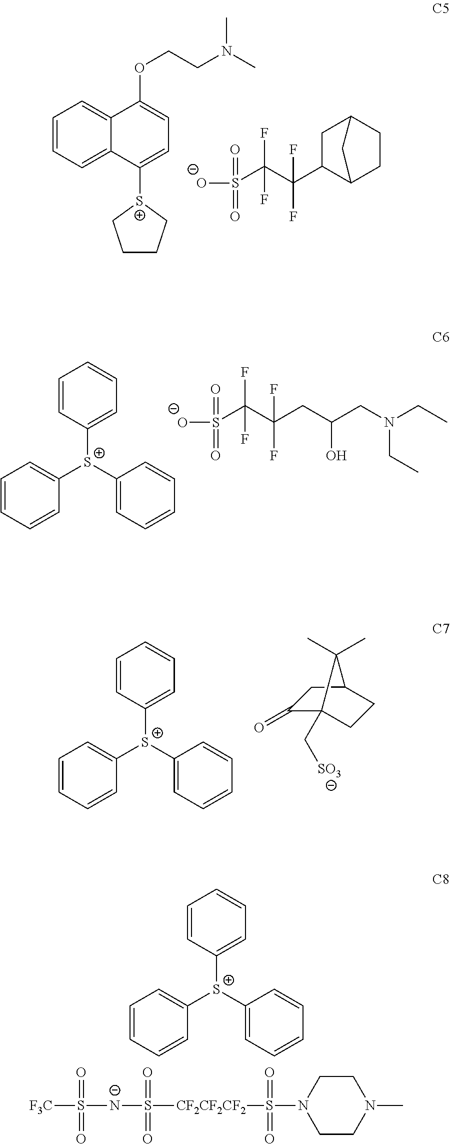

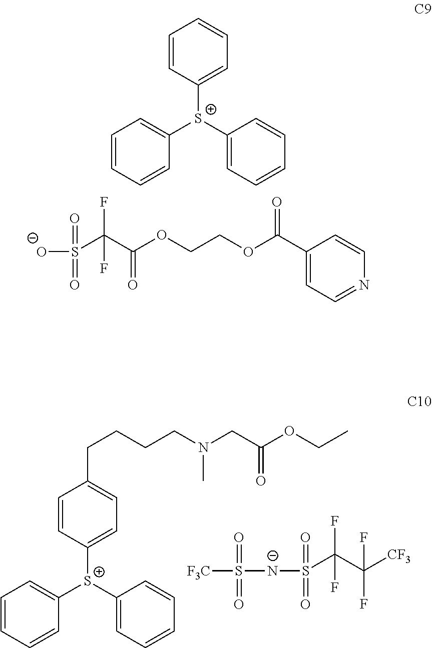

### Synthesis Example 1

### Synthesis of Compound (C3)>

By Friedel-crafts reaction between 2-phenylpropyl acetate and diphenylsulfoxide, a sulfonium salt was synthesized. Thereafter, the sulfonium salt was hydrolyzed, thereby obtaining the following compound (C3-1).

In a 200 mL three-neck flask, 3.7 g of the compound (C3-1) was dissolved in a mixed solvent including 1.5 g of pyridine and 25 g of THF. The resultant was stirred under ice cooling, and 2.1 g of chloroacetyl chloride was added dropwise thereto over 30 minutes. After dropwise addition, the icebath was removed, and the resultant was stirred for 1 hour at room temperature. 100 g of chloroform was added thereto, and the organic layer was sequentially washed with water, saturated sodium bicarbonate water, and water, and then the solvents were removed to obtain the brown liquid-like following compound (C3-2).

In a 200 mL three-neck flask, the compound (C3-2) was dissolved in 25 g of acetone. The resultant was stirred under ice cooling, and 1.7 g of piperidine was added dropwise thereto over 30 minutes. After dropwise addition, the icebath was removed, and the resultant was stirred for 5 hours at room temperature. 100 g of chloroform was added thereto, and the organic layer was sequentially washed with water, saturated sodium bicarbonate water, and water, and then the solvents were removed to obtain obtaining the brown liquid-like following compound (C3-3).

To an aqueous solution obtained by dissolving the compound (C3-3) in 50 g of water, 3.6 g of the following compound (C3-4) was added, followed by stirring for 30 minutes. After 100 of chloroform was added thereto, the organic layer was washed with water, thereby obtaining 3.3 g of a brown liquid-like compound (C3).

¹H-NMR (300 MHz, CDCl₃); 7.78 to 7.62 (m, 12H), 7.55 (d, 2H), 4.22 (m, 2H), 3.95 (d, 1H), 3.76 (d, 1H), 3.23 (m, 1H), 3.13 (s, 2H), 3.04 (t, 1H), 2.65 (t, 1H), 2.40 (m, 4H), 1.82 to 1.55 (m, 8H), 1.48 to 1.20 (m, 6H), 1.14 to 0.84 (m, 3H).

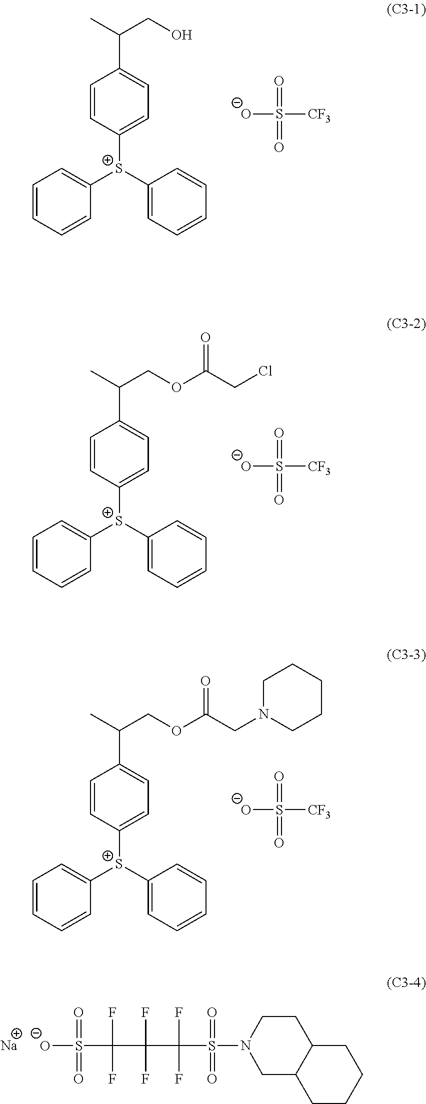

### <Compound (D)>

As the compound (D), the following compounds (D1) to (D6) were prepared.

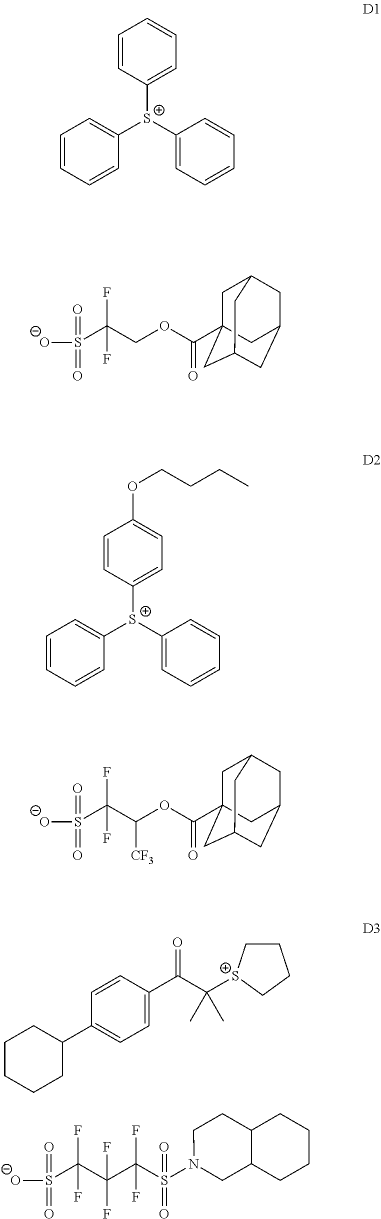

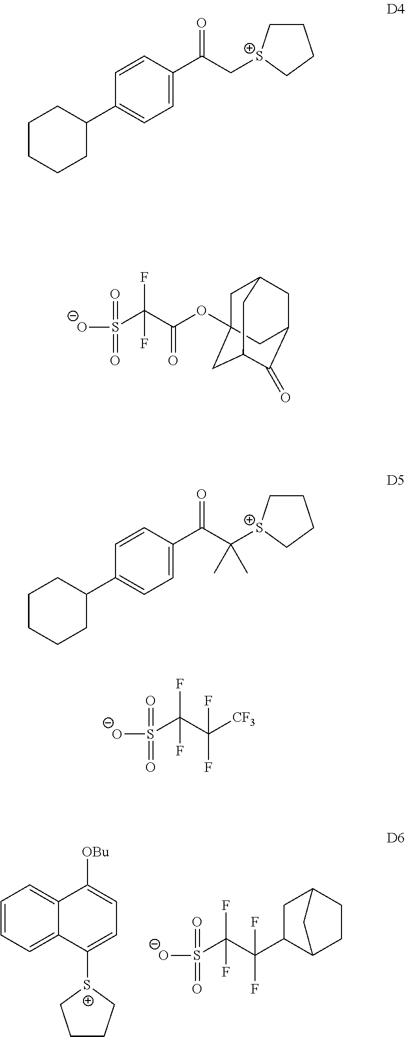

### <Solvent>

As solvents, the following (E1) to (E4) were prepared.

E1: propylene glycol monomethyl ether acetate

E2: propylene glycol monomethyl ether

E3: γ-butyrolactone

E4: cyclohexanone

<Basic Compound or Compound (G)>
F1: 2,6-diisopropyl aniline
F2: N-phenyldiethanolamine

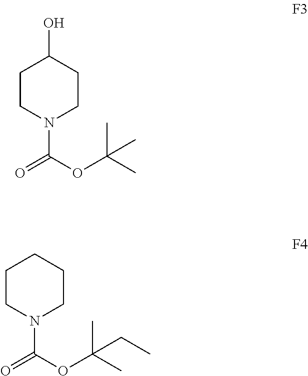

<Surfactant>
W1: Megafac F176 (based on fluorine, available from Dainippon Ink & Chemicals, Inc.)
W2: Megafac R08 (based on fluorine and silicon, available from Dainippon Ink & Chemicals, Inc.)
W3: polysiloxane polymer KP-341 (based on silicon, available from Shin-Etsu Chemical Co., Ltd)
W4: Troysol S-366 (available from Troy Chemical)
W5: PF656 (based on fluorine, available from OMNOVA solutions Inc.)
W6: PF6320 (based on fluorine, available from OMNOVA solutions Inc.)

<Preparation of Resist Composition>

The components shown in Table 2 below were dissolved in the mixed solvent shown in the table, thereby preparing a solution having a solid content concentration of 5.0% by mass. This solution was filtered through a polyethylene filter having a pore size of 0.03 μm, thereby preparing a resist composition (positive resist solution)

<ArF Liquid Immersion Exposure>

ARC 29SR (available from Nissan Chemical Industries, Ltd.) for forming an organic antireflection film was coated on a silicon wafer, followed by baking for 60 seconds at 205° C., thereby forming an antireflection film having a film thickness of 86 nm. The prepared resist composition was coated on this film, followed by baking for 60 seconds at 130° C., thereby forming a resist film having a film thickness of 120 nm. The obtained wafer was exposed by using an ArF excimer laser liquid immersion scanner (XT 1700i available from ASML, NA=1.20, C-Quad, outer sigma of 0.981, inner sigma of 0.895, XY deflection), through a mask of 72 nm line and space patterns (1:1). Ultrapure water was used as the liquid for liquid immersion.

Thereafter, the resultant was heated for 60 seconds at 130° C., followed by development for 30 seconds with an aqueous tetramethyl ammonium hydroxide solution (2.38% by mass). Subsequently, the resultant was rinsed with pure water, followed by spin drying, thereby obtaining a resist pattern.

<Resist Evaluation>

(Depth of Focus; DOF)

In an exposure amount in which a line width of 72.0 nm was obtained, a width of depth of focus reproducing a line width of 72 nm±10% was observed. Desirably, the larger this value, the larger the allowance for out-of-focus.

(Density Distribution Dependency)

A line width of an isolated pattern (line/space=1/10) in an exposure amount reproducing a mask pattern of a dense pattern (line/space=1/1) having a line width of 0.10 μm was measured. Thereafter, a difference between this line width and 0.10 μm was calculated. The smaller this value, the better the density distribution dependency.

These evaluation results are shown in the following Table 2.

TABLE 2

| | Resist composition | | | | | | | | | | |
|---|---|---|---|---|---|---|---|---|---|---|---|
| | Resin (A) | | | | | | | | | | |
| | (6.0 G) | | Resin (B) | | | Compound (C) | | | Compound (D) | | |
| | | Mass | | Mass | Added | | Mass | Added | | Mass | Added |
| Examples | Type | ratio | Type | ratio | amount | Type | ratio | amount | Type | ratio | amount |
| Example 1 | A1 | | B1 | | 0.02 g | C1 | | 0.25 g | D1/D4 | 1/3 | 0.50 g |
| Example 2 | A2 | | B2/B3 | 1/2 | 0.02 g | C2 | | 0.20 g | D2/D4 | 1/2 | 0.70 g |
| Example 3 | A2/A3 | 2/1 | B4/B5 | 2/1 | 0.04 g | C3/C4 | 2/1 | 0.20 g | D2/D5 | 2/1 | 0.55 g |
| Example 4 | A2/A4 | 2/3 | B3 | | 0.02 g | C4 | | 0.20 g | D2 | | 0.50 g |
| Example 5 | A5 | | B5 | | 0.04 g | C5 | | 0.30 g | D3/D5 | 4/1 | 0.50 g |
| Example 6 | A6 | | B6/B7 | 1/1 | 0.02 g | C1 | | 0.25 g | D3/D6 | 1/1 | 0.55 g |
| Example 7 | A1/A6 | 2/1 | B7 | | 0.02 g | C3 | | 0.20 g | D4 | | 0.50 g |
| Example 8 | A1 | | B1/B8 | 1/2 | 0.03 g | C4 | | 0.25 g | D1/D5 | 1/4 | 0.50 g |
| Example 9 | A2 | | B9 | | 0.06 g | C5 | | 0.30 g | D2/D4 | 1/2 | 0.70 g |
| Example 10 | A4 | | B10 | | 0.04 g | C2/C5 | 1/2 | 0.20 g | D1/D4 | 1/6 | 0.50 g |
| Example 11 | A5 | | B10 | | 0.04 g | C2 | | 0.20 g | D4 | | 0.50 g |
| Example 12 | A6 | | B11 | | 0.02 g | C1 | | 0.20 g | D5 | | 0.60 g |
| Example 13 | A5 | | B5 | | 0.04 g | C10 | | 0.30 g | D3/D5 | 1/3 | 0.50 g |
| Comparative | A2/A4 | 1/1 | B5 | | 0.05 g | — | | — | D4/D5 | 1/2 | 0.60 g |
| example 1 | | | | | | | | | | | |
| Comparative | A4 | | B6 | | 0.03 g | C6 | | 0.20 g | D2/D5 | 1/4 | 0.55 g |
| example 2 | | | | | | | | | | | |
| Comparative | A1/A4 | 2/1 | B2/B3 | 1/2 | 0.03 g | C7 | | 0.30 g | D2 | | 0.55 g |
| example 3 | | | | | | | | | | | |
| Comparative | A4 | | B4/B5 | 2/1 | 0.03 g | C8 | | 0.20 g | D5 | | 0.60 g |
| example 4 | | | | | | | | | | | |
| Comparative | A5 | | B5 | | 0.03 g | C9 | | 0.25 g | D2/D5 | 1/4 | 0.55 g |
| example 5′ | | | | | | | | | | | |

| Resist composition | | | | | Evaluation | |
|---|---|---|---|---|---|---|
| | | Surfactant | | Basic | | Density |
| Solvent | | (0.02 g) | | compound | | distribution |
| | Mass | | Mass | (0.05 g) | DOF | dependency |

| Examples | Type | ratio | Type | ratio | Type | (μm) | (nm) |
|---|---|---|---|---|---|---|---|
| Example 1 | E1/E2 | 8/2 | W1 | | — | 0.40 | 36 |
| Example 2 | E1/E3 | 8/2 | W2 | | F1 | 0.45 | 35 |
| Example 3 | E2/E4 | 6/4 | W1/W3 | 2/1 | — | 0.40 | 35 |
| Example 4 | E1 | | W4 | | — | 0.55 | 32 |
| Example 5 | E1/E2/E3 | 8/1/1 | W5 | | — | 0.50 | 33 |
| Example 6 | E1/E2/E4 | 8/1/1 | W6 | | F2 | 0.50 | 32 |
| Example 7 | E1/E2 | 6/4 | W2 | | F3 | 0.55 | 30 |
| Example 8 | E1/E3 | 6/4 | W1/W6 | 1/1 | — | 0.50 | 30 |
| Example 9 | EI/E3 | 8/2 | W4 | | — | 0.50 | 29 |
| Example 10 | E1 | | W5 | | F4 | 0.55 | 28 |
| Example 11 | E1/E2 | 8/2 | W5 | | — | 0.55 | 27 |
| Example 12 | E1/E2/E4 | 8/1/1 | W6 | | — | 0.65 | 28 |
| Example 13 | E1/E2/E3 | 8/1/1 | W5 | | — | 0.50 | 33 |
| Comparative | E1/E2 | 8/2 | W4 | | F3 | 0.20 | 42 |
| example 1 | | | | | | | |
| Comparative | E1/E3 | 1/1 | W5 | | — | 0.25 | 46 |
| example 2 | | | | | | | |
| Comparative | E1/E2/E3 | 7/2/1 | W2/W4 | 7/3 | — | 0.25 | 45 |
| example 3 | | | | | | | |
| Comparative | E1/E2 | 8/2 | W5 | | F4 | 0.25 | 43 |
| example 4 | | | | | | | |
| Comparative | E1/E3 | 6/4 | W6 | | — | 0.20 | 45 |
| example 5′ | | | | | | | |

Table 2 clearly shows that when the composition according to the present invention is used, the depth of focus and the density distribution dependency greatly are improved compared to a case of using the composition according to comparative examples.

What is claimed is:

1. An actinic-ray-sensitive or radiation-sensitive resin composition comprising:
(A) a first resin which decomposes by an action of an acid to increase a solubility of the first resin in an alkaline developer;
(B) a second resin which includes at least one of a fluorine atom and a silicon atom and is different from the first resin; and
(C) an onium salt which includes a nitrogen atom in a cation portion and generates an acid by being decomoposed upon irradiation with actinic-ray or radiation.

2. The composition according to claim 1,
wherein the content of the second resin is in a range from 0.1% by mass to 10% by mass based on the total solid content of the composition.

3. The composition according to claim 1,
wherein the second resin includes a repeating unit that has at least one group selected from a group consisting of the following (x), (y), and (z):
(x) an alkali-soluble group;
(y) a group which decomposes by an action of an alkaline developer to increase a solubility of the second resin in the alkaline developer; and
(z) a group which decomposes by an action of an acid to increase a solubility of the second resin in an alkaline developer.

4. The composition according to claim 1,
wherein the second resin includes a repeating unit having (z) the group which decomposes by an action of an acid to increase a solubility of the second resin in an alkaline developer.

5. The composition according to claim 1,
wherein the onium salt is a sulfonium salt.

6. The composition according to claim 1,
wherein the cation portion includes a basic moiety having the nitrogen atom.

7. The composition according to claim 1,
wherein the cation portion includes a partial structure represented by the following general formula (N-I). 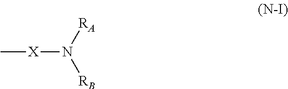
In the formula,
each of R_{A} and R_{B} independently represents a hydrogen atom or an organic group.
X represents a single bond or a linking group.
At least two of R_{A}, R_{B}, and X may form a ring by binding to each other.

8. The composition according to claim 1,
wherein the onium salt is represented by the following general formula (N-II). 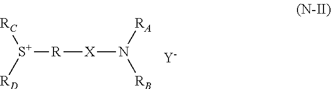
In the formula,
each of R_{A} and R_{B} independently represents a hydrogen atom or an organic group.
X represents a single bond or a linking group.
R represents an organic group.
Each of R_{C} and R_{D} independently represents a hydrogen atom or an organic group.
At least two of R_{A}, R_{B}, X, R, R_{C}, and R_{D} may form a ring by binding to each other.
Y⁻ represents an anion.

9. An actinic-ray-sensitive or radiation-sensitive film formed using the composition according to claim 1.

10. A pattern forming method comprising:
forming a film by using the composition according to claim 1;
exposing the film through a liquid for liquid immersion; and
developing the exposed film.

11. The composition according to claim 2,
wherein the second resin includes a repeating unit that has at least one group selected from a group consisting of the following (x), (y), and (z):
(x) an alkali-soluble group;
(y) a group which decomposes by an action of an alkaline developer to increase a solubility of the second resin in the alkaline developer; and
(z) a group which decomposes by an action of an acid to increase a solubility of the second resin in an alkaline developer.

12. The composition according to claim 2,
wherein the second resin includes a repeating unit having (z) the group which decomposes by an action of an acid to increase a solubility of the second resin in an alkaline developer.

13. The composition according to claim 2,
wherein the onium salt is a sulfonium salt.

14. The composition according to claim 3,
wherein the onium salt is a sulfonium salt.

15. The composition according to claim 2,
wherein the cation portion includes a basic moiety having the nitrogen atom.

16. The composition according to claim 3,
wherein the cation portion includes a basic moiety having the nitrogen atom.

17. The composition according to claim 2,
wherein the cation portion includes a partial structure represented by the following general formula (N-I). 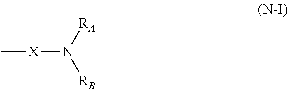
In the formula, R_{A}, R_{B}, and X are the same as the above-described R_{A}, R_{B}, and X respectively.

18. The composition according to claim 3,
wherein the cation portion includes a partial structure represented by the following general formula (N-I). 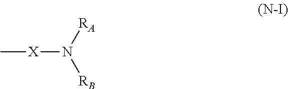
In the formula, R_{A}, R_{B}, and X are the same as the above-described R_{A}, R_{B}, and X respectively.

19. The composition according to claim 2,
wherein the onium salt is represented by the following general formula (N-II) 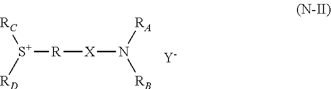
In the formula, R_{A}, R_{B}, X, R, R_{C}, and R_{D} are the same as the above-described R_{A}, R_{B}, X, R, R_{C}, and R_{D} respectively.

20. The composition according to claim 3,
wherein the onium salt is represented by the following general formula (N-II). 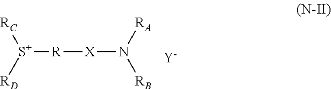
In the formula, R_{A}, R_{B}, X, R, R_{C}, and R_{D} are the same as the above-described R_{A}, R_{B}, X, R, R_{C}, and R_{D} respectively.
